(19) United States
(12) Patent Application Publication
(10) Pub. No.: US 2024/0130216 A1
(43) Pub. Date: Apr. 18, 2024

(54) IRIDIUM COMPLEX AND APPLICATION THEREOF

(71) Applicant: GUANGDONG AGLAIA OPTOELECTRONIC MATERIALS CO., LTD, Foshan, Guangdong (CN)

(72) Inventors: Liangliang YAN, Foshan (CN); Lei DAI, Foshan (CN); Lifei CAI, Foshan (CN)

(73) Assignee: GUANGDONG AGLAIA OPTOELECTRONIC MATERIALS CO., LTD, Foshan, Guangdong (CN)

(21) Appl. No.: 18/038,677

(22) PCT Filed: Oct. 24, 2021
(86) PCT No.: PCT/CN2021/125927

§ 371 Date: May 24, 2023

(30) Foreign Application Priority Data
Dec. 4, 2020 (CN) 202011397746.2
Sep. 29, 2021 (CN) 202111148949.2

(51) Int. Cl. H10K 85/30; C07F 15/00; C09K 11/06

(52) U.S. Cl. CPC H10K 85/342; C07F 15/0033; C09K 11/06; C09K 2211/1007; C09K 2211/1029; C09K 2211/1044; C09K 2211/1088; C09K 2211/185; H10K 50/12

(57) ABSTRACT

The present invention relates to an iridium complex and application thereof. The iridium complex has a general formula of Ir(La)(Lb)(Lc), and has a structure as shown in a formula (1) as a ligand. The provided metal complex has the advantages of low sublimation temperature, good optical and electrical stability, high luminous efficiency, long service life, and high color saturation. The metal complex can be used in organic light-emitting devices, especially as a red light-emitting phosphorescent material, and has the potential of being applied in the AMOLED industry.

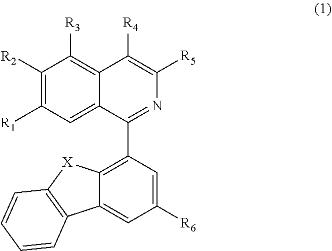

### TECHNICAL FIELD

The present invention relates to the technical field of organic electroluminescence, in particular to a technology of an organic luminescent material applicable to organic electroluminescent devices, and specially relates to an iridium complex and application thereof in an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage, and service life of OLED devices still need to be strengthened and improved.

In generally, the OLED devices include various organic functional material films with different functions sandwiched between metal electrodes as basic structures, which are similar to sandwich structures. Under the driving of a current, holes and electrons are injected from a cathode and an anode, respectively. After moving a certain distance, the holes and the electrons are compounded in a light-emitting layer, and then released in the form of light or heat to achieve luminescence of the OLED. However, organic functional materials are core components of the OLED devices, and the thermal stability, photochemical stability, electrochemical stability, quantum yield, film forming stability, crystallinity, and color saturation of the materials are main factors affecting properties of the devices.

In general, the organic functional materials include fluorescent materials and phosphorescent materials. The fluorescent materials are usually organic small-molecule materials, which can only use 25% of singlet luminescence, thus having low luminous efficiency. Meanwhile, due to a spin-orbit coupling effect caused by a heavy atom effect, the phosphorescent materials can use 25% of singlet excitons, and can also use 75% of energy of triplet excitons, so that the luminous efficiency can be improved. However, compared with the fluorescent materials, the phosphorescent materials are developed later, and the thermal stability, service life, color saturation and the like of the materials need to be improved. Thus, the phosphorescent materials are a challenging topic. Various organic metal compounds have been developed to serve as the phosphorescent materials. For example, according to an invention patent document CN107973823, a quinoline iridium compound is disclosed. However, the color saturation and device properties, especially luminous efficiency and device service life, of the compound need to be improved. According to an invention patent document CN106459114, an iridium compound coordinated with a β-dione coordination group is disclosed. However, the compound has high sublimation temperature and low color saturation. In particular, the device performance is unsatisfactory, which needs to be further improved. According to an invention patent CN109721628, a compound with a fluorenyl thiophenpyrimidine structure and an organic electroluminescent device and compound including the compound are disclosed. According to invention patents CN111377969A and CN111620910A, a complex with a dibenzofuran-isoquinoline structure and an organic electroluminescent device and compound including the complex are disclosed.

However, a novel material capable of further improving properties of organic electroluminescent devices is still expected to be developed.

### SUMMARY

In order to solve the above defects, the present invention provides an organic electroluminescent device having high properties and a novel material capable of realizing the organic electroluminescent device.

In order to achieve the above purposes, the inventor has conducted in-depth studies repeatedly and found that an organic electroluminescent device having high properties can be obtained by using an iridium complex having a structure as shown in the following formula (1) as a ligand.

One of the purposes of the present invention is to provide an iridium complex. The iridium complex has the advantages of low sublimation temperature, high optical and electrochemical stability, high color saturation, high luminous efficiency, and long device service life, and can be used in organic electroluminescent devices. In particular, the iridium complex has the potential for application in the OLED industry as a red light-emitting dopant.

In order to achieve the above purposes, the following technical solutions are adopted in the present invention.

An iridium complex has a structure of Ir(La)(Lb)(Lc),
where La, Lb, and Lc are different from each other, the “different from each other” refers to having different parent nuclear structures, having same parent nuclear structures but different substituents, or having same parent nuclear structures and same substituents but different positions of the substituents, all the La, the Lb, and the Lc are a monoanionic bidentate ligand, any two of the La, the Lb, and the Lc are connected to each other to form a multidentate ligand, or the La, the Lb, and the Lc are connected by a group;
the ligand La is as shown in a formula (1):

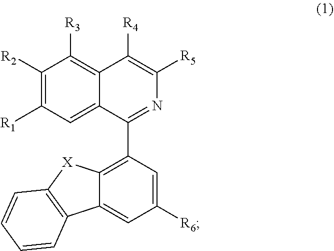

X is independently selected from O, S, and Se;
R₁-R₅ are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, substituted or unsubstituted C₃-C₂₀ heterocycloalkyl, substituted or unsubstituted C₃-C₃₀ alkylsilyl, substituted or unsubstituted C₁-C₁₀ alkoxyl, substituted or unsubstituted C₇-C₃₀ aralkyl, substituted or unsubstituted C₆-C₃₀ aryloxyl, substituted or unsubstituted C₂-C₂₀ alkenyl, substituted or unsubstituted C₂-C₂₀ alkynyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino;
at least one of the R₁-R₅ is F, and another one is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;
R₆ is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;
the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino;
and the heteroalkyl, the heterocycloalkyl, or the heteroaryl includes at least one of S, O, and N heteroatoms.

The Lb has a structure as shown in a formula (2):

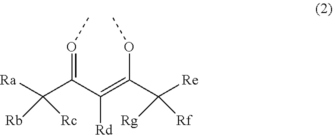

where a dotted line refers to a position connected to metal Ir;
Rₐ-R_{g} are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocycloalkyl, or any two of Rₐ, R_{b}, and R_{c} are connected to each other to form an aliphatic ring structure, and any two of Rₑ, R_{f}, and R_{g} are connected to each other to form an aliphatic ring structure; the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino; and the heteroalkyl or the heterocycloalkyl includes at least one of S, O, and N heteroatoms.

The Rₐ, the R_{b}, and the R_{c} are the same as the Rₑ, the R_{f}, and the R_{g}, respectively.

The Rₐ, the R_{b}, the R_{c}, the Rₑ, the R_{f}, and the R_{g} are independently selected from hydrogen, deuterium, halogen, substituted or unsubstituted alkyl containing 1-10 carbon atoms on a main chain, and substituted or unsubstituted cycloalkyl containing 3-20 ring forming carbon atoms, or any two of the Rₐ, the R_{b}, and the R_{c} are connected to each other to form an aliphatic ring structure, and any two of the R_{c}, the R_{f}, and the R_{g} are connected to each other to form an aliphatic ring structure; and the “substituted” refers to substitution with deuterium, F, Cl, Br, C₁-C₄ alkyl, or C₃-C₆ cycloalkyl.

R_{d} is selected from hydrogen, deuterium, halogen, and substituted or unsubstituted alkyl containing 1-10 carbon atoms on a main chain.

As a preferred iridium complex, the Lc has any one structure as shown in a formula (3) to a formula (5):

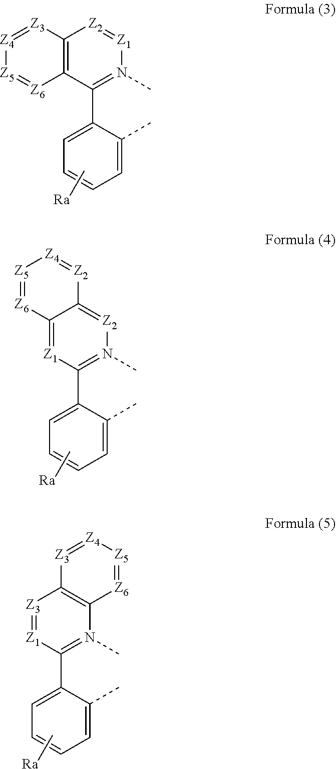

where Z₁-Z₆ are independently N or CR₀;
the number of Rₐ ranges from a minimum substitution number to a maximum substitution number;

R₀ and the Rₐ are independently selected from hydrogen, deuterium, halogen, substituted or unsubstituted C₁-C₂₀ alkyl, substituted or unsubstituted C₃-C₃₀ cycloalkyl, substituted or unsubstituted C₁-C₃₀ heteroalkyl, substituted or unsubstituted C₃-C₂₀ heterocycloalkyl, substituted or unsubstituted C₇-C₃₀ aralkyl, substituted or unsubstituted C₁-C₂₀ alkoxyl, substituted or unsubstituted C₆-C₃₀ aryloxyl, substituted or unsubstituted C₂-C₂₀ alkenyl, substituted or unsubstituted C₃-C₃₀ alkylsilyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino, or two adjacent substituents may be optionally connected to form a ring or a fused structure;
the “substituted” refers to substitution with deuterium, F, Cl, Br, C₁-C₁₀ alkyl, C₁-C₁₀ alkoxyl, C₃-C₁₀ cycloalkyl, amino substituted with C₁-C₁₀ alkyl, C₆-C₃₀ aryl, C₇-C₃₀ aralkyl, cyano, nitrile, isonitrile, or phosphino;
and the heteroalkyl, the heterocycloalkyl, or the heteroaryl includes at least one of S, O, and N heteroatoms.

As a preferred iridium complex, at least two of the Rₐ are not hydrogen.

As a preferred iridium complex, at least one of the Z₁-Z₆ is CR₀.

As a preferred iridium complex, the Rₐ is substituted or unsubstituted C₁-C₈ alkyl, the R₀ is selected from substituted or unsubstituted C₁-C₈ alkyl and substituted or unsubstituted C₃-C₆ cycloalkyl, and the “substituted” refers to substitution with deuterium, F, Cl, Br, or C₁-C₄ alkyl.

As a preferred iridium complex, the R₆ is substituted or unsubstituted C₁-C₄ alkyl, or substituted or unsubstituted C₃-C₆ cycloalkyl.

As a preferred iridium complex, the F is not positioned at the R₅.

The X is an O atom.

As a preferred iridium complex, one of the R₁-R₅ is F, another one is substituted or unsubstituted alkyl containing no more than 4 carbon atoms on a main chain, or substituted or unsubstituted cycloalkyl containing no more than δ ring forming carbon atoms, and the other three are hydrogen.

As a preferred iridium complex, when one of the R₁-R₅ is F, another one is branched C₁-C₄ alkyl substituted with C₁-C₄ alkyl.

As a preferred iridium complex, the La is independently selected from one of the following structural formulas, or corresponding parts or complete deuterides or fluorides thereof:

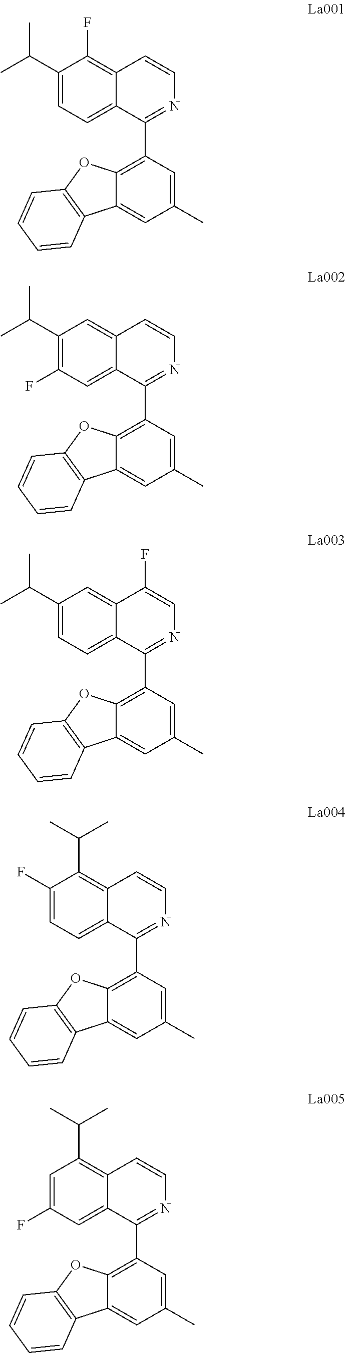

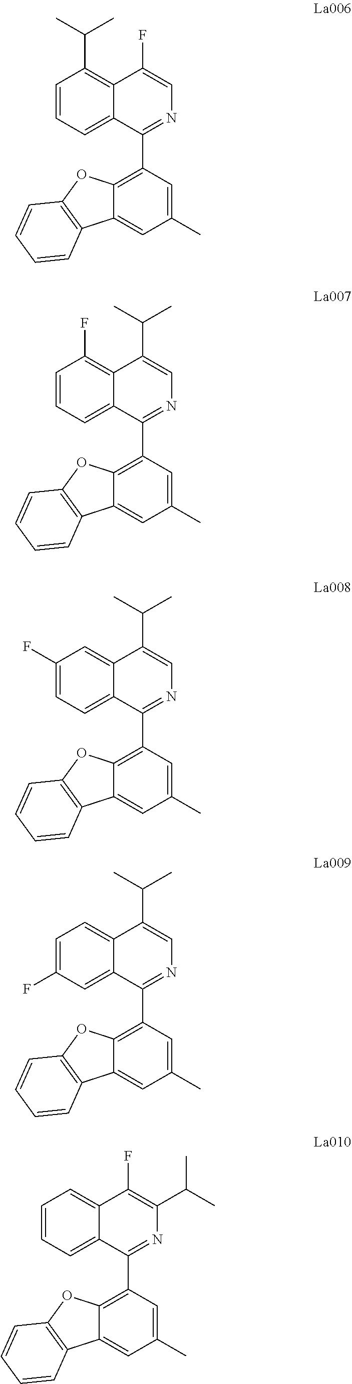 [SMILES: Cc1cc(-c2ncc(F)c3c(C(C)C)cccc23)c2oc3ccccc3c2c1 ; Cc1cc(-c2ncc(C(C)C)c3c(F)cccc23)c2oc3ccccc3c2c1 ; Cc1cc(-c2ncc(C(C)C)c3cc(F)ccc23)c2oc3ccccc3c2c1 ; Cc1cc(-c2ncc(C(C)C)c3ccc(F)cc23)c2oc3ccccc3c2c1 ; Cc1cc(-c2nc(C(C)C)c(F)c3ccccc23)c2oc3ccccc3c2c1]

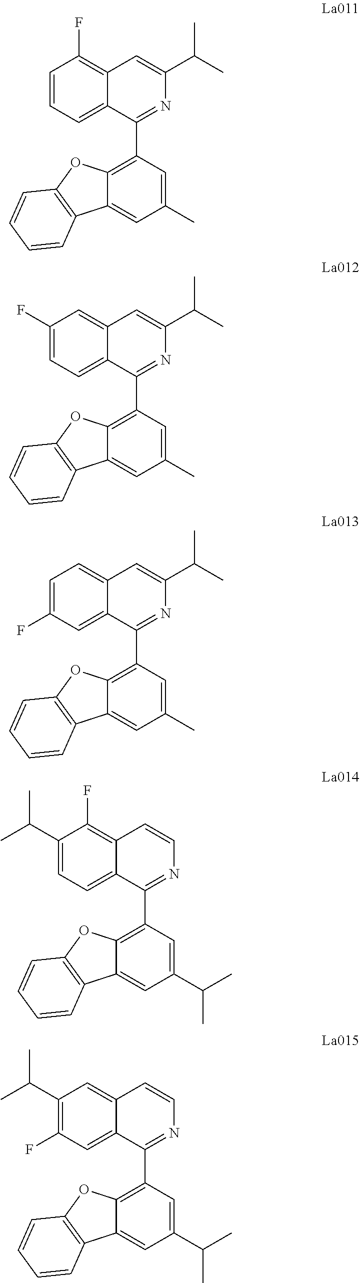

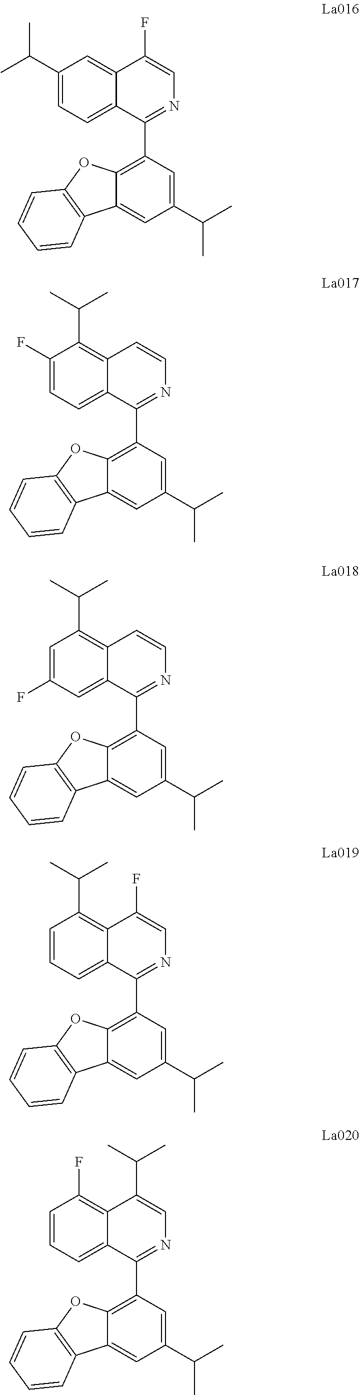

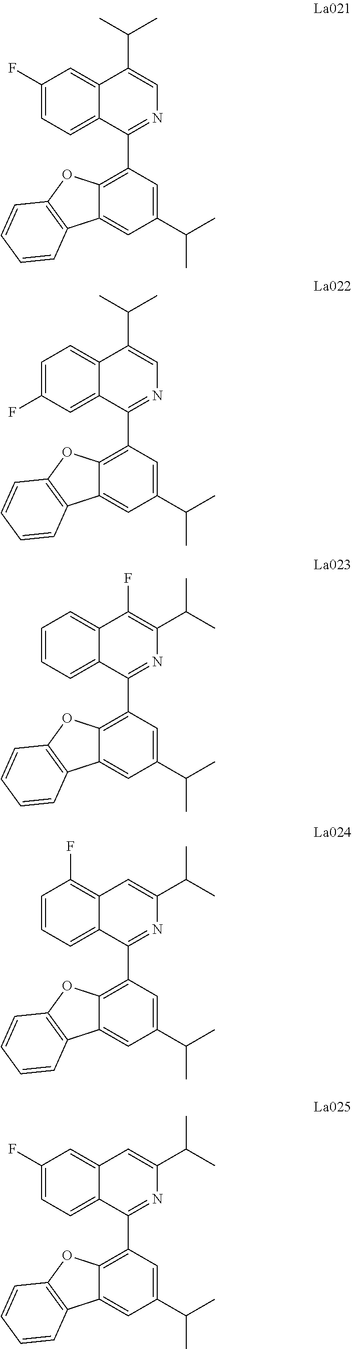

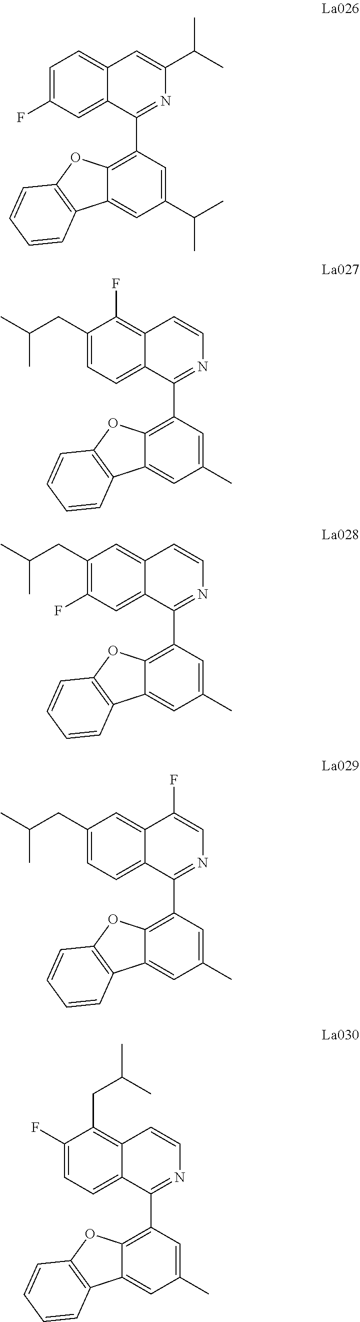

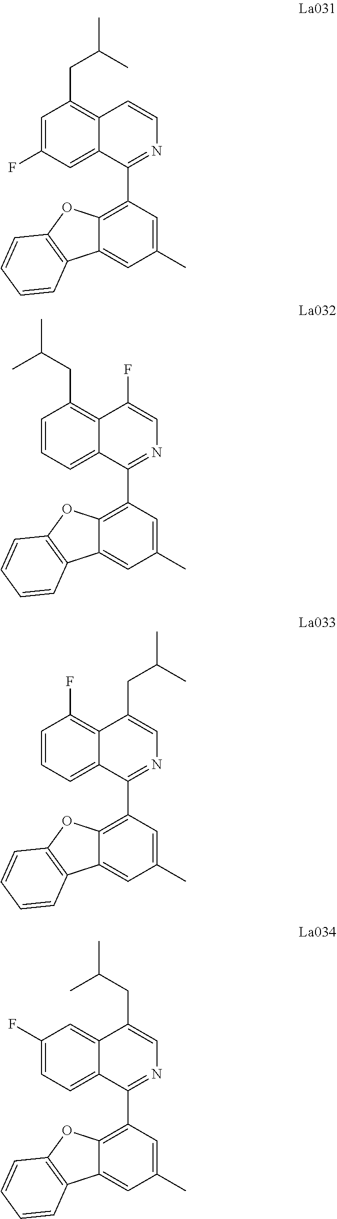

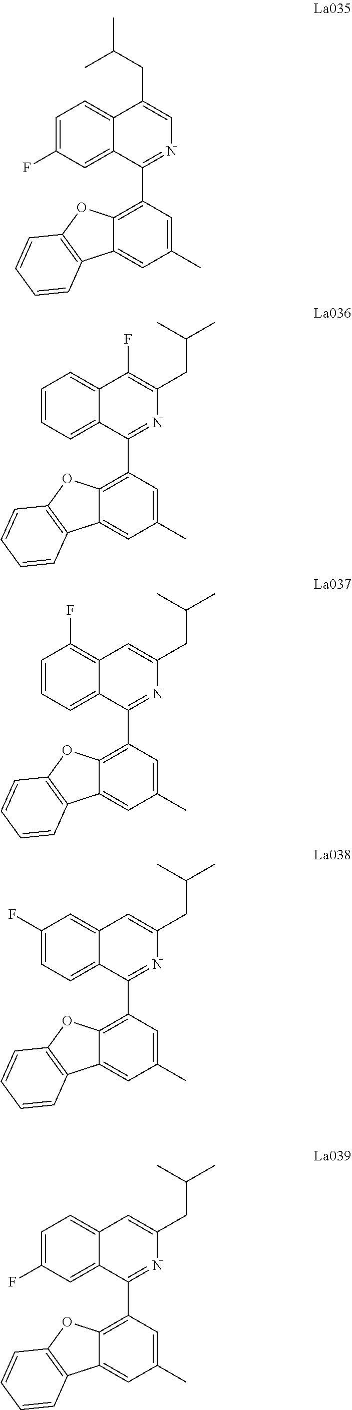 [SMILES: Cc1cc(-c2ncc(CC(C)C)c3ccc(F)cc23)c2oc3ccccc3c2c1 ; Cc1cc(-c2nc(CC(C)C)c(F)c3ccccc23)c2oc3ccccc3c2c1 ; Cc1cc(-c2nc(CC(C)C)cc3c(F)cccc23)c2oc3ccccc3c2c1 ; Cc1cc(-c2nc(CC(C)C)cc3cc(F)ccc23)c2oc3ccccc3c2c1 ; Cc1cc(-c2nc(CC(C)C)cc3ccc(F)cc23)c2oc3ccccc3c2c1]

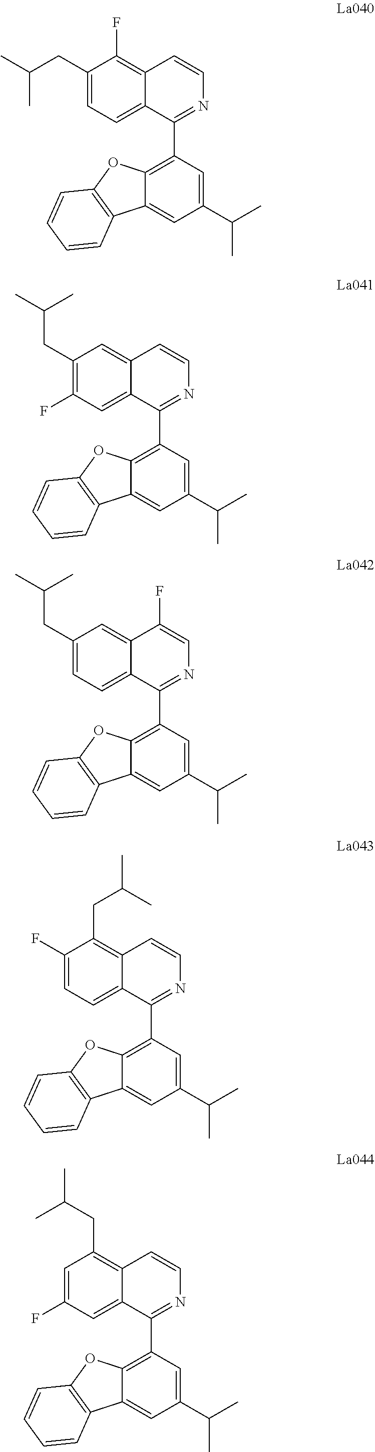

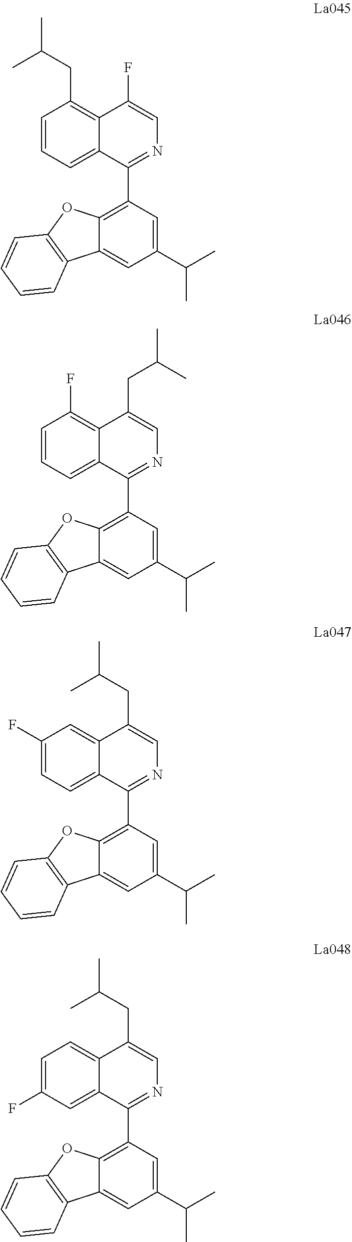

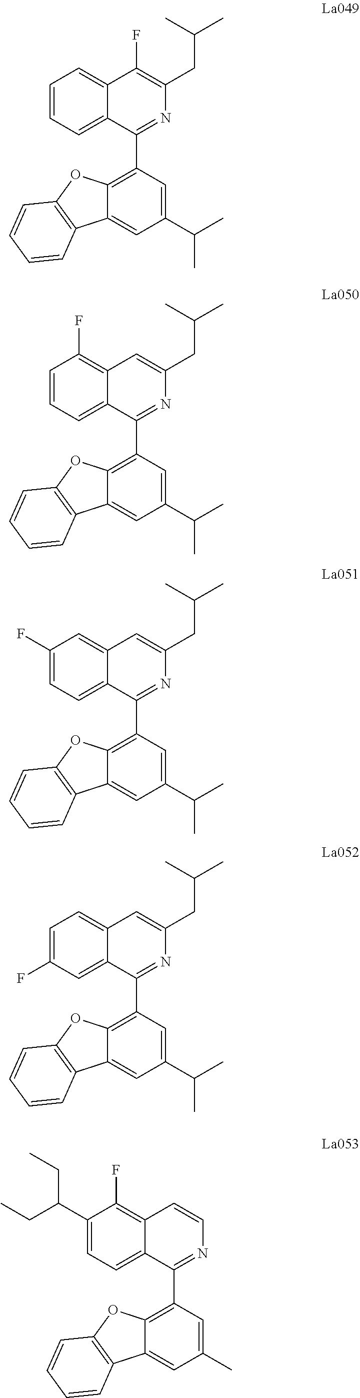

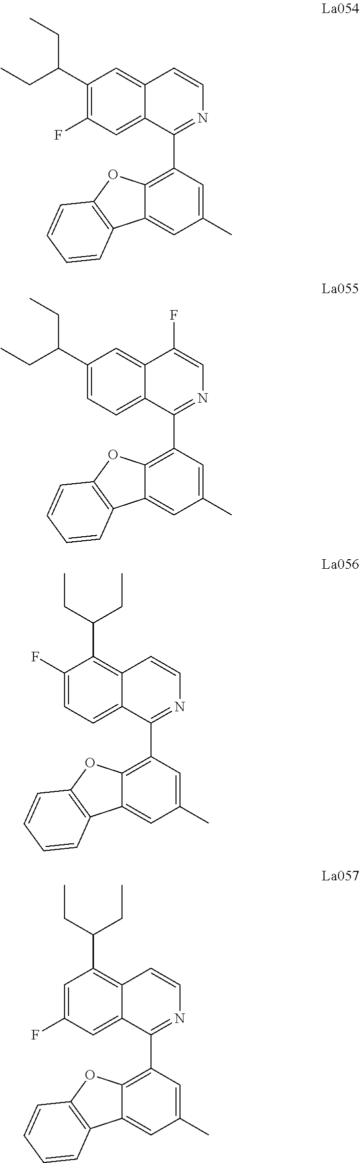

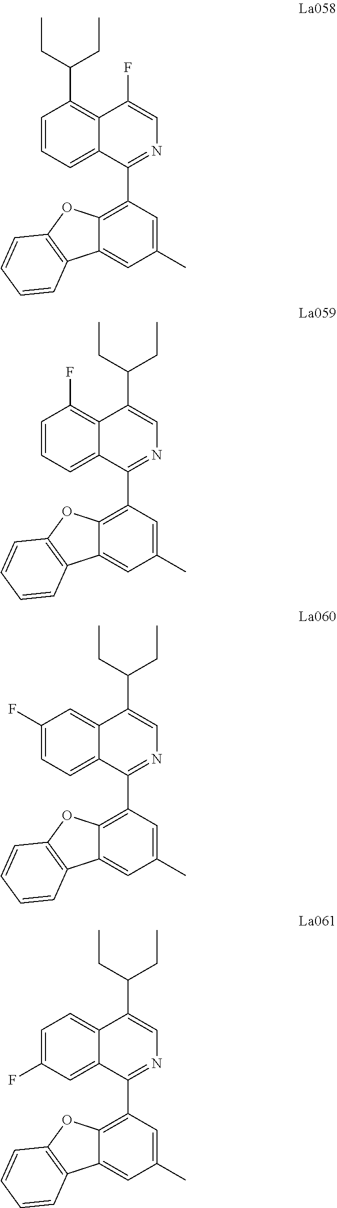 [SMILES: CCC(CC)c1cccc2c(-c3cc(C)cc4c3oc3ccccc34)ncc(F)c12 ; CCC(CC)c1cnc(-c2cc(C)cc3c2oc2ccccc23)c2cccc(F)c12 ; CCC(CC)c1cnc(-c2cc(C)cc3c2oc2ccccc23)c2ccc(F)cc12 ; CCC(CC)c1cnc(-c2cc(C)cc3c2oc2ccccc23)c2cc(F)ccc12]

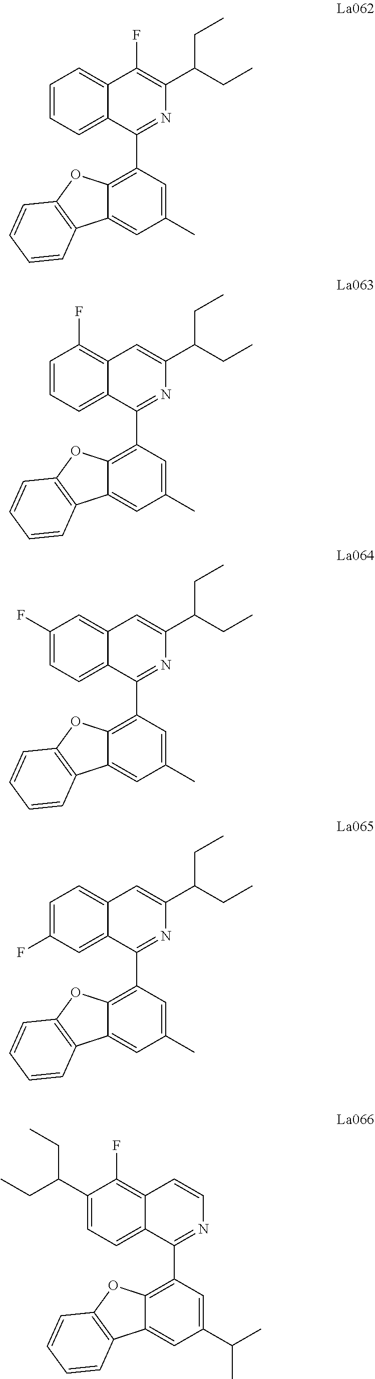

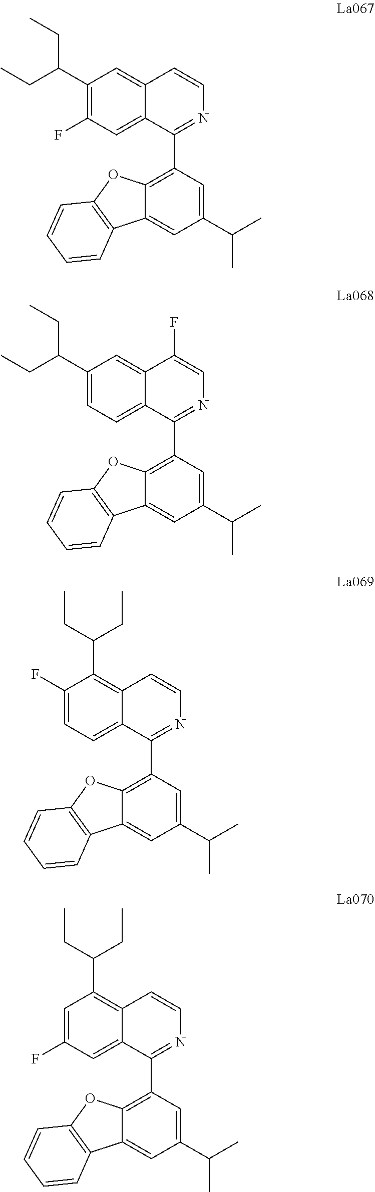

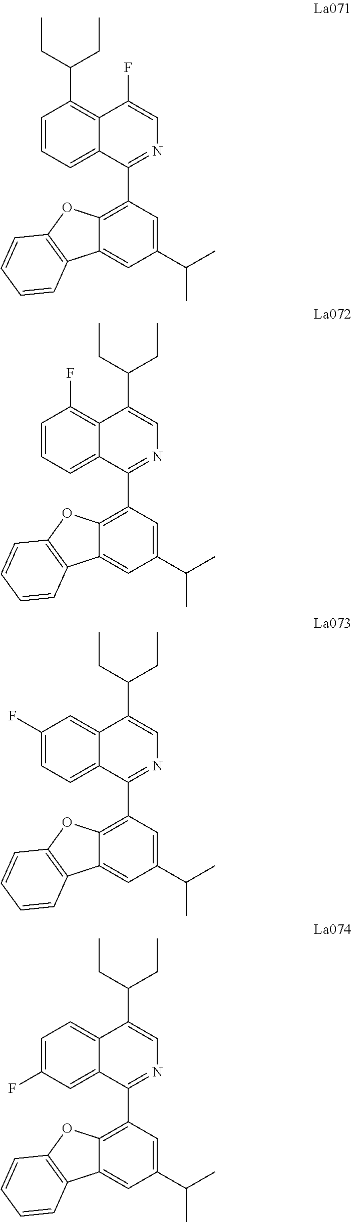

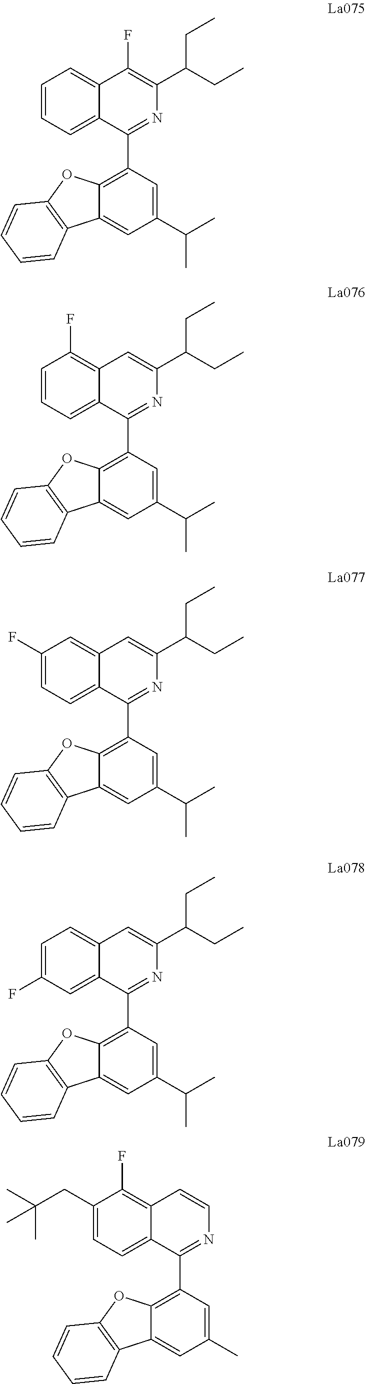

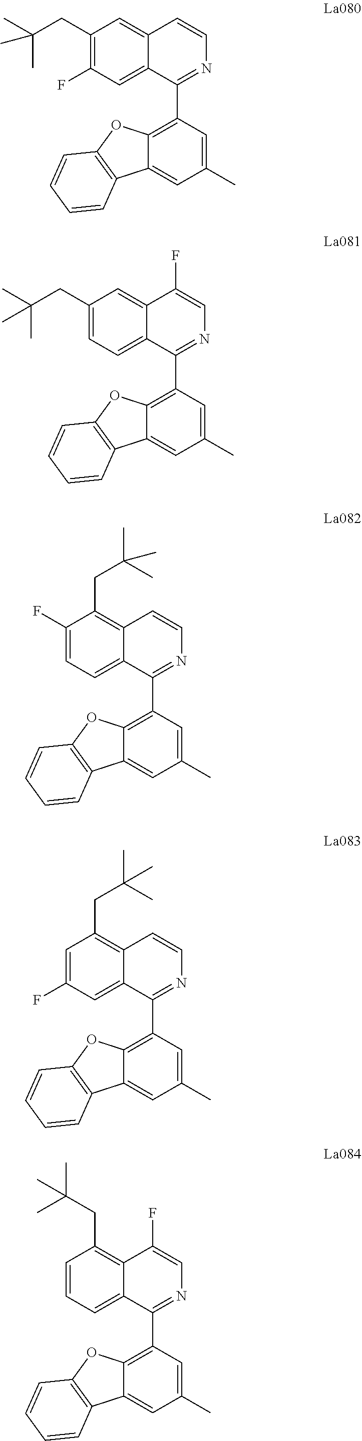

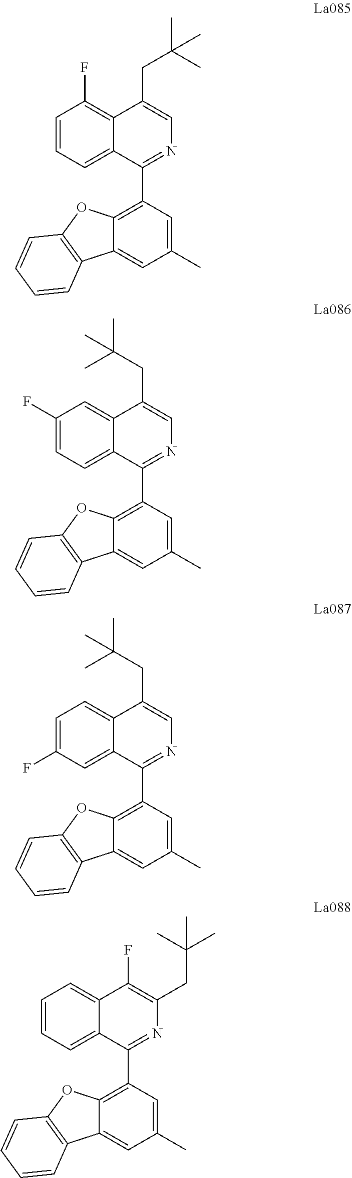

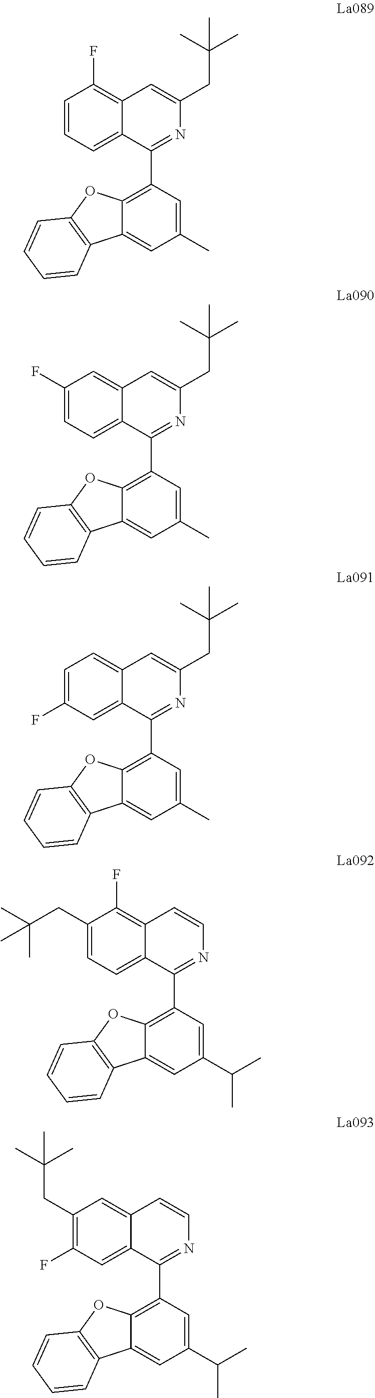

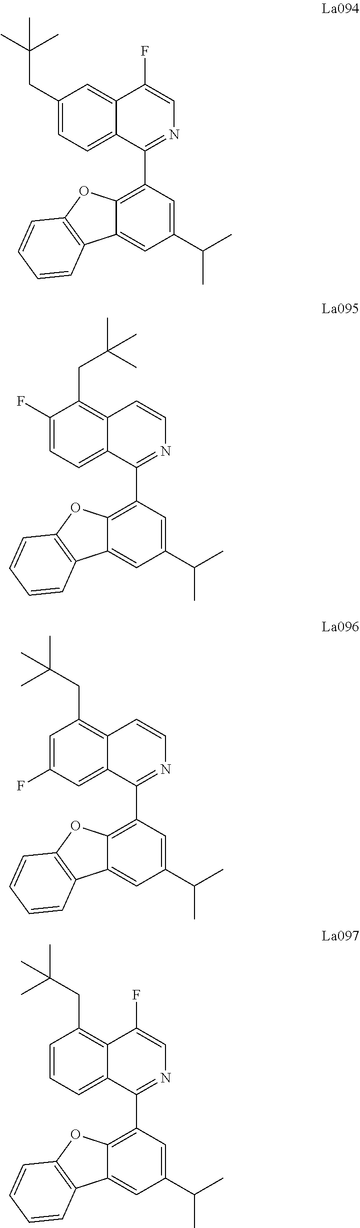

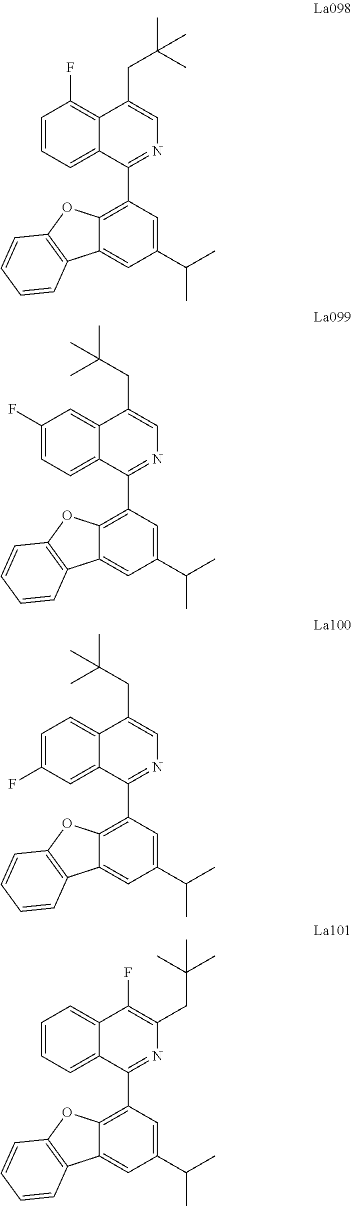

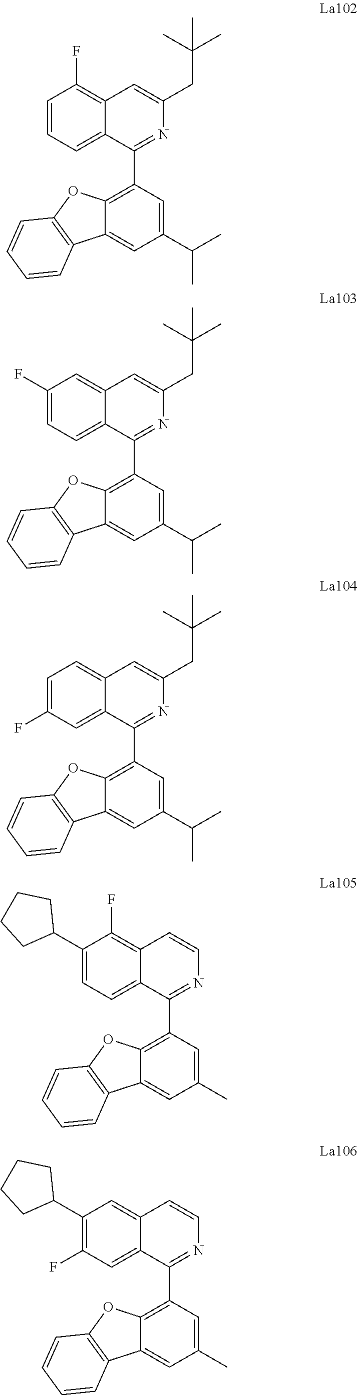

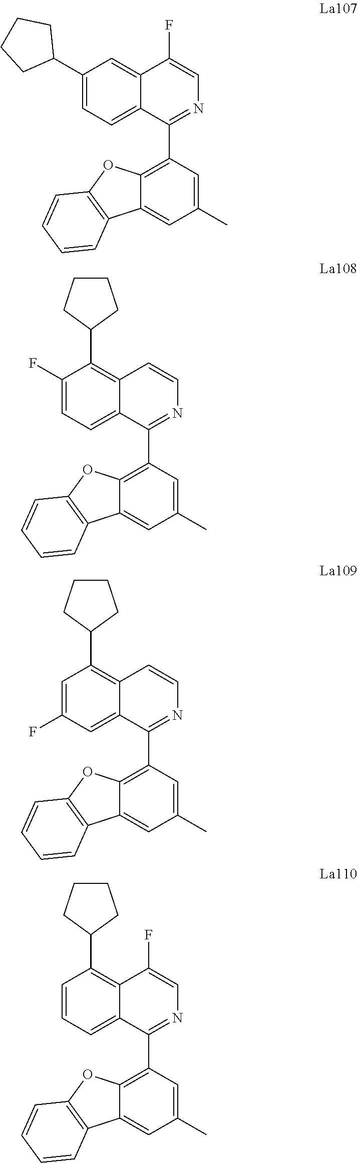

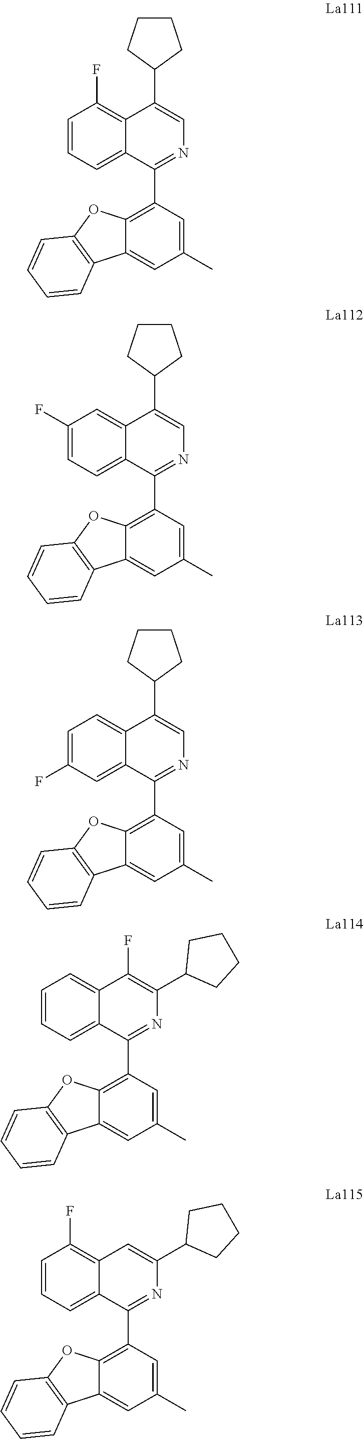 [SMILES: Cc1cc(-c2ncc(C3CCCC3)c3c(F)cccc23)c2oc3ccccc3c2c1 ; Cc1cc(-c2ncc(C3CCCC3)c3cc(F)ccc23)c2oc3ccccc3c2c1 ; Cc1cc(-c2ncc(C3CCCC3)c3ccc(F)cc23)c2oc3ccccc3c2c1 ; Cc1cc(-c2nc(C3CCCC3)c(F)c3ccccc23)c2oc3ccccc3c2c1 ; Cc1cc(-c2nc(C3CCCC3)cc3c(F)cccc23)c2oc3ccccc3c2c1]

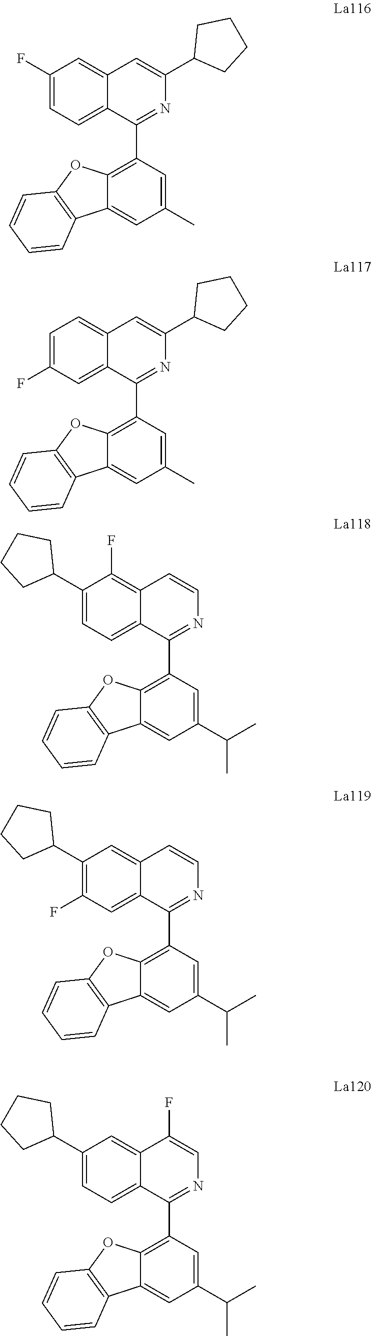

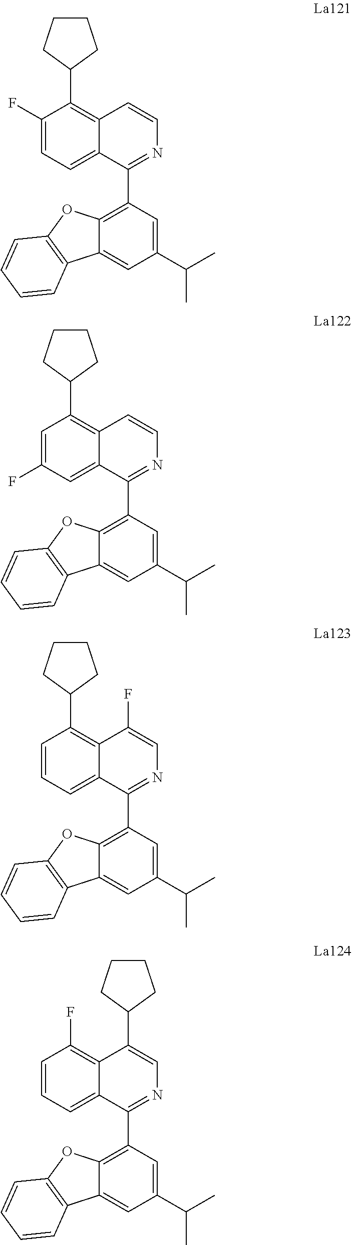

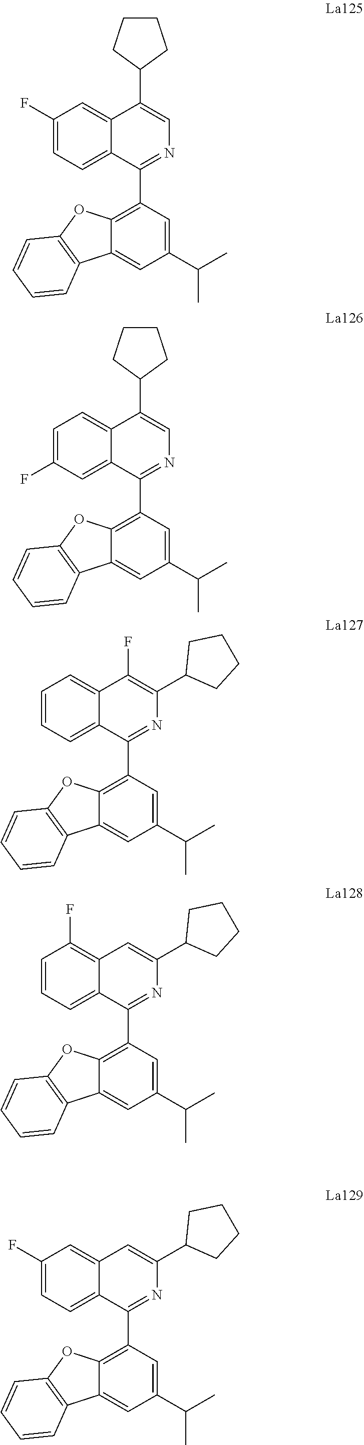

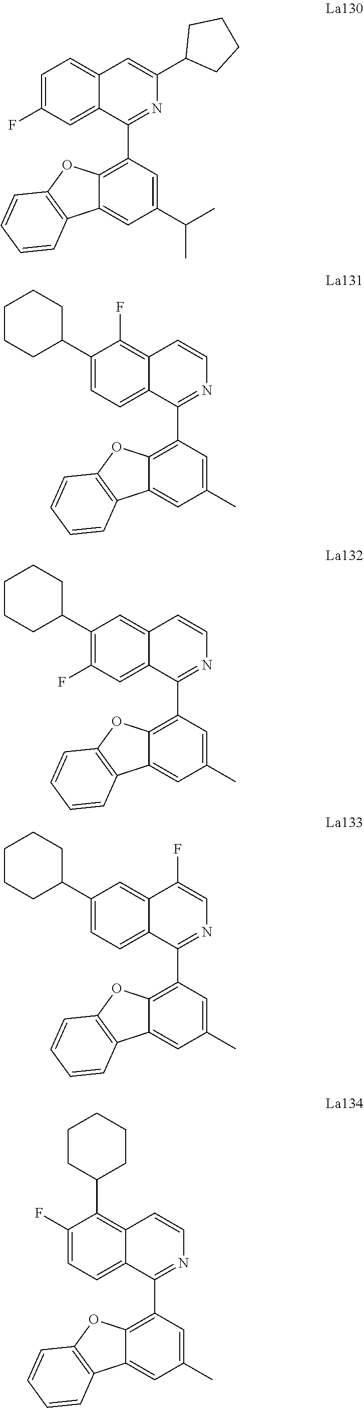

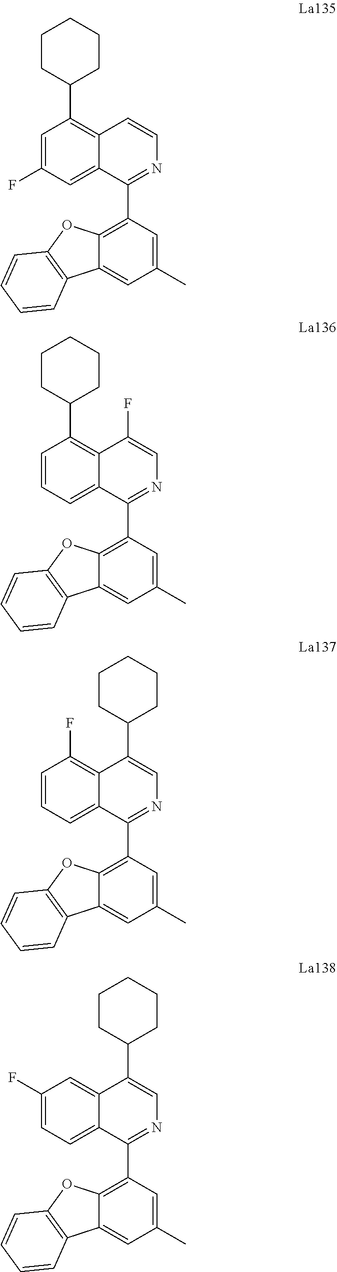

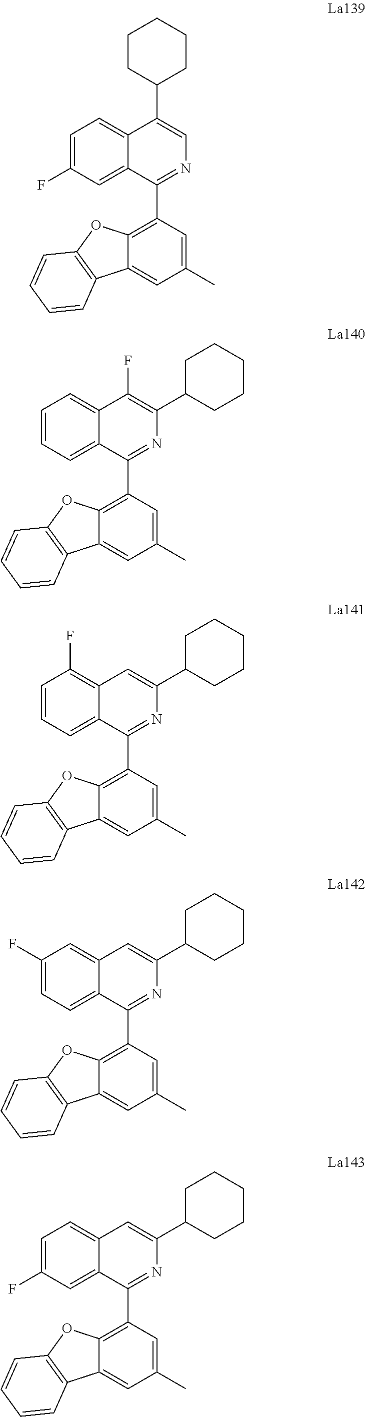 [SMILES: Cc1cc(-c2ncc(C3CCCCC3)c3ccc(F)cc23)c2oc3ccccc3c2c1 ; Cc1cc(-c2nc(C3CCCCC3)c(F)c3ccccc23)c2oc3ccccc3c2c1 ; Cc1cc(-c2nc(C3CCCCC3)cc3c(F)cccc23)c2oc3ccccc3c2c1 ; Cc1cc(-c2nc(C3CCCCC3)cc3cc(F)ccc23)c2oc3ccccc3c2c1 ; Cc1cc(-c2nc(C3CCCCC3)cc3ccc(F)cc23)c2oc3ccccc3c2c1]

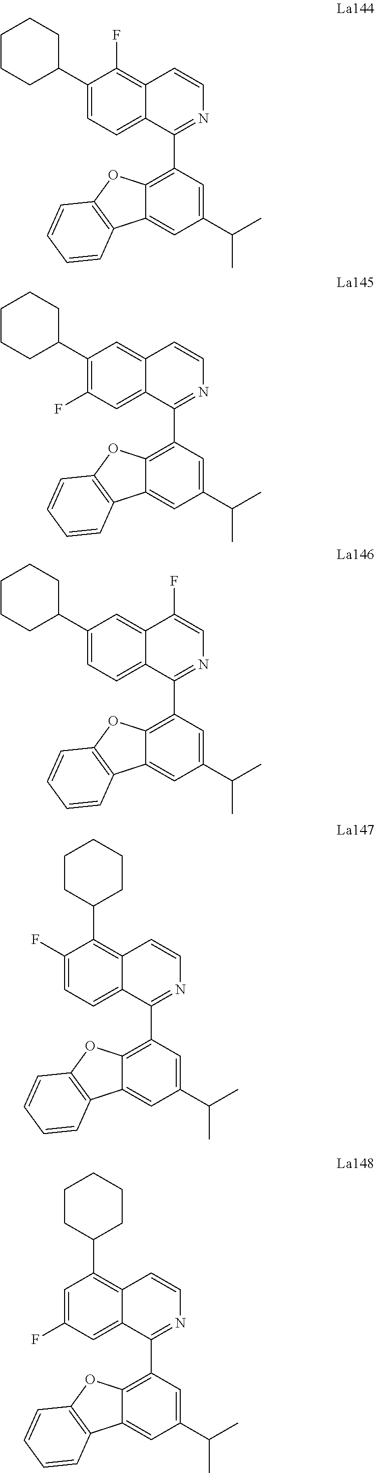

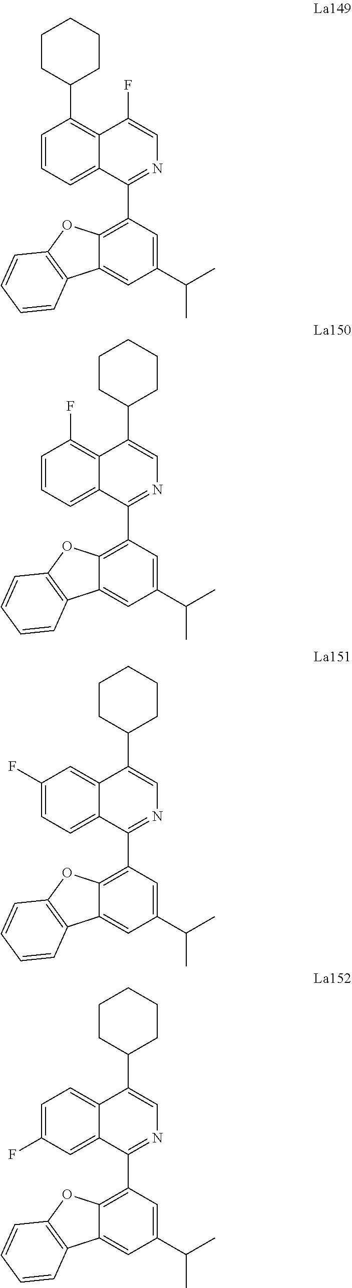 [SMILES: CC(C)c1cc(-c2ncc(F)c3c(C4CCCCC4)cccc23)c2oc3ccccc3c2c1 ; CC(C)c1cc(-c2ncc(C3CCCCC3)c3c(F)cccc23)c2oc3ccccc3c2c1 ; CC(C)c1cc(-c2ncc(C3CCCCC3)c3cc(F)ccc23)c2oc3ccccc3c2c1 ; CC(C)c1cc(-c2ncc(C3CCCCC3)c3ccc(F)cc23)c2oc3ccccc3c2c1]

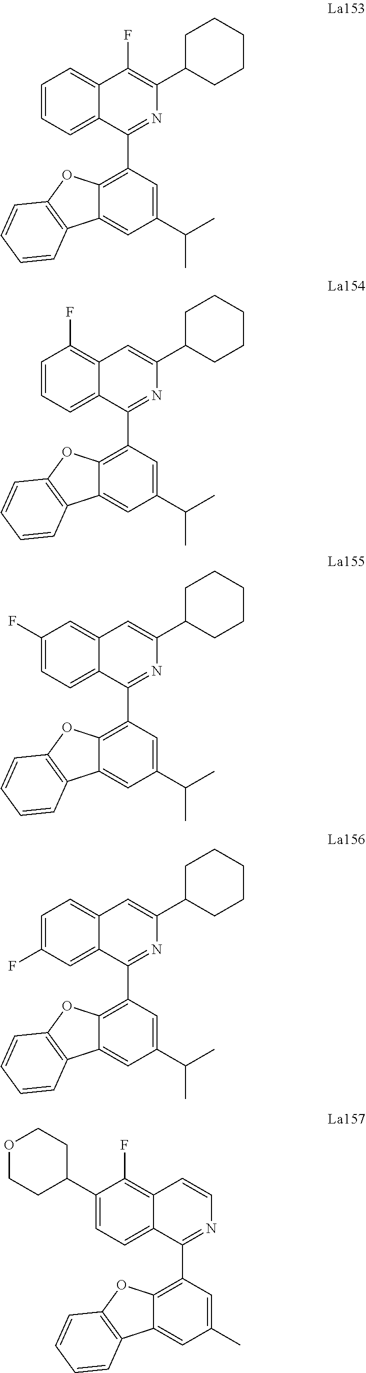

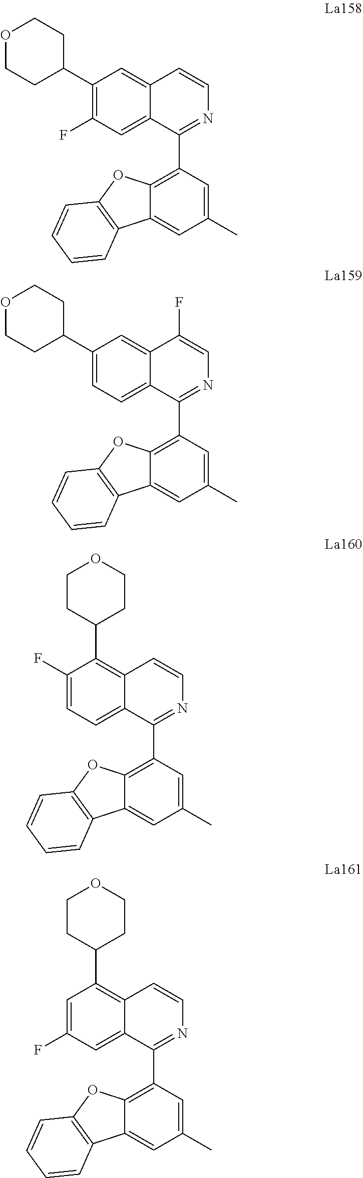

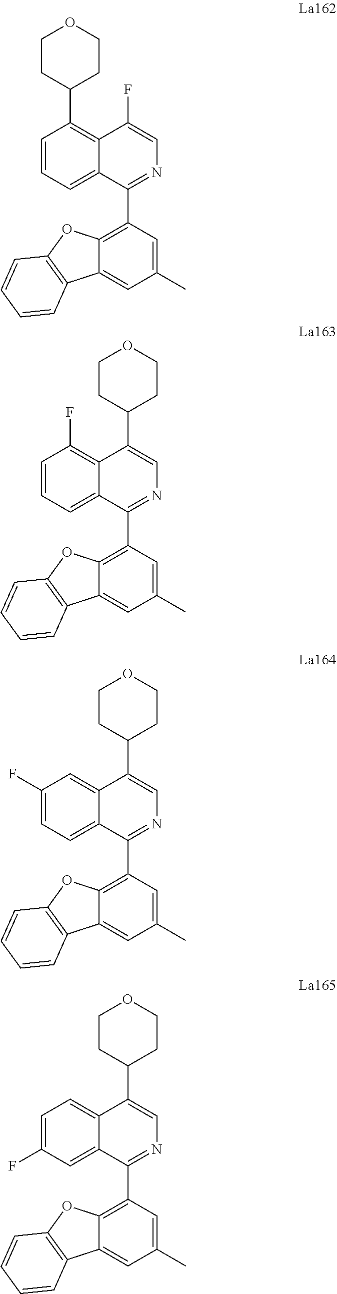 [SMILES: Cc1cc(-c2ncc(F)c3c(C4CCOCC4)cccc23)c2oc3ccccc3c2c1 ; Cc1cc(-c2ncc(C3CCOCC3)c3c(F)cccc23)c2oc3ccccc3c2c1 ; Cc1cc(-c2ncc(C3CCOCC3)c3cc(F)ccc23)c2oc3ccccc3c2c1 ; Cc1cc(-c2ncc(C3CCOCC3)c3ccc(F)cc23)c2oc3ccccc3c2c1]

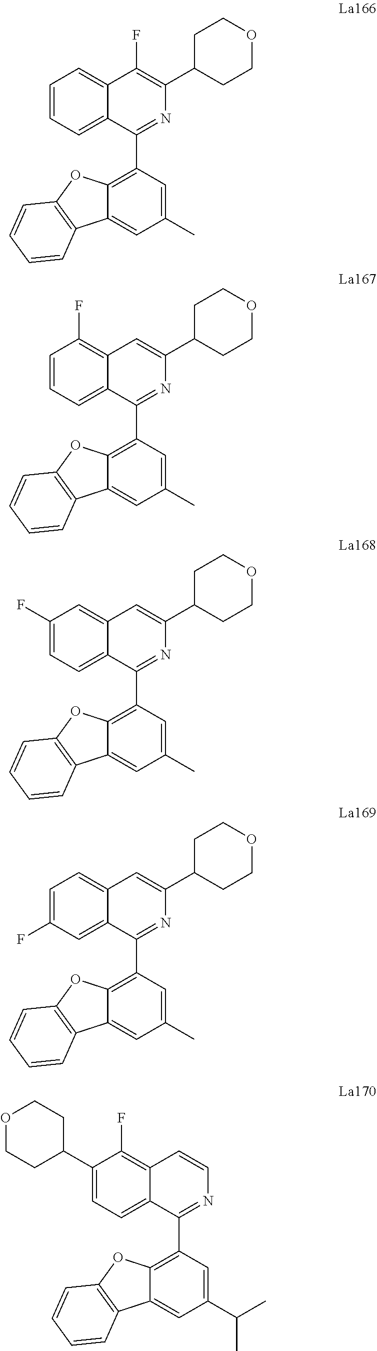

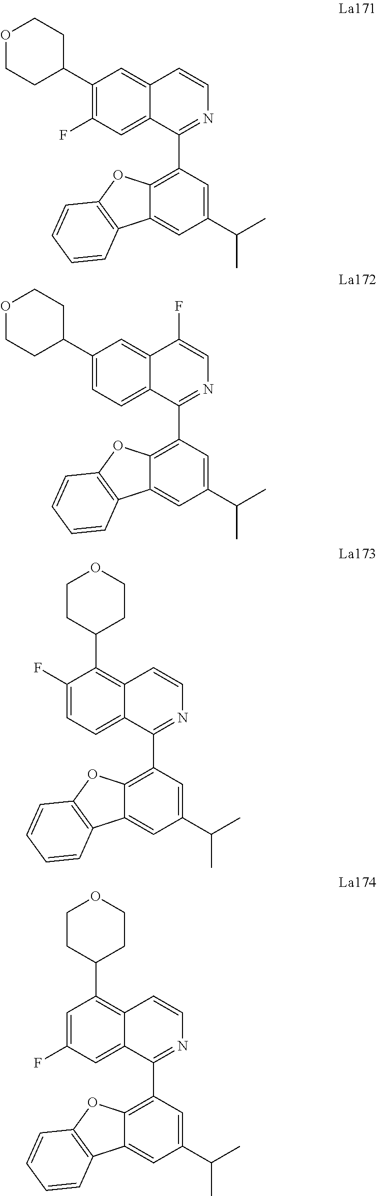

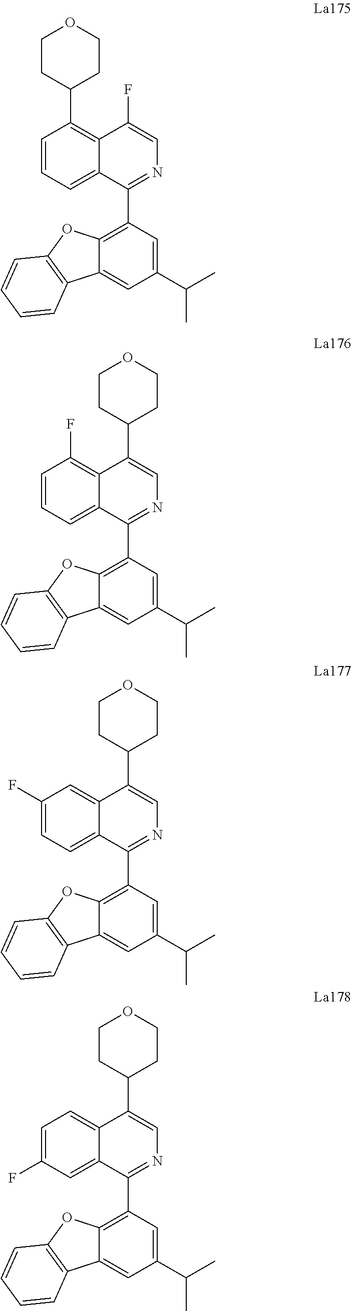 [SMILES: CC(C)c1cc(-c2ncc(F)c3c(C4CCOCC4)cccc23)c2oc3ccccc3c2c1 ; CC(C)c1cc(-c2ncc(C3CCOCC3)c3c(F)cccc23)c2oc3ccccc3c2c1 ; CC(C)c1cc(-c2ncc(C3CCOCC3)c3cc(F)ccc23)c2oc3ccccc3c2c1 ; CC(C)c1cc(-c2ncc(C3CCOCC3)c3ccc(F)cc23)c2oc3ccccc3c2c1]

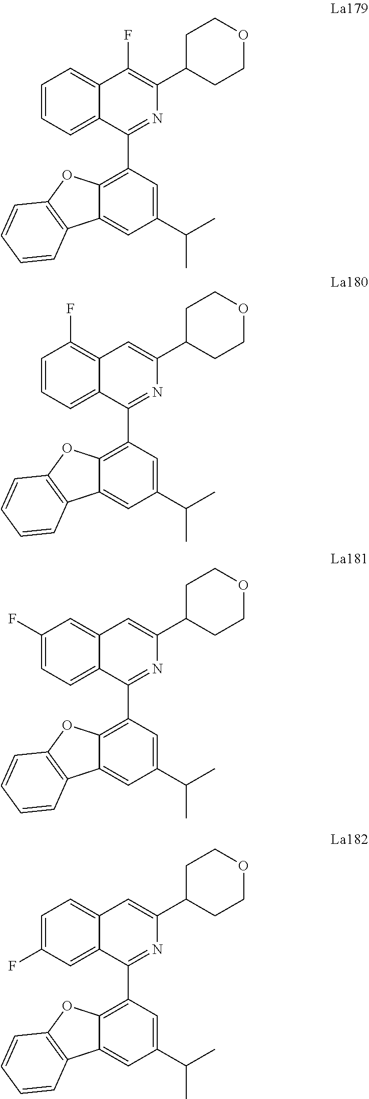

As a preferred iridium complex, the Lb is independently selected from one of the following structural formulas, corresponding parts or complete deuterides thereof, or corresponding parts or complete fluorides thereof:

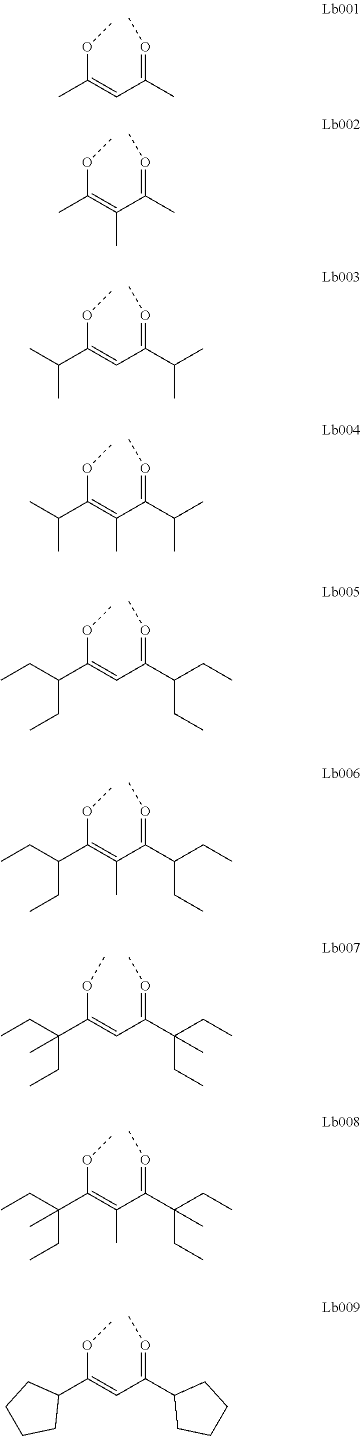

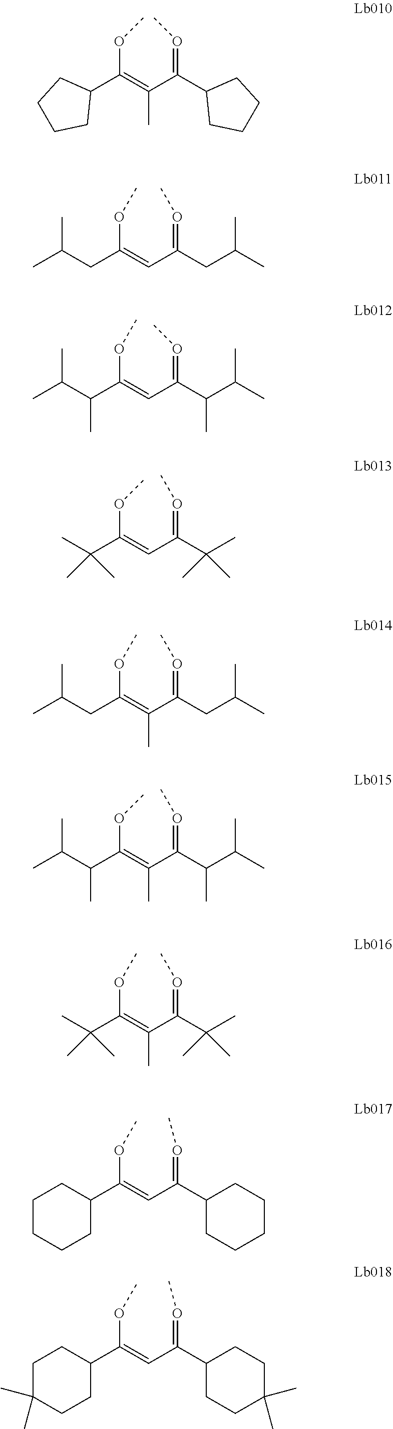

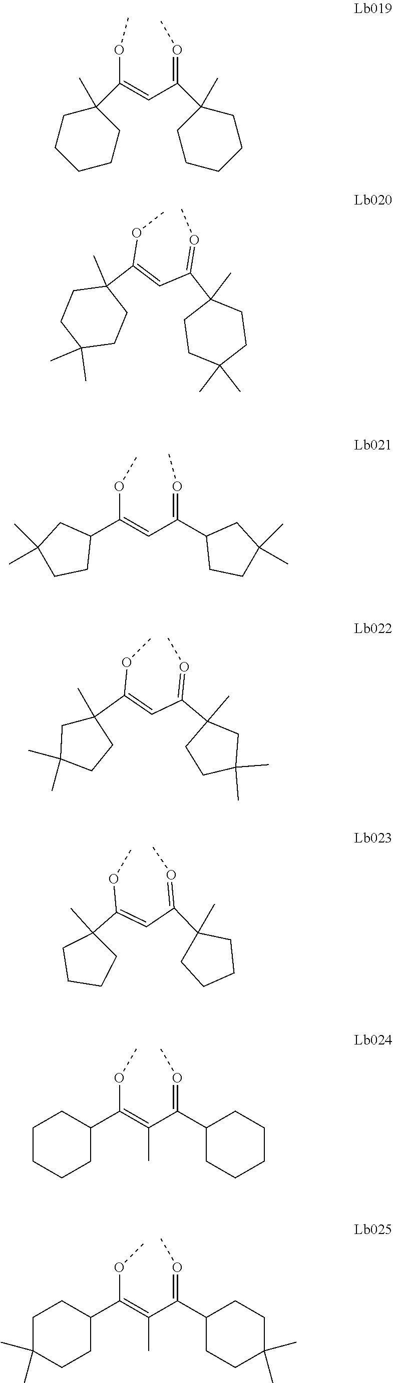

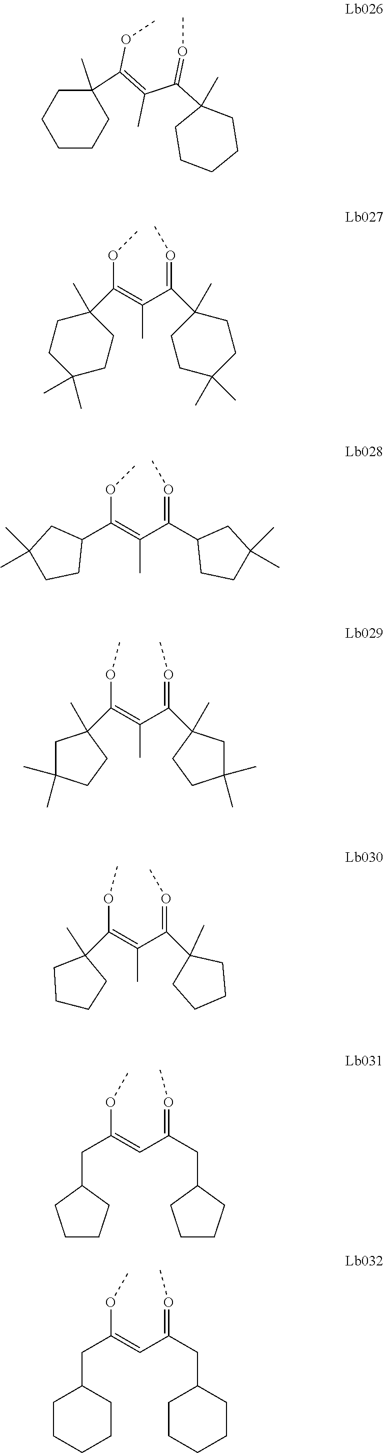

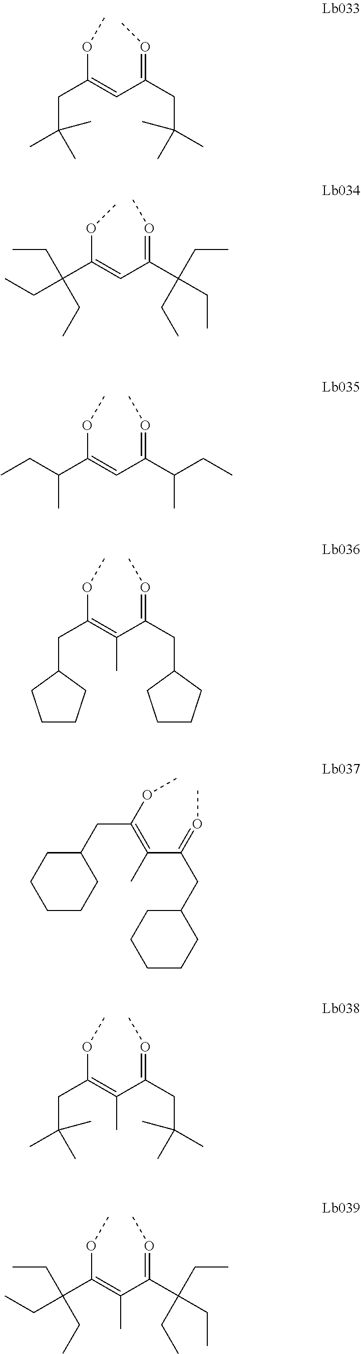

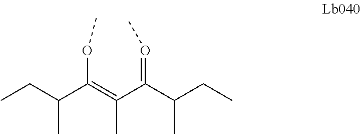

As a preferred iridium complex, the Lc is independently selected from any one of La001-La182, corresponding parts or complete deuterides thereof, or corresponding parts or complete fluorides thereof, and the La and the Lc do not have the same numbered structure simultaneously.

As a preferred iridium complex, the Lc is independently selected from the following structural formulas, or corresponding parts or complete deuterides or fluorides thereof:

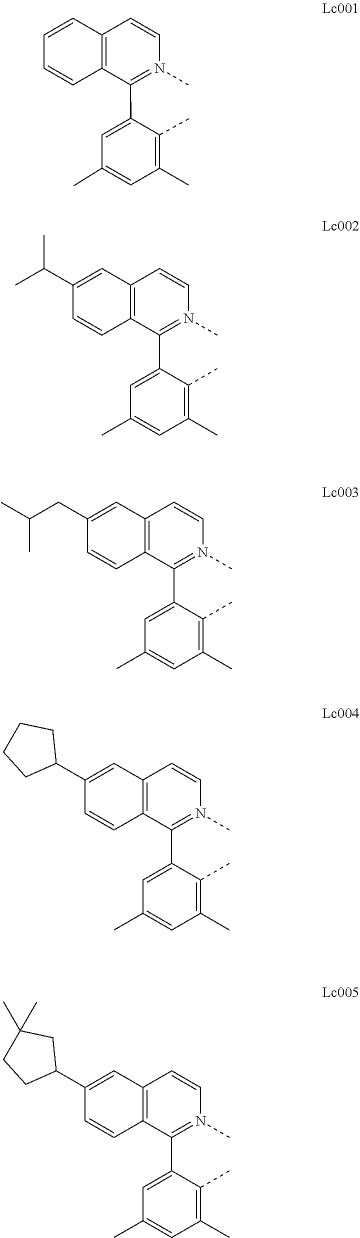

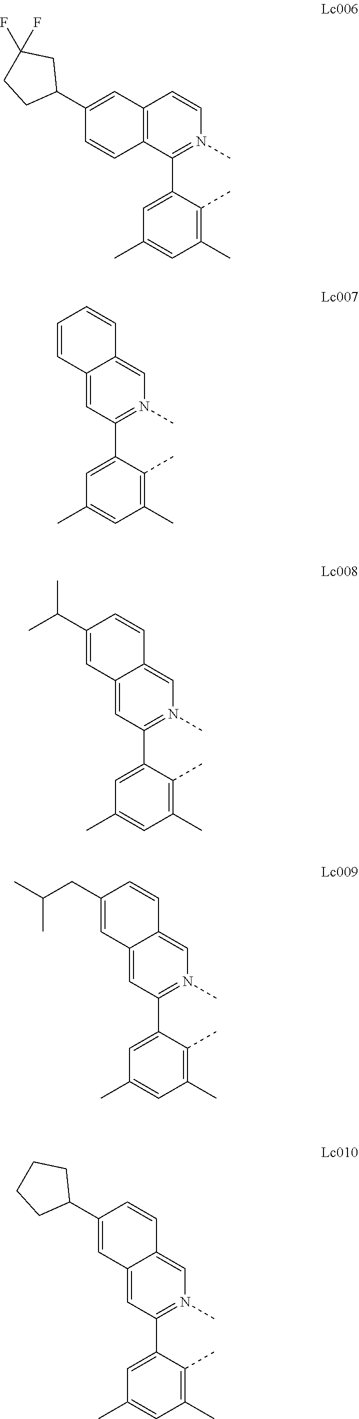

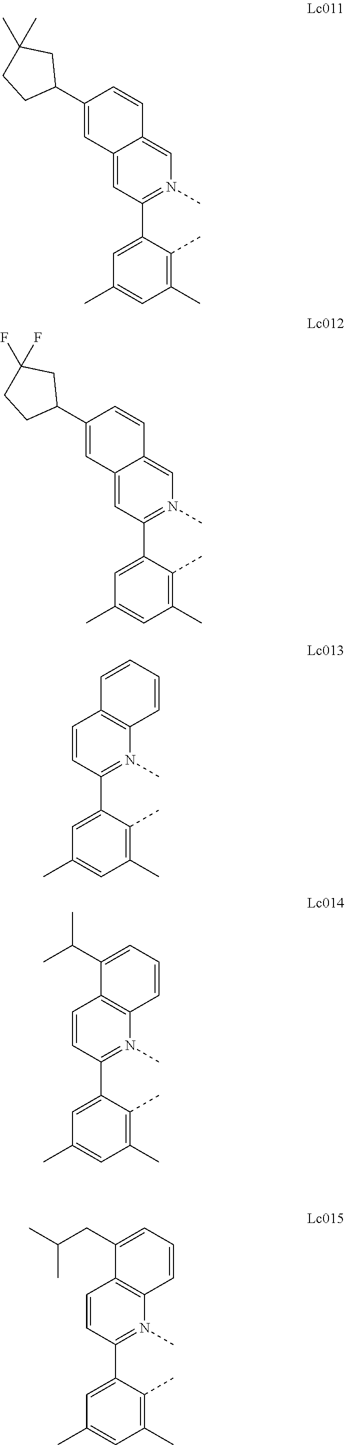

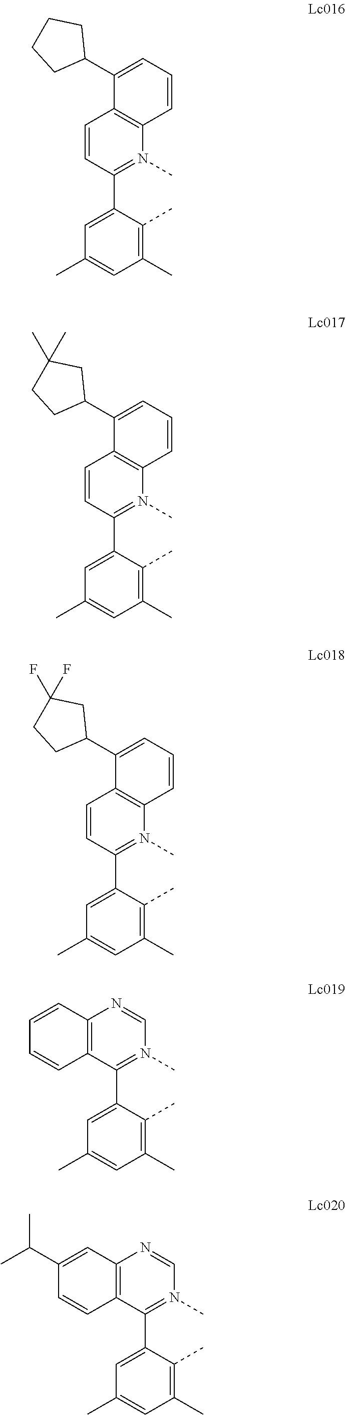

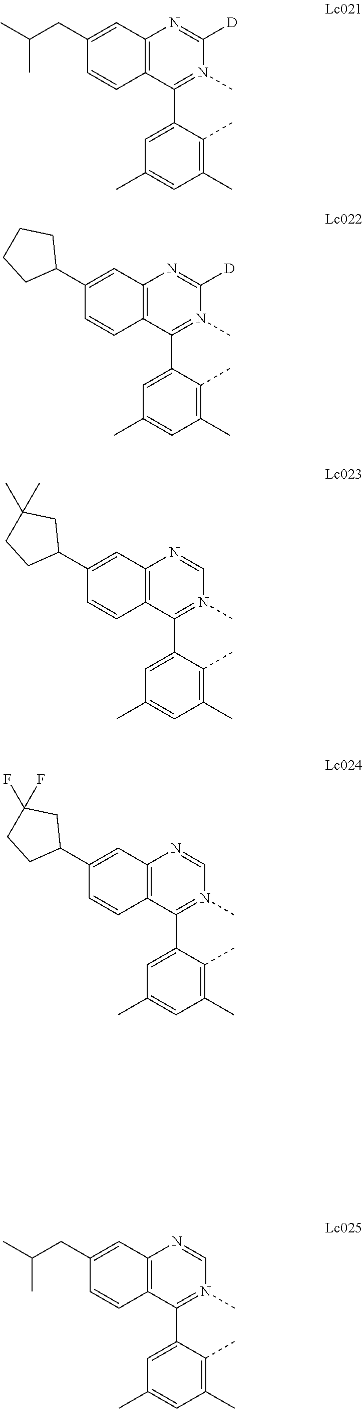

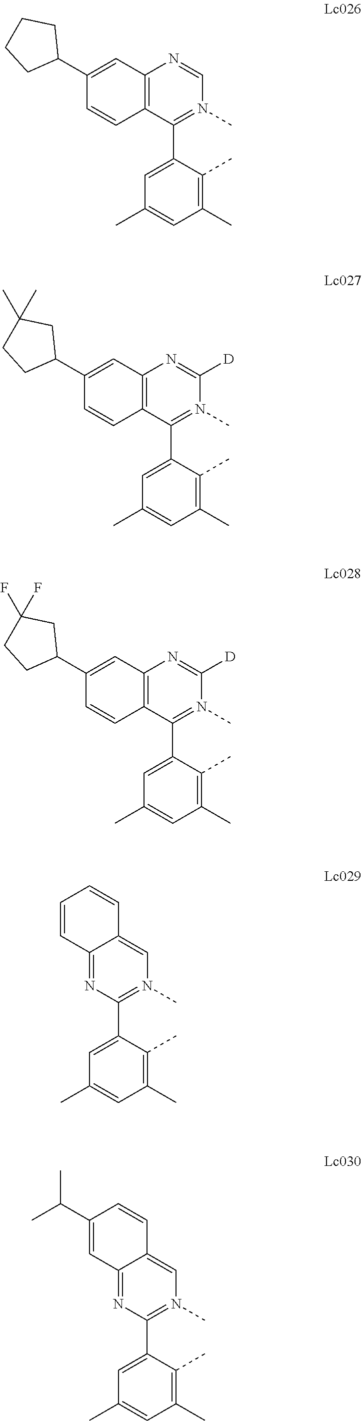

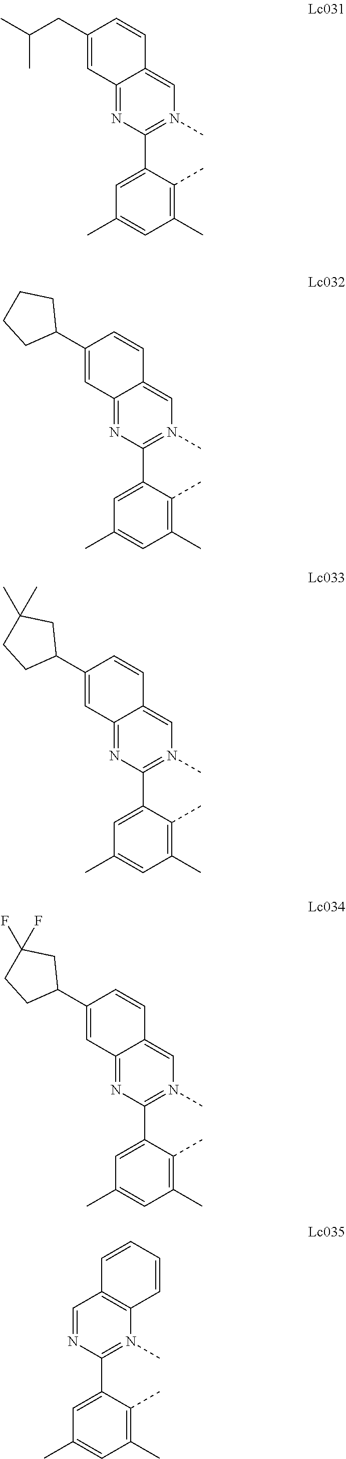

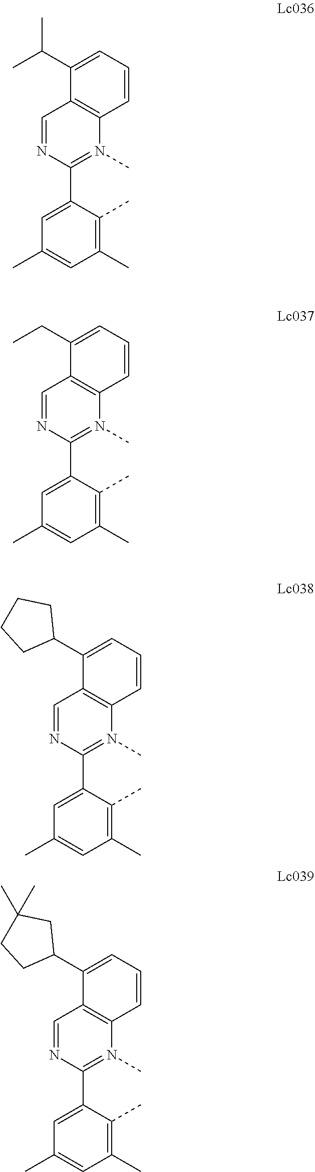

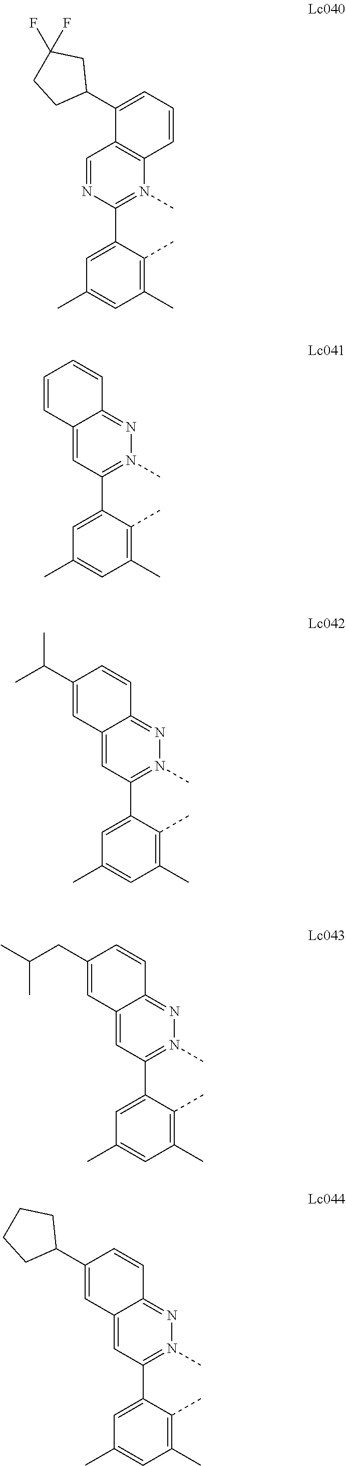

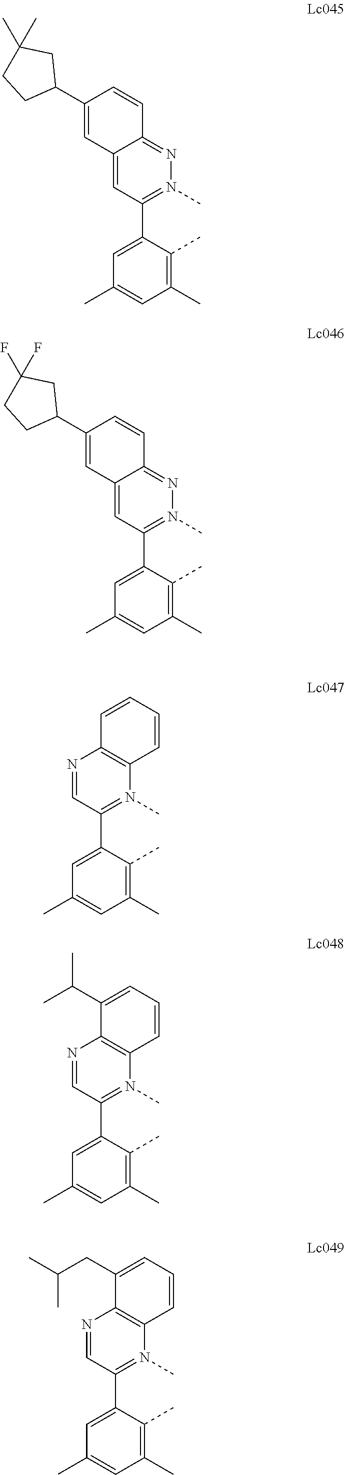

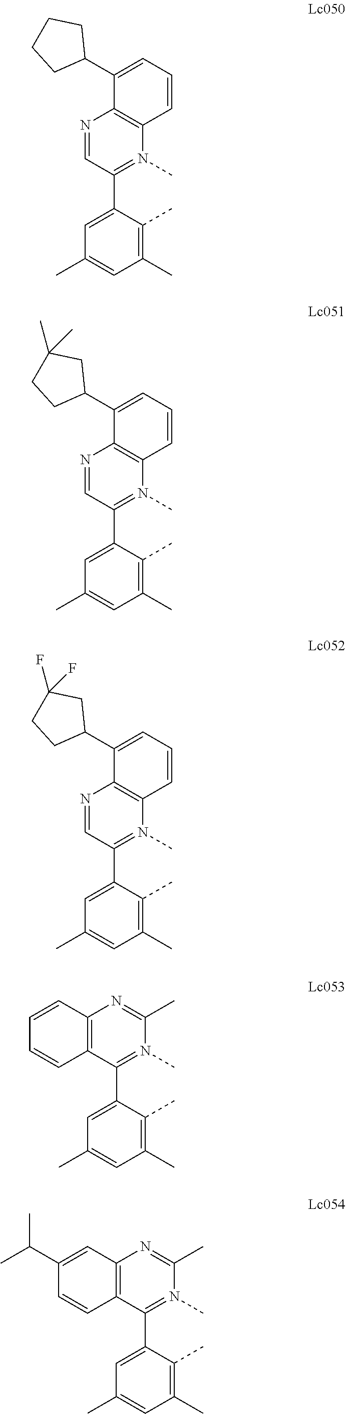

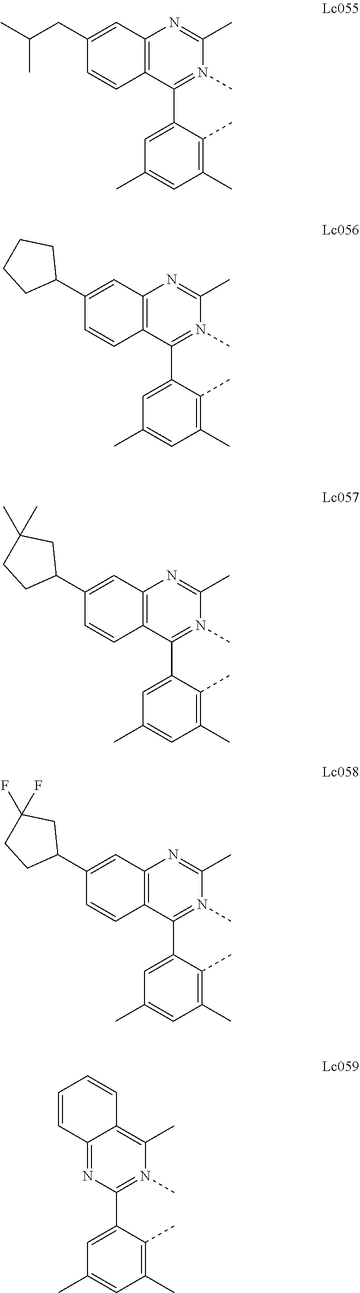

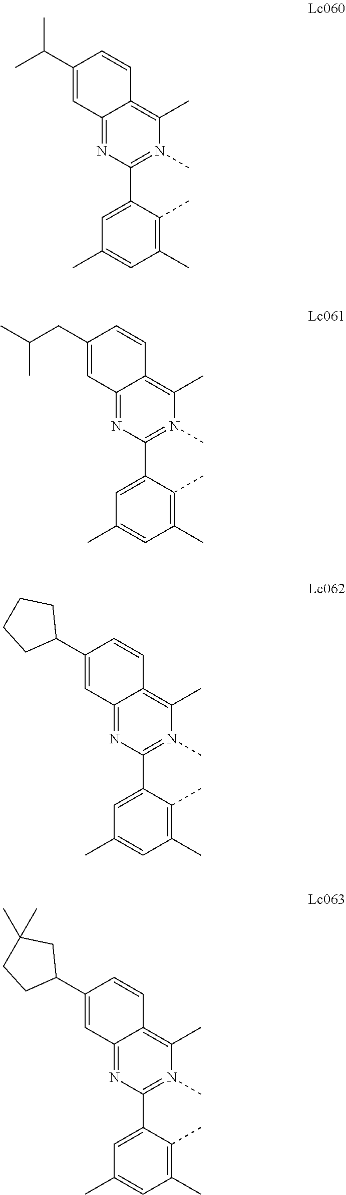

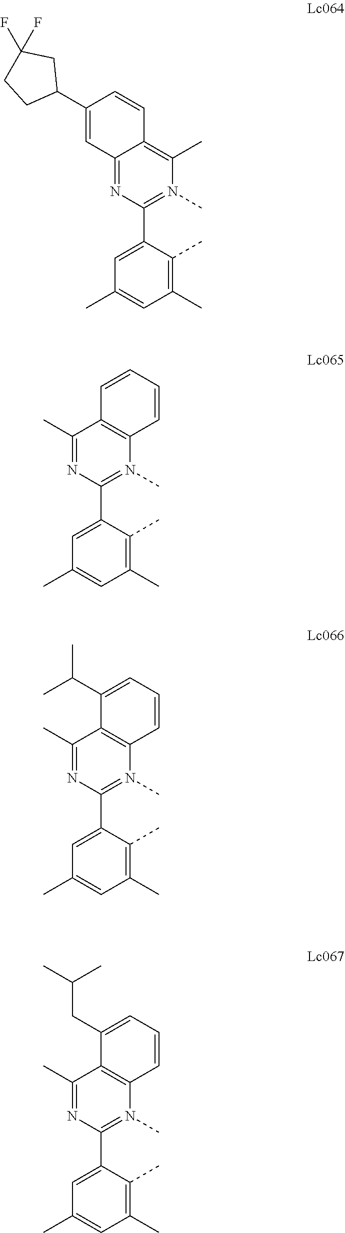

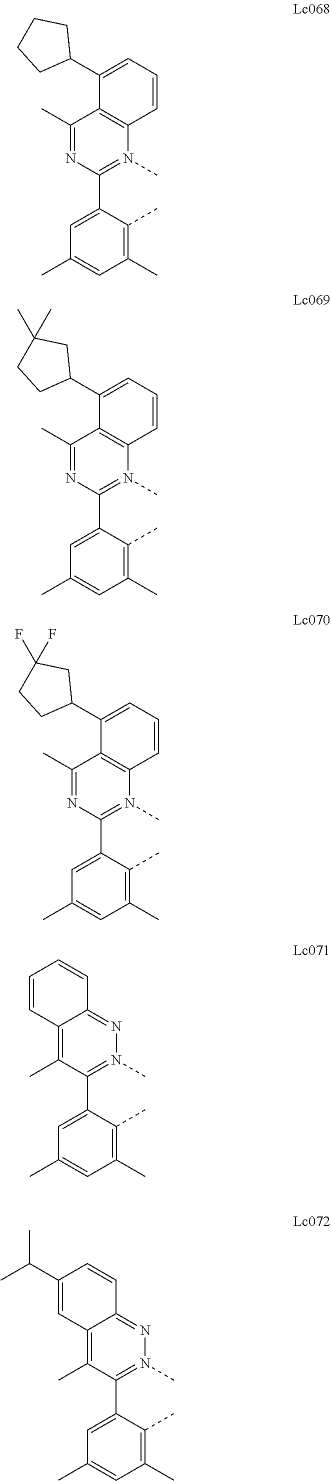

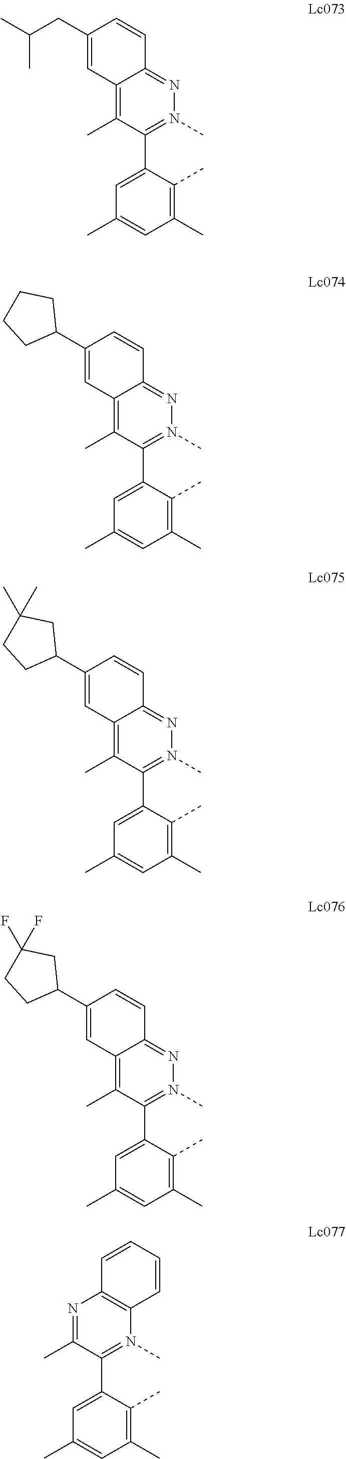

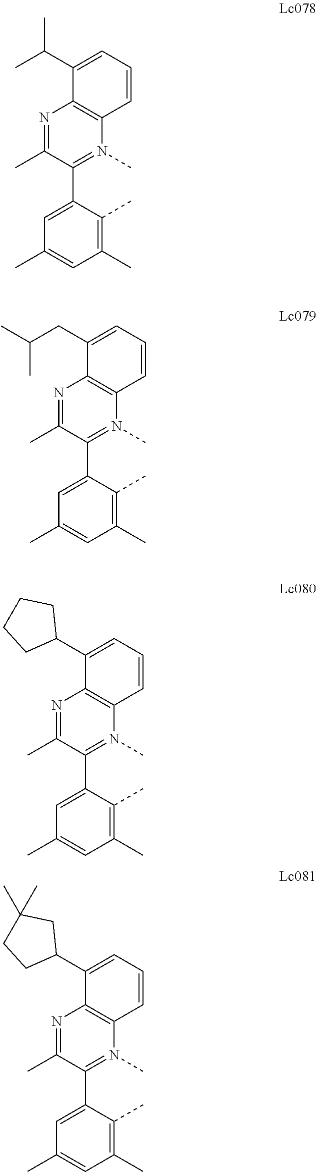

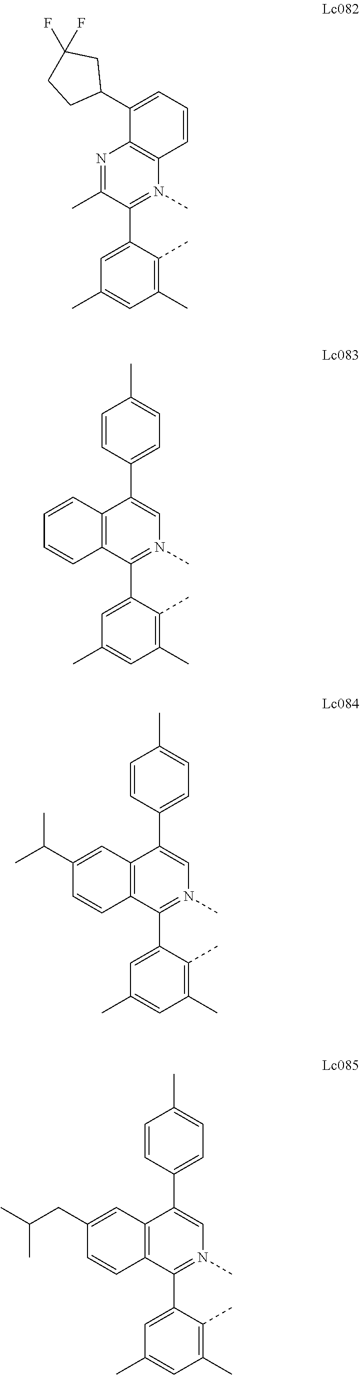

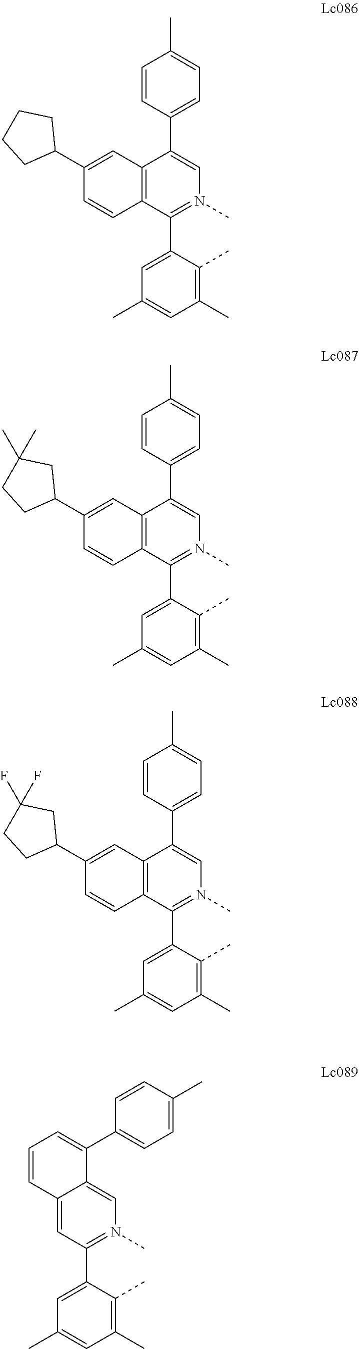

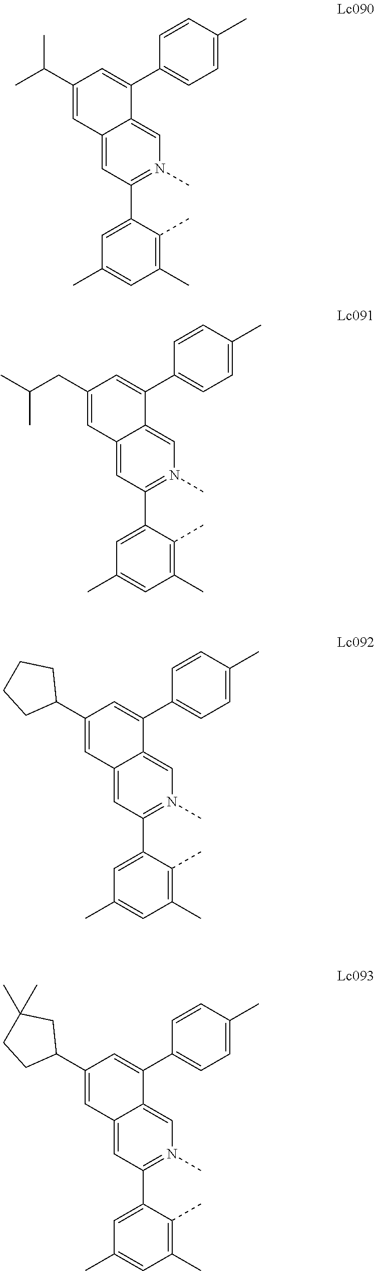

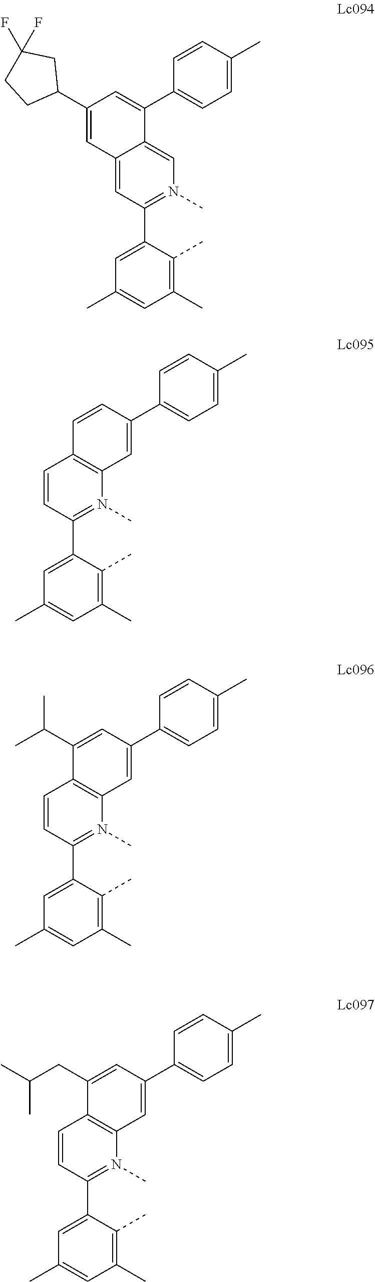

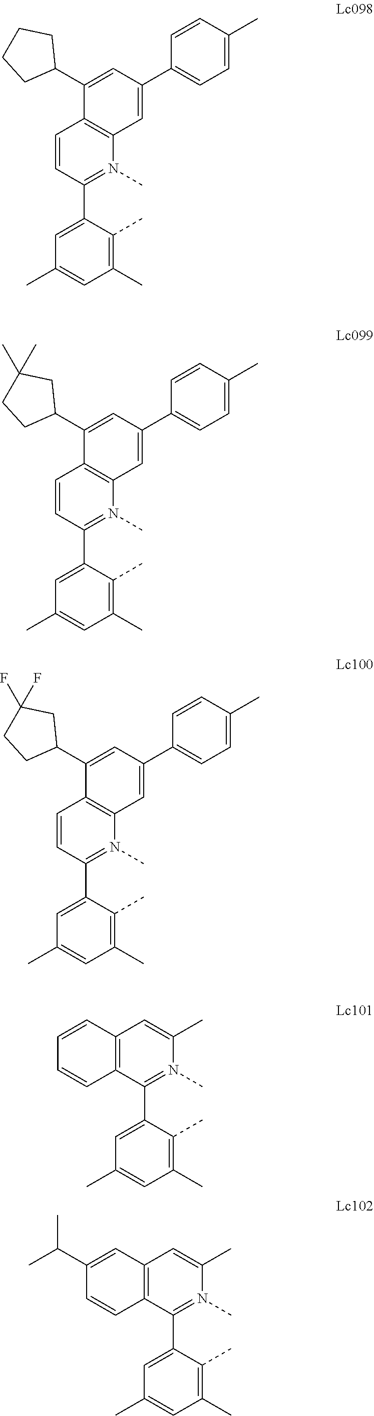

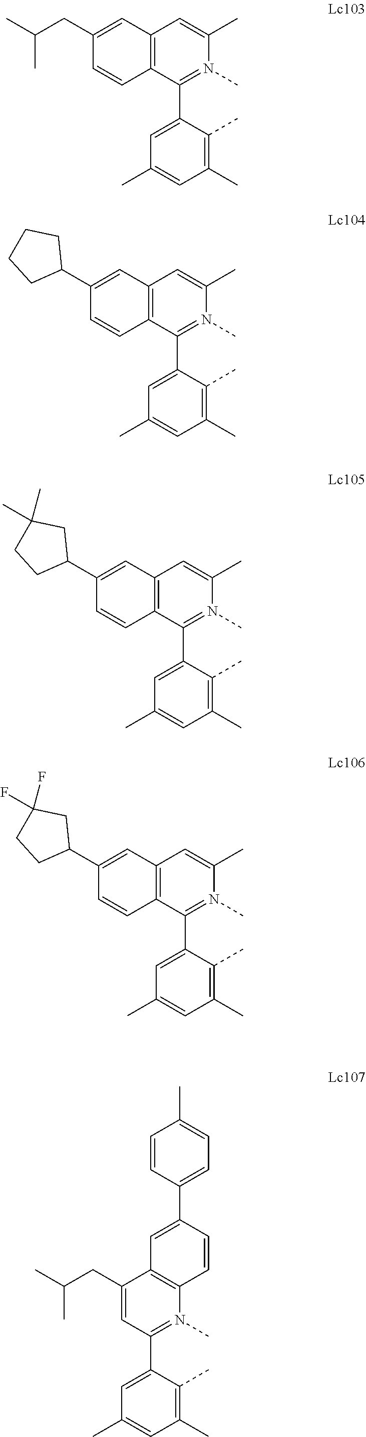

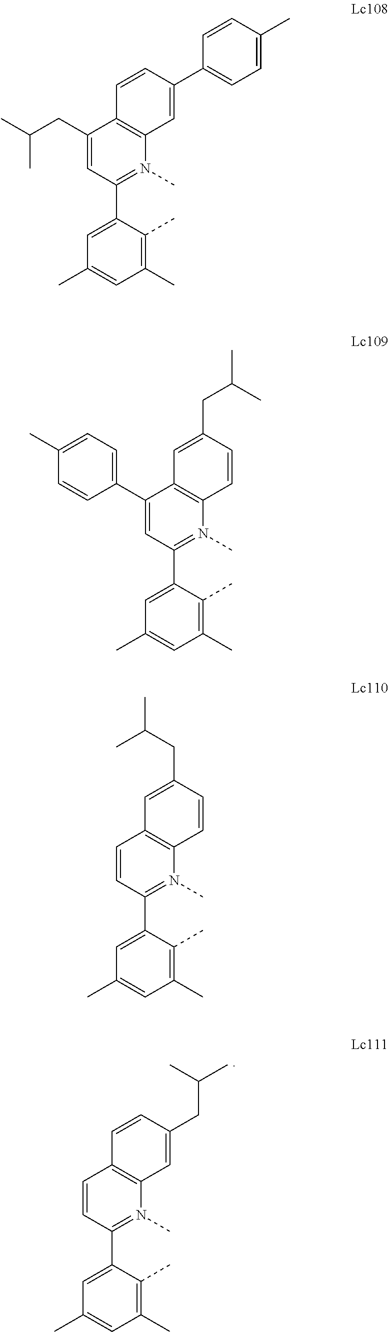

Another invention purpose of the present invention is to provide an electroluminescent device. The electroluminescent device includes a cathode, an anode, and organic layers arranged between the cathode and the anode. At least one of the organic layers includes the iridium complex.

Another invention purpose of the present invention is to provide an electroluminescent device, where the organic layers include a light-emitting layer, and the iridium complex is used a red light-emitting doping material for the light-emitting layer; or the organic layers include a hole injection layer, and the iridium complex is used as a hole injection material in the hole injection layer.

The material of the present invention has the advantages of low sublimation temperature, high optical and electrochemical stability, high color saturation, high luminous efficiency, and long device service life. As a phosphorescent material, the material of the present invention can convert a triplet excited state into light, so that the luminous efficiency of an organic electroluminescent device can be improved, and the energy consumption is reduced.

### DETAILED DESCRIPTION OF EMBODIMENTS

An iridium complex of the present invention has a structure of Ir(La)(Lb)(Lc),
where La, Lb, and Lc are different from each other, the “different from each other” refers to having different parent nuclear structures, having same parent nuclear structures but different substituents, or having same parent nuclear structures and same substituents but different positions of the substituents; all the La, the Lb, and the Lc are a monoanionic bidentate ligand, any two of the La, the Lb, and the Lc are connected to each other to form a multidentate ligand, or the La, the Lb, and the Lc are connected by a group;
the ligand La is as shown in a formula (1):

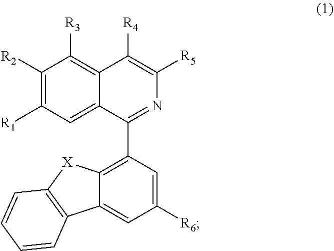

X is independently selected from O, S, and Se;
R₁-R₅ are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, substituted or unsubstituted C₃-C₂₀ heterocycloalkyl, substituted or unsubstituted C₃-C₃₀ alkylsilyl, substituted or unsubstituted C₁-C₁₀ alkoxyl, substituted or unsubstituted C₇-C₃₀ aralkyl, substituted or unsubstituted C₆-C₃₀ aryloxyl, substituted or unsubstituted C₂-C₂₀ alkenyl, substituted or unsubstituted C₂-C₂₀ alkynyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino;
at least one of the R₁-R₅ is F, and another one is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;

R₆ is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;
the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino;
and the heteroalkyl, the heterocycloalkyl, or the heteroaryl includes at least one of S, O, and N heteroatoms.

The Lb has a structure as shown in a formula (2):

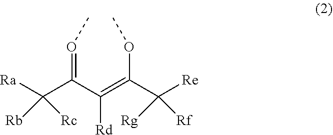

where a dotted line refers to a position connected to metal Ir;
Rₐ-R_{g} are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocycloalkyl, or any two of Rₐ, R_{b}, and R_{c} are connected to each other to form an aliphatic ring structure, and any two of Rₑ, R_{f}, and R_{g} are connected to each other to form an aliphatic ring structure; the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino; and the heteroalkyl or the heterocycloalkyl includes at least one of S, O, and N heteroatoms.

The Rₐ , the R_{b}, and the R_{c} are the same as the Rₑ, the R_{f}, and the R_{g}, respectively.

The Rₐ-R_{g} are independently selected from hydrogen, deuterium, halogen, substituted or unsubstituted alkyl containing 1-10 carbon atoms on a main chain, and substituted or unsubstituted cycloalkyl containing 3-20 ring forming carbon atoms, or any two of the Rₐ , the R_{b}, and the R_{c} are connected to each other to form an aliphatic ring structure, and any two of the Rₑ, the R_{f}, and the R_{g} are connected to each other to form an aliphatic ring structure; and the “substituted” refers to substitution with deuterium, F, Cl, Br, C₁-C₄ alkyl, or C₃-C₆ cycloalkyl.

R_{d} is selected from hydrogen, deuterium, halogen, and substituted or unsubstituted alkyl containing 1-10 carbon atoms on a main chain.

As a preferred iridium complex, the Lc has any one structure as shown in a formula (3) to a formula (5):

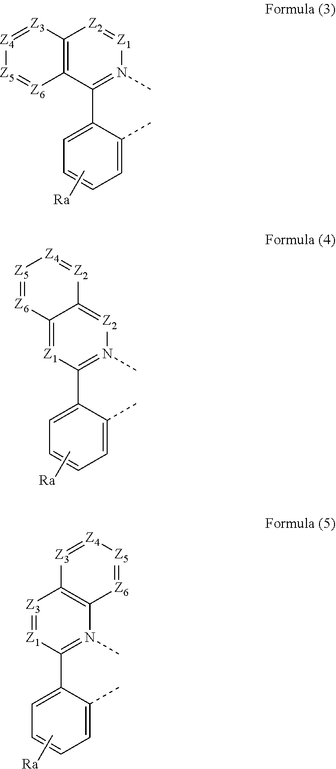

where Z₁-Z₆ are independently N or CR₀;
the number of Rₐ ranges from a minimum substitution number to a maximum substitution number;
R₀ and the Rₐ are independently selected from hydrogen, deuterium, halogen, substituted or unsubstituted C₁-C₂₀ alkyl, substituted or unsubstituted C₃-C₃₀ cycloalkyl, substituted or unsubstituted C₁-C₃₀ heteroalkyl, substituted or unsubstituted C₃-C₂₀ heterocycloalkyl, substituted or unsubstituted C₇-C₃₀ aralkyl, substituted or unsubstituted C₁-C₂₀ alkoxyl, substituted or unsubstituted C₆-C₃₀ aryloxyl, substituted or unsubstituted C₂-C₂₀ alkenyl, substituted or unsubstituted C₃-C₃₀ alkylsilyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino, or two adjacent substituents may be optionally connected to form a ring or a fused structure;
the “substituted” refers to substitution with deuterium, F, Cl, Br, C₁-C₁₀ alkyl, C₁-C₁₀ alkoxyl, C₃-C₁₀ cycloalkyl, amino substituted with C₁-C₁₀ alkyl, C₆-C₃₀ aryl, C₇-C₃₀ aralkyl, cyano, nitrile, isonitrile, or phosphino; and the heteroalkyl, the heterocycloalkyl, or the heteroaryl includes at least one of S, O, and N heteroatoms.

As a preferred iridium complex, at least two of the Rₐ are not hydrogen.

As a preferred iridium complex, at least one of the Z₁-Z₆ is CR₀.

As a preferred iridium complex, the Rₐ is substituted or unsubstituted C₁-C₈ alkyl, the R₀ is selected from substituted or unsubstituted C₁-C₈ alkyl and substituted or unsubstituted C₃-C₆ cycloalkyl, and the “substituted” refers to substitution with deuterium, F, Cl, Br, or C₁-C₄ alkyl.

As a preferred iridium complex, the R₆ is substituted or unsubstituted C₁-C₄ alkyl, or substituted or unsubstituted C₃-C₆ cycloalkyl.

As a preferred iridium complex, the F is not positioned at the R₅.

The X is an O atom.

As a preferred iridium complex, one of the R₁-R₅ is F, another one is substituted or unsubstituted alkyl containing no more than 4 carbon atoms on a main chain, or substituted or unsubstituted cycloalkyl containing no more than 6 ring forming carbon atoms, and the other three are hydrogen.

As a preferred iridium complex, when one of the R₁-R₅ is F, another one is branched C₁-C₄ alkyl substituted with C₁-C₄ alkyl.

Examples of various groups of the compound as shown in the formula (1) to the formula (5) are described below.

It should be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, preferably methyl, ethyl, propyl, isopropyl, n-butyl, isobutyl, sec-butyl, and tert-butyl, and more preferably propyl, isopropyl, isobutyl, sec-butyl, and tert-butyl.

The C₃-C₂₀ cycloalkyl may include cyclopropyl, cyclobutyl, cyclopentyl, cyclohexyl, 1-adamantyl, 2-adamantyl, 1-norbornyl, and 2-norbornyl, preferably cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, preferably propeny and allyl.

As a linear or branched alkyl or cycloalkyl consisting of atoms other than carbon and hydrogen, the C₁-C₁₀ heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, preferably methoxymethyl and epoxy pentyl.

The C₃-C₁₀ heterocycloalkyl may include oxacyclopropyl, thiocyclobutyl, azacyclopentyl, oxacyclopentyl, oxacyclohexyl, dioxacyclohexyl and the like, preferably oxacyclopentyl and oxacyclohexyl. Specific examples of the aryl include phenyl, naphthyl, anthracyl, phenanthryl, tetracenyl, pyrenyl, chrysenyl, benzo [c]phenanthryl, benzo [g]chrysenyl, fluorenyl, benzofluorenyl, dibenzofluorenyl, biphenyl, triphenyl, tetraphenyl, and fluoranthracyl, preferably phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, preferably pyridyl, pyrimidinyl, triazinyl, dibenzofuryl, dibenzothienyl, azodibenzofuryl, azodibenzothienyl, diazodibenzofuryl, diazodibenzothienyl, carbazolyl, azocarbazolyl, and diazocarbazolyl.

The following embodiments are merely described to facilitate the understanding of the technical invention, and should not be considered as specific limitations of the present invention.

All raw materials, solvents and the like involved in the synthesis of compounds in the present invention are purchased from Alfa, Acros, and other suppliers known to persons skilled in the art.

### Synthesis of a Compound La001

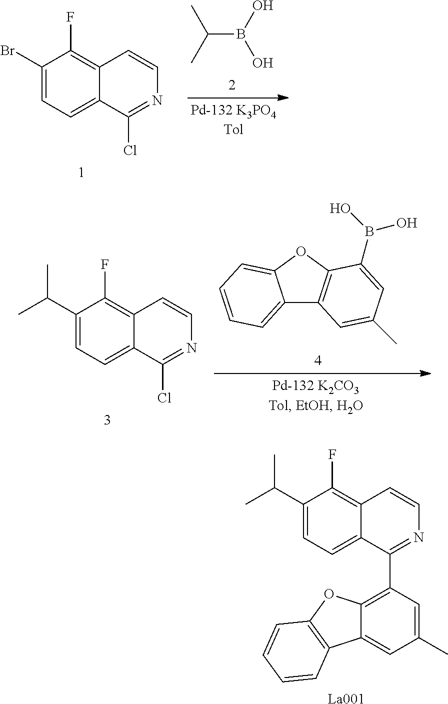

### Synthesis of a Compound 3

A compound 1 (45.00 g, 172.75 mmol, 1.0 eq), a compound 2 (22.78 g, 259.13 mmol, 1.5 eq), dichloroldi-tert-butyl-(4-dimethylaminophenyl)phosphinol palladium (II) (6.12 g, 8.64 mmol, 0.05 eq), anhydrous potassium phosphate (91.67 g, 431.88 mmol, 2.5 eq), and toluene (675 ml) were added into a 1 L three-mouth flask, vacuumization was conducted for the replacement of nitrogen for 3 times, and the above compounds were stirred for a reaction at 100° C. for 4 hours under the protection of nitrogen. According to monitoring by TLC, the compound 1 was completely reacted. After cooling was conducted to room temperature, concentration was conducted under reduced pressure to remove an organic solvent, dichloromethane (337 ml) and deionized water (160 ml) were added for extraction, spin drying was conducted, and separation was conducted by column chromatography (with a mixture of ethyl acetate and n-hexane at a ratio of 1:100 as an eluting agent). Then, concentration was conducted to obtain 23.32 g of a light yellow sugar solid, namely compound 3, with a yield of 60.35%. The mass spectrum was: 224.67 (M+H).

### Synthesis of a Compound La001

The compound 3 (22.00 g, 98.36 mmol, 1.0 eq), a compound 4 (24.46 g, 108.19 mmol, 1.1 eq), dichloroldi-tert-butyl-(4-dimethylaminophenyl)phosphinol palladium (II) (3.48 g, 4.92 mmol, 0.05 eq), potassium carbonate (27.19 g, 196.71 mmol, 2.00 eq), toluene (330 ml), ethanol (110 ml), and deionized water (110 ml) were added into a 1 mL three-mouth flask, vacuumization was conducted for the replacement of nitrogen for 3 times, and the above compounds were stirred for a reaction at 70° C. for 1.5 hour under the protection of nitrogen. According to monitoring by TLC, the compound 3 was completely reacted. After cooling was conducted to room temperature, concentration was conducted under reduced pressure to remove an organic solvent, dichloromethane (420 ml) and deionized water (180 ml) were added for extraction, spin drying was conducted, and separation was conducted by column chromatography (with a mixture of ethyl acetate and n-hexane at a ratio of 1.5:100 as an eluting agent). Then, concentration was conducted to obtain 23.88 g of a white solid, namely compound La001, with a yield of 65.71%. The mass spectrum was: 370.43 (M+H).

### Synthesis of a Compound Lc002

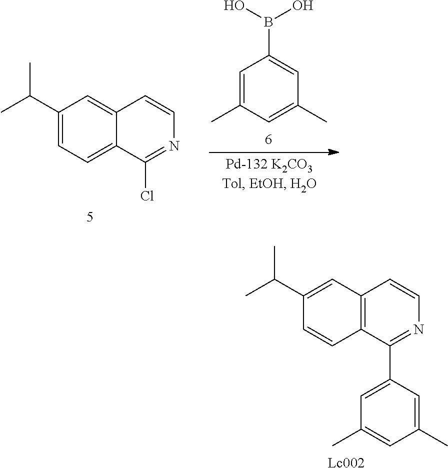

With reference to the synthesis and purification methods of the compound La001, only the corresponding raw materials were required to be changed, and a target compound Lc002 was obtained. The mass spectrum was 276.39 (M+H).

### Synthesis of a Compound Ir(La001)(Lb031)(Lc002)

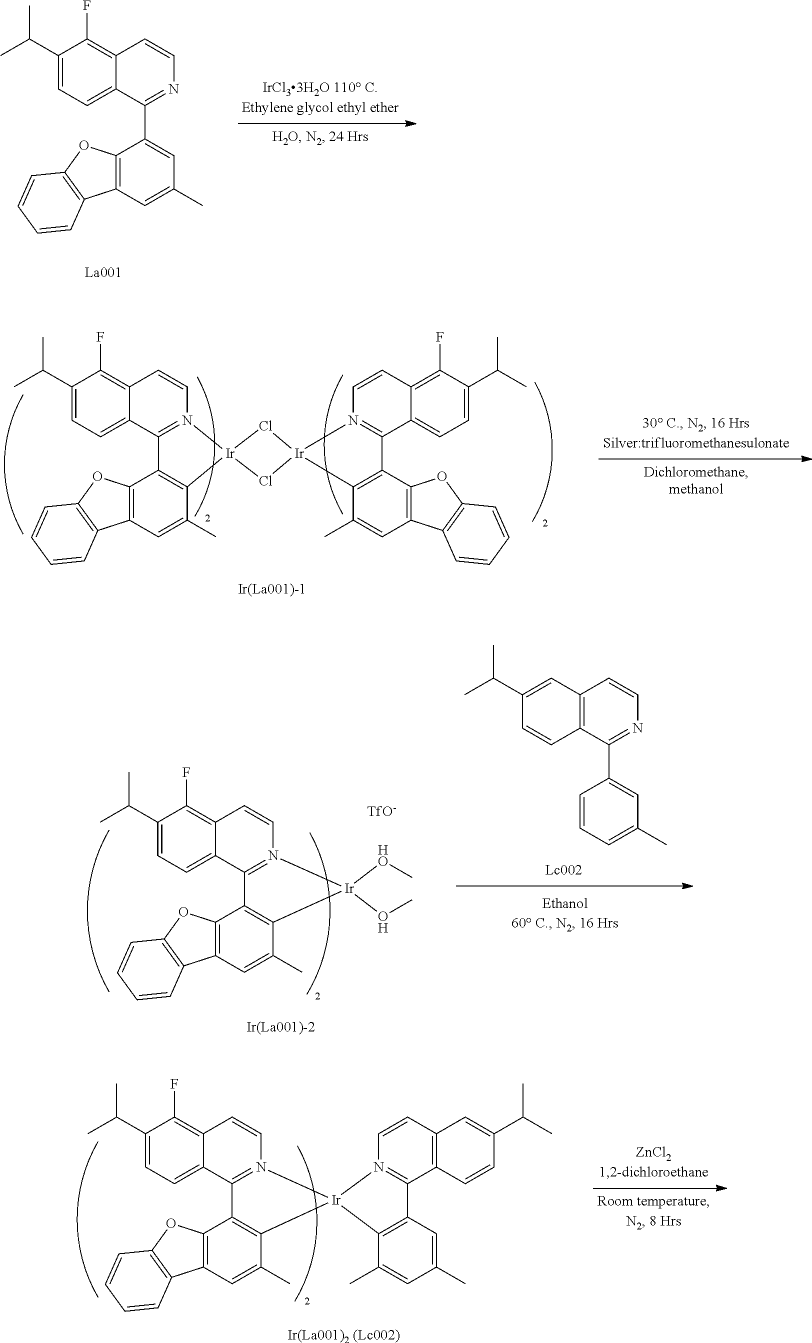

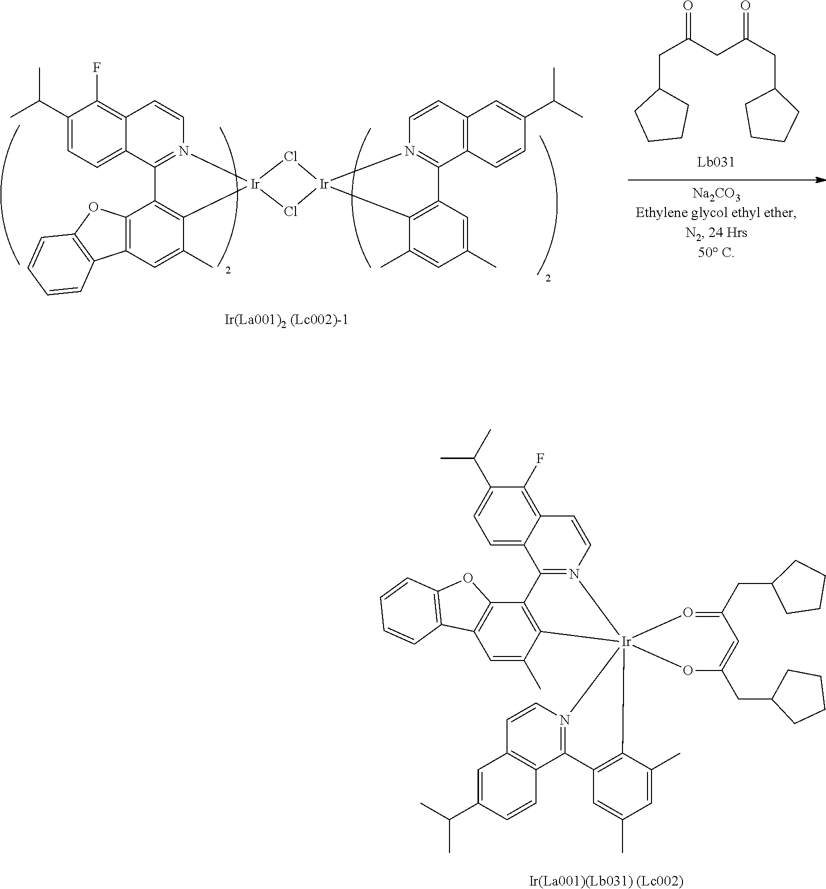

### Synthesis of a Compound Ir(La001)-1

The compound La001 (21.5 g, 58.20 mmol, 3.5 eq) and IrCl₃.3H₂O (5.86 g, 16.63 mmol, 1.0 eq) were placed into a 1 L round-bottomed one-mouth flask, ethylene glycol ethyl ether (322 ml) and deionized water (107 ml) were added, vacuumization was conducted for replacement for 3 times, and a resulting mixture was stirred at 110° C. for 24 hours under the protection of N₂. After cooling was conducted to room temperature, concentration was conducted to remove a solvent, DCM (450 ml) was added for dissolution, filtration was conducted with silica gel, and a filtrate was washed with deionized water. Then, an organic phase was concentrated to obtain 14.65 g of a dark red oily substance, namely compound Ir(La001)-1, with a yield of 91.34%. The obtained compound was directly used in the next step without further purification.

### Synthesis of a Compound Ir(La001)-2

The dimer Ir(La001)-1 (13.55 g, 14.05 mmol, 1.0 eq) and dichloromethane (1.1 L) were added into a 3 L three-mouth flask, and stirred for dissolution. Silver trifluoromethanesulfonate (7.22 g, 28.10 mmol, 2.0 eq) was dissolved in methanol (720 ml) and then added into an original solution in the reaction flask, vacuumization was conducted for replacement for 3 times, and a resulting mixture was stirred at room temperature for 16 hours under the protection of N₂. Then, a resulting reaction solution was filtered by diatomite, a filtrate residue was washed with dichloromethane (300 ml), and a filtrate was spin-dried to obtain 11.65 g of a compound Ir(La001)-2 with a yield of 72.65%. The obtained compound was directly used in the next step without purification.

### Synthesis of a Compound Ir(La001)₂(Lc002)

The compound Ir(La001)-2 (6.85 g, 6.0 mmol, 1.0 eq) and the Lc002 (4.13 g, 15.01 mmol, 2.5 eq) were added into a 250 ml three-mouth flask, ethanol (75 ml) was added, vacuumization was conducted for replacement for 3 times, and a resulting mixture was stirred for reflux for 16 hours under the protection of N₂. After cooling was conducted to room temperature, filtration was conducted, a solid was collected, dissolved in dichloromethane (150 ml) and filtered by silica gel. Then, a filter cake was rinsed with dichloromethane (50 ml), and a filtrate was spin-dried, recrystallized with tetrahydrofuran/methanol (the ratio of the product to tetrahydrofuran to methanol was 1:5:10) for 2 times, and dried to obtain 3.46 g of a compound Ir(La001)₂(Lc002) with a yield of 47.85%. The mass spectrum was: 1204.44 (M+H).

### Synthesis of a Compound Ir(La001)₂(Lc002)-1

The compound Ir(La001)₂(Lc002) (3.45 g, 2.87 mmol, 1.0 eq) and zinc chloride (19.54 g, 143.34 mmol, 50 eq) were added into a 1 L one-mouth flask, 1,2-dichloroethane (207 ml) was added, vacuumization was conducted for replacement for 3 times, and a resulting mixture was stirred for reflux for a reaction for 18 hours under the protection of N₂. According to monitoring by a TLC point plate, the raw material Ir(La001)₂(Lc002) was basically and completely reacted. After cooling was conducted to room temperature, deionized water (250 ml) was added for washing for 3 times. Then, a filtrate was spin-dried to obtain 2.14 g of a compound Ir(La001)₂(Lc002)-1 with a yield of 85.69%. The obtained compound was directly used in the next step without purification.

### Synthesis of a Compound Ir(La001)(Lb031)(Lc002)

The compound Ir(La001)₂(Lc002)-1 (3.22 g, 3.7 mmol, 1.0 eq), Lb031 (4.37 g, 18.5 mmol, 5.0 eq), and sodium carbonate (3.92 g, 36.99 mmol, 10.0 eq) were placed in a 250 ml round-bottomed one-mouth flask, ethylene glycol ethyl ether (64 ml) was added, vacuumization was conducted for replacement for 3 times, and a resulting mixture was stirred at 50° C. for 24 hours under the protection of N₂. According to monitoring by TLC, the Ir(La001)₂(Lc002)-1 was completely reacted. After cooling was conducted to room temperature, 128 ml of methanol was added for beating at room temperature for 2 hours. Suction filtration was conducted, a filter cake was dissolved in dichloromethane (80 ml) and filtered by silica gel, and a filtrate was washed with deionized water (60 ml). After liquid layering was conducted, an organic phase was collected, concentrated and dried to obtain a dark red solid. Then, the dark red solid was recrystallized with tetrahydrofuran/methanol (a ratio of the product to tetrahydrofuran to methanol was 1:5:8) for 3 times to obtain 1.6 g of a red solid, namely compound Ir(La001)(Lb031)(Lc002), with a yield of 40.35%. 1.6 g of the crude product (La001)(Lb031)(Lc002) was sublimated and purified to obtain 0.91 g of sublimated pure Ir(La001)(Lb031)(Lc002) with a yield of 56.87%. The mass spectrum was: 1071.36 (M+H). ¹H NMR (400 MHz, CDCl₃) δ 8.86 (d, J=15.0 Hz, 2H), 8.24(s, 1H), 7.98 (d, 1H), 7.75 (m, 2H), 7.47 (m, 4H), 7.39 (m, 2H), 7.31 (m, 2H), 6.92 (d, 2H), 4.83 (s, 1H), 2.85 (m, 4H), 2.46(m, 2H), 2.32 (s, 6H), 1.96(s, 3H), 1.92 (d, J=21.5 Hz, 6H), 1.76 (m, 4H), 1.65 (m, 8H), 1.19 (m, 12H).

### Synthesis of a Compound Lc003

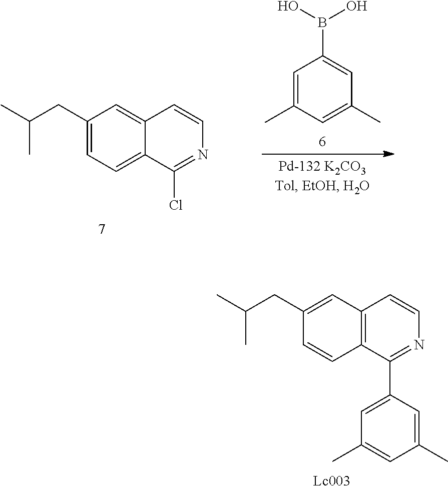

With reference to the synthesis and purification methods of the compound La001, only the corresponding raw materials were required to be changed, and a target compound Lc003 was obtained. The mass spectrum was 290.41 (M+H).

### Synthesis of a Compound Ir(La001)(Lb031)(Lc003)

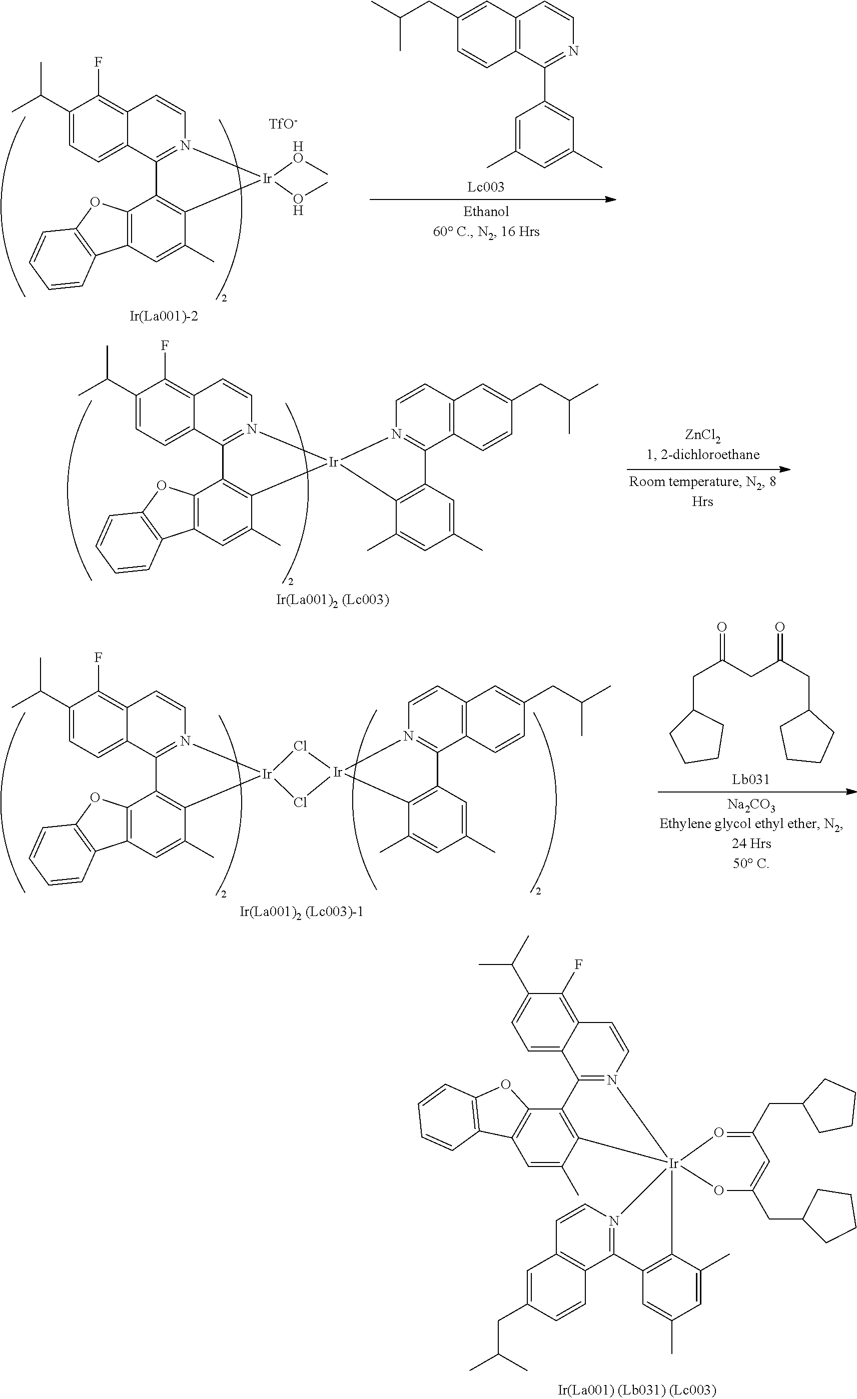

### Synthesis of a Compound Ir(La001)₂(Lc003)

With reference to the synthesis and purification methods of the compound Ir(La001)₂(Lc002), only the corresponding raw materials were required to be changed, and a target compound Ir(La001)₂(Lc003) was obtained. The mass spectrum was 1218.47 (M+H).

### Synthesis of a Compound Ir(La001)₂(Lc003)-1:

With reference to the synthesis and purification methods of the compound Ir(La001)₂(Lc002)-1, only the corresponding raw materials were required to be changed, and a target compound Ir(La001)₂(Lc003)-1 was obtained and directly used in the next step without purification.

### Synthesis of a Compound Ir(La001)(Lb031)(Lc003)

With reference to the synthesis and purification methods of the compound Ir(La001)(Lb031)(Lc002), only the corresponding raw materials were required to be changed, and 1.57 g of a dark red solid, namely compound Ir(La001)(Lb031)(Lc003), with a yield of 37.62% was obtained. 1.57 g of the crude product (La001)(Lb031)(Lc003) was sublimated and purified to obtain 0.86 g of sublimated pure Ir(La001)(Lb031)(Lc003) with a yield of 54.77%. The mass spectrum was: 1085.39 (M+H). ¹H NMR (400 MHz, CDCl₃) δ 8.85 (d, J=15.0 Hz, 2H), 8.26(s, 1H), 8.03 (d, 1H), 7.71 (m, 2H), 7.46 (m, 4H), 7.41 (m, 2H), 7.32 (m, 2H), 6.96 (d, 2H), 4.81 (s, 1H), 2.83(m, 4H), 2.46(m, 2H), 2.32 (s, 6H), 2.21(m, 2H), 1.96(s, 3H), 1.93 (d, J=20.3 Hz, 6H), 1.74 (m, 4H), 1.62 (m, 8H), 1.08 (m, 12H).

### Synthesis of a Compound Lc005

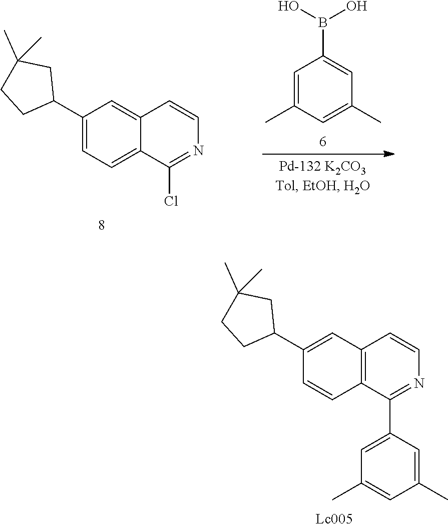

With reference to the synthesis and purification methods of the compound La001, only the corresponding raw materials were required to be changed, and a target compound Lc005 was obtained. The mass spectrum was 330.48 (M+H).

### Synthesis of a Compound Ir(La001)(Lb031)(Lc005)

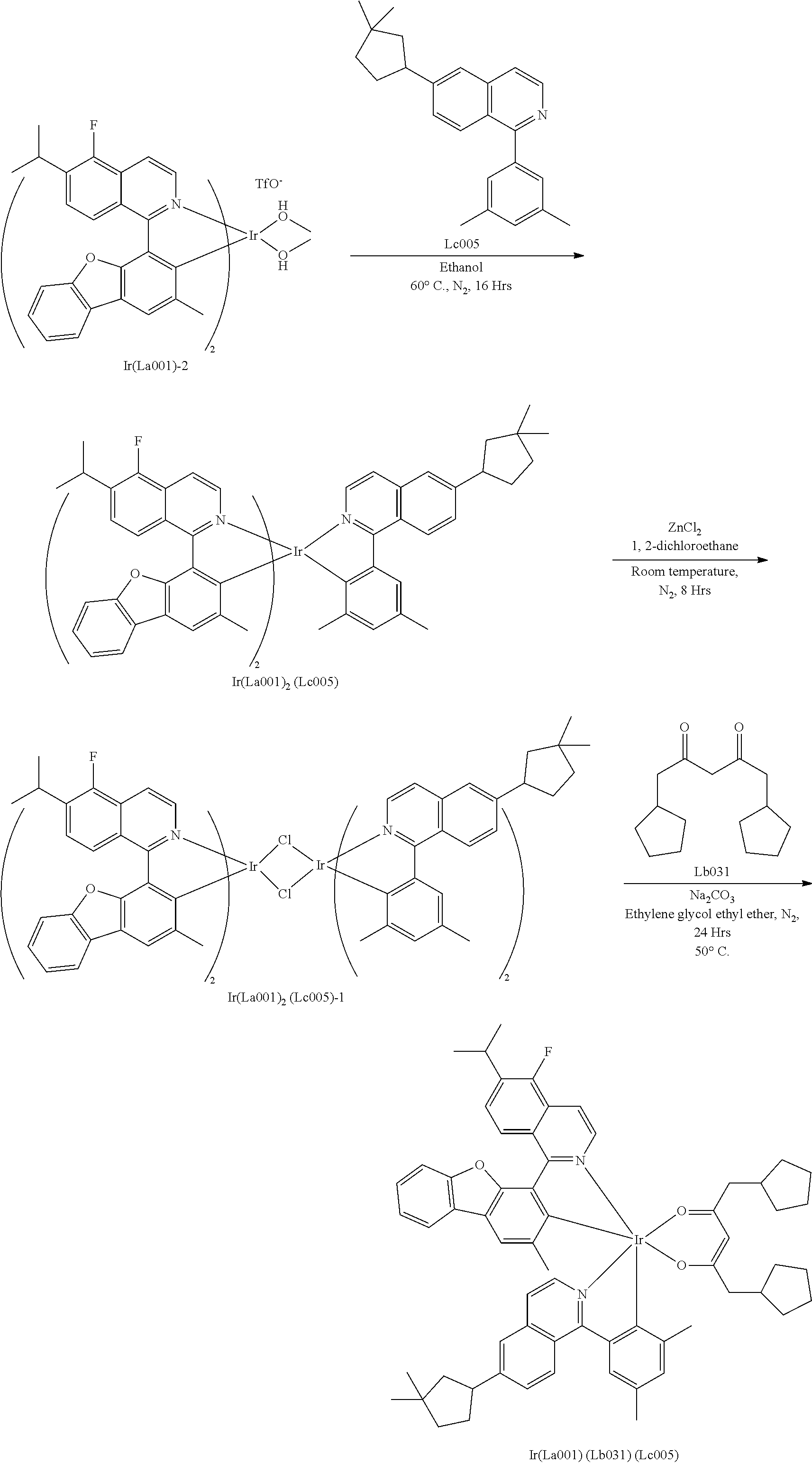

### Synthesis of a Compound Ir(La001)₂(Lc005)

With reference to the synthesis and purification methods of the compound Ir(La001)₂(Lc002), only the corresponding raw materials were required to be changed, and a target compound Ir(La001)₂(Lc005) was obtained. The mass spectrum was 1258.53 (M+H).

### Synthesis of a Compound Ir(La001)₂(Lc005)-1

With reference to the synthesis and purification methods of the compound Ir(La001)₂(Lc002)-1, only the corresponding raw materials were required to be changed, and a target compound Ir(La001)₂(Lc005)-1 was obtained and directly used in the next step without purification.

### Synthesis of a Compound Ir(La001)(Lb031)(Lc005)

With reference to the synthesis and purification methods of the compound Ir(La001)(Lb031)(Lc002), only the corresponding raw materials were required to be changed, and 1.61 g of a dark red solid, namely compound Ir(La001)(Lb031)(Lc005), with a yield of 39.22% was obtained. 1.61 g of the crude product (La001)(Lb031)(Lc005) was sublimated and purified to obtain 0.89 g of sublimated pure Ir(La001)(Lb031)(Lc005) with a yield of 55.27%. The mass spectrum was: 1125.45 (M+H). δ 8.87 (d, J=15.0 Hz, 2H), 8.25(s, 1H), 8.01 (d, 1H), 7.72 (m, 2H), 7.45 (m, 4H), 7.39 (m, 2H), 7.34 (m, 2H), 6.95 (d, 2H),4.83 (s, 1H), 2.83(m, 4H), 2.44(m, 2H), 2.34 (m, 6H), 2.12(m, 2H), 1.96(s, 3H), 1.88 (d, J=19.8 Hz, 6H) 1.74 (m, 4H), 1.62 (m, 8H), 1.52 (s, 6H), 1.08 (m, 12H).0.87 (s, 6H)

### Synthesis of a Compound La027

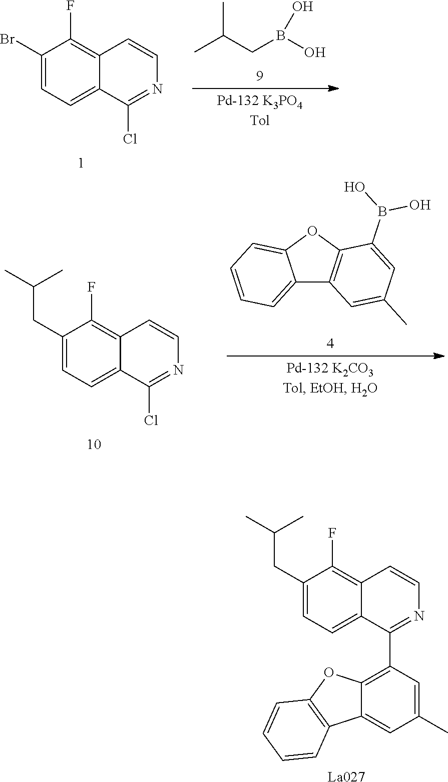

### Synthesis of a Compound 10

With reference to the synthesis and purification methods of the compound 3, only the corresponding raw materials were required to be changed, and a target compound 10 was obtained. The mass spectrum was 238.70 (M+H).

### Synthesis of a Compound La027

With reference to the synthesis and purification methods of the compound La001, only the corresponding raw materials were required to be changed, and a target compound La027 was obtained. The mass spectrum was 384.46 (M+H).

### Synthesis of a Compound Ir(La027)(Lb005)(Lc002)

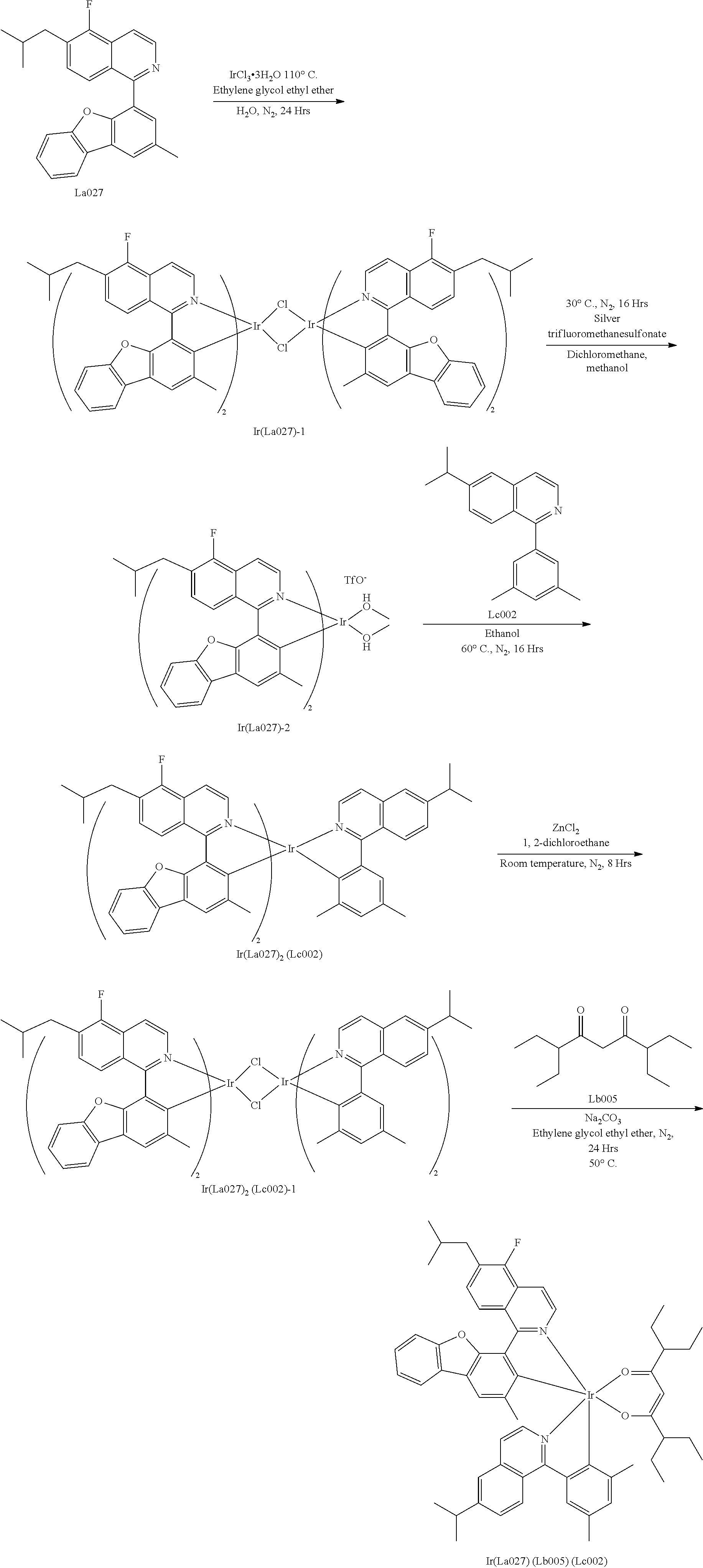

### Synthesis of a Compound Ir(La027)-1

With reference to the synthesis and purification methods of the compound Ir(La001)-1, only the corresponding raw materials were required to be changed, and a target compound Ir(La027)-1 was obtained and directly used in the next step without purification.

### Synthesis of a Compound Ir(La027)-2

With reference to the synthesis and purification methods of the compound Ir(La001)-2, only the corresponding raw materials were required to be changed, and a target compound Ir(La027)-2 was obtained and directly used in the next step without purification.

### Synthesis of a Compound Ir(La027)₂(Lc002)

With reference to the synthesis and purification methods of the compound Ir(La001)₂(Lc002), only the corresponding raw materials were required to be changed, and a target compound Ir(La027)₂(Lc002) was obtained. The mass spectrum was 1232.50 (M+H).

### Synthesis of a Compound Ir(La027)₂(Lc002)-1

With reference to the synthesis and purification methods of the compound Ir(La001)₂(Lc002)-1, only the corresponding raw materials were required to be changed, and a target compound Ir(La027)₂(Lc002)-1 was obtained and directly used in the next step without purification.

### Synthesis of a Compound Ir(La027)(Lb005)(Lc002)

With reference to the synthesis and purification methods of the compound Ir(La001)(Lb031)(Lc002), only the corresponding raw materials were required to be changed, and 1.49 g of a dark red solid, namely compound Ir(La027)(Lb005)(Lc002), with a yield of 37.94% was obtained. 1.49 g of the crude product (La027)(Lb005)(Lc002) was sublimated and purified to obtain 0.82 g of sublimated pure Ir(La027)(Lb005)(Lc002) with a yield of 55.03%. The mass spectrum was: 1061.37 (M+H). ¹H NMR (400 MHz, CDCl₃) δ8.85 (d, J=15.0 Hz, 2H), 8.26(s, 1H), 8.03 (d, 1H), 7.71 (m, 2H), 7.46 (m, 4H), 7.41 (m, 2H), 7.32 (m, 2H), 6.96 (d, 2H), 4.81 (s, 1H), 2.87 (m, 1H), 2.47 (d, 2H), 2.32 (d, J=15.0 Hz, 9H), 1.80 (m, 1H), 1.25 (m, 12H), 1.09-0.89 (m, 16H), 0.86 (d, 6H).

### Synthesis of a Compound Ir(La027)(Lb005)(Lc003)

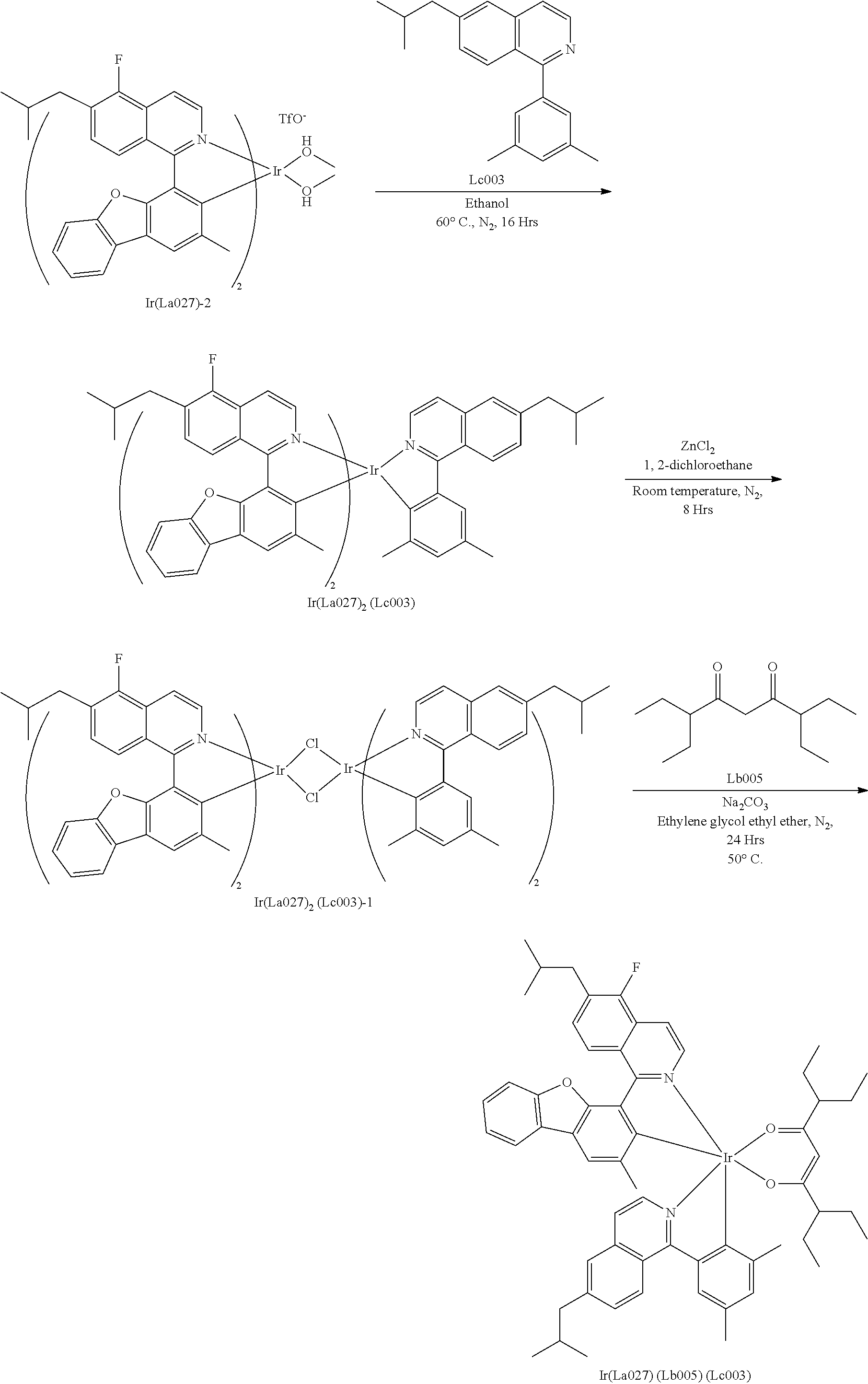

### Synthesis of a Compound Ir(La027)₂(Lc003)

With reference to the synthesis and purification methods of the compound Ir(La001)₂(Lc002), only the corresponding raw materials were required to be changed, and a target compound Ir(La027)₂(Lc003) was obtained. The mass spectrum was 1246.52 (M+H).

### Synthesis of a Compound Ir(La027)₂(Lc003)-1

With reference to the synthesis and purification methods of the compound Ir(La001)₂(Lc002)-1, only the corresponding raw materials were required to be changed, and a target compound Ir(La027)₂(Lc003)-1 was obtained and directly used in the next step without purification.

### Synthesis of a Compound Ir(La027)(Lb005)(Lc003)

With reference to the synthesis and purification methods of the compound Ir(La001)(Lb031)(Lc002), only the corresponding raw materials were required to be changed, and 1.71 g of a dark red solid, namely compound Ir(La027)(Lb005)(Lc003), with a yield of 42.39% was obtained. 1.71 g of the crude product (La027)(Lb005)(Lc003) was sublimated and purified to obtain 1.02 g of sublimated pure Ir(La027)(Lb005)(Lc003) with a yield of 59.64%. The mass spectrum was: 1075.39 (M+H). ¹H NMR (400 MHz, CDCl₃) δ 8.87 (d, J=15.0 Hz, 2H), 8.28(s, 1H), 8.04 (d, 1H), 7.76 (m, 2H), 7.51 (m, 4H), 7.42 (m, 2H), 7.33 (m, 2H), 6.97(d, 2H), 4.82 (s, 1H), 2.88(m, 1H), 2.48 (d, 2H), 2.33 (d, J=15.0 Hz, 9H), 2.22 (d, 2H),1.80 (m, 1H), 1.27 (m, 12H), 1.09-0.89 (m, 16H), 0.88(d, 6H).

### Synthesis of a Compound Ir(La027)(Lb005)(Lc005)

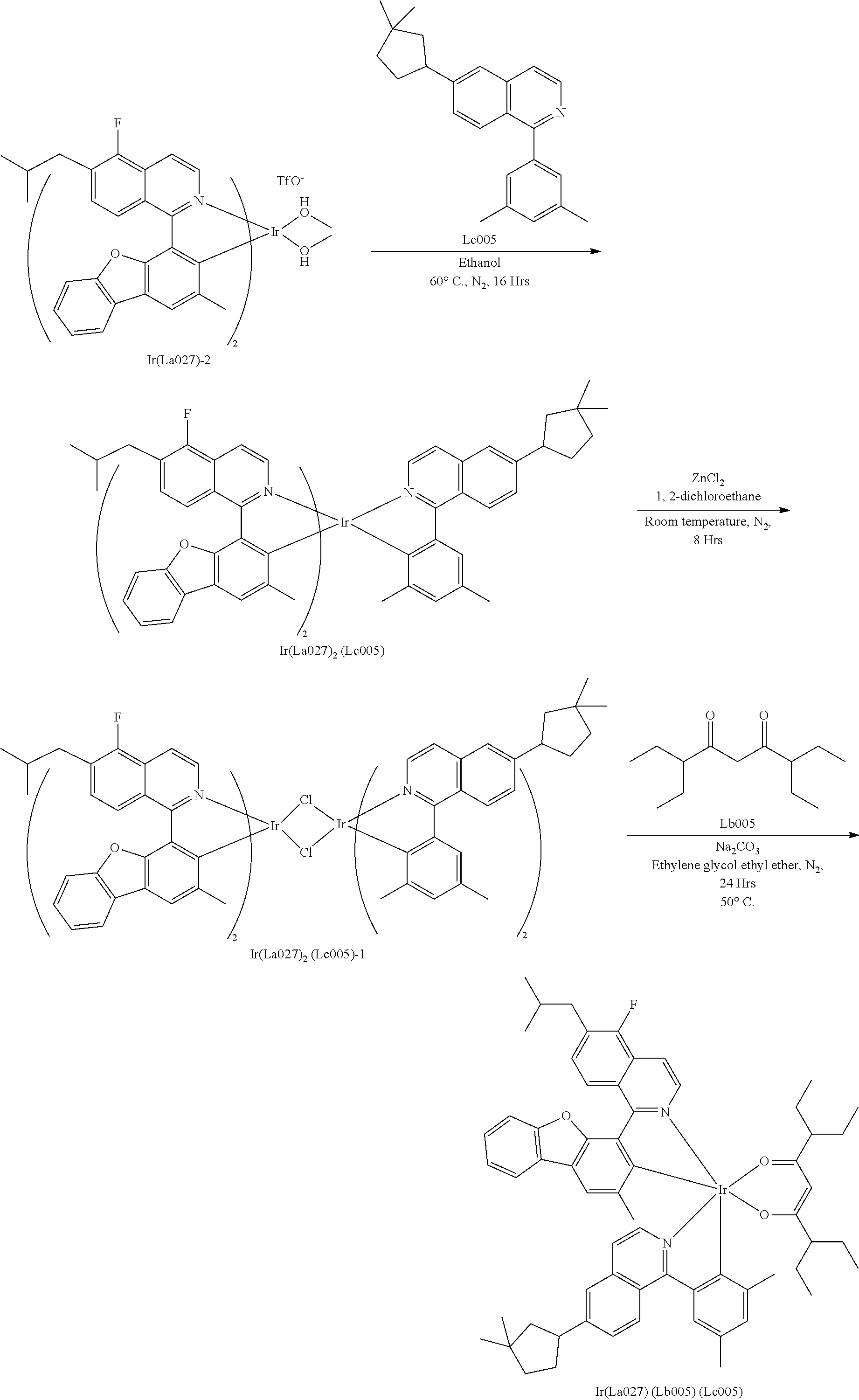

### Synthesis of a Compound Ir(La027)₂(Lc005)

With reference to the synthesis and purification methods of the compound Ir(La001)₂(Lc002), only the corresponding raw materials were required to be changed, and a target compound Ir(La027)₂(Lc005) was obtained. The mass spectrum was 1286.59 (M+H).

### Synthesis of a Compound Ir(La027)₂(Lc005)-1

With reference to the synthesis and purification methods of the compound Ir(La001)₂(Lc002)-1, only the corresponding raw materials were required to be changed, and a target compound Ir(La027)₂ (Lc005)-1 was obtained and directly used in the next step without purification.

### Synthesis of a Compound Ir(La027)(Lb005)(Lc005)

With reference to the synthesis and purification methods of the compound Ir(La001)(Lb031)(Lc002), only the corresponding raw materials were required to be changed, and 1.51 g of a dark red solid, namely compound Ir(La027)(Lb005)(Lc005), with a yield of 41.33% was obtained. 1.51 g of the crude product (La027)(Lb005)(Lc005) was sublimated and purified to obtain 0.84 g of sublimated pure Ir(La027)(Lb005)(Lc005) with a yield of 55.62%. The mass spectrum was: 1115.46 (M+H).

¹H NMR (400 MHz, CDCl₃) 8.87 (d, J=15.0 Hz, 2H), 8.28(s, 1H), 8.04 (d, 1H), 7.76 (m, 2H), 7.51 (m, 4H), 7.42 (m, 2H), 7.33 (m, 2H), 6.97(d, 2H), 4.82 (s, 1H), 2.88(m, 1H), 2.48 (d, 2H), 2.33 (d, J=15.0 Hz, 9H), 2.22 (m, 1H), 1.88 (m, 6H), 1.27 (m, 12H), 1.09 — 0.89 (m, 16H), 0.88(s, 6H).

### Synthesis of a Compound La037

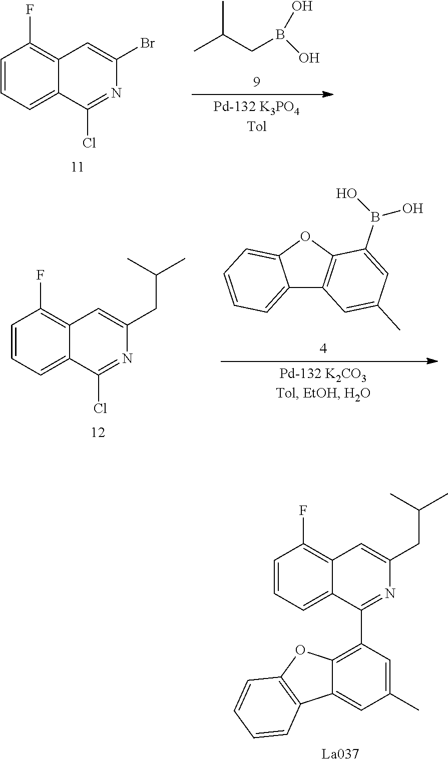

### Synthesis of a Compound 12

With reference to the synthesis and purification methods of the compound 3, only the corresponding raw materials were required to be changed, and a target compound 12 was obtained. The mass spectrum was 238.70 (M+H).

### Synthesis of a Compound La037

With reference to the synthesis and purification methods of the compound La001, only the corresponding raw materials were required to be changed, and a target compound La037 was obtained. The mass spectrum was 384.46 (M+H).

### Synthesis of a Compound Lc020

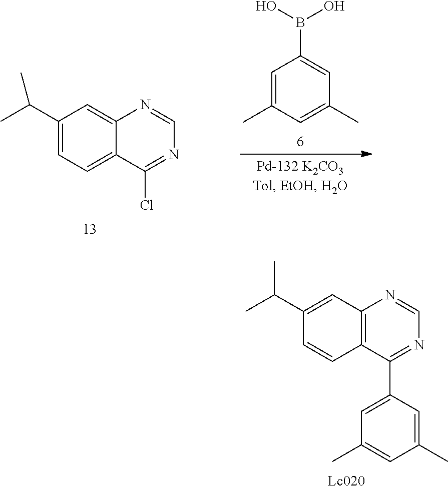

With reference to the synthesis and purification methods of the compound La001, only the corresponding raw materials were required to be changed, and a target compound Lc020 was obtained. The mass spectrum was 277.38 (M+H).

### Synthesis of a Compound Ir(La037)(Lb005)(Lc020)

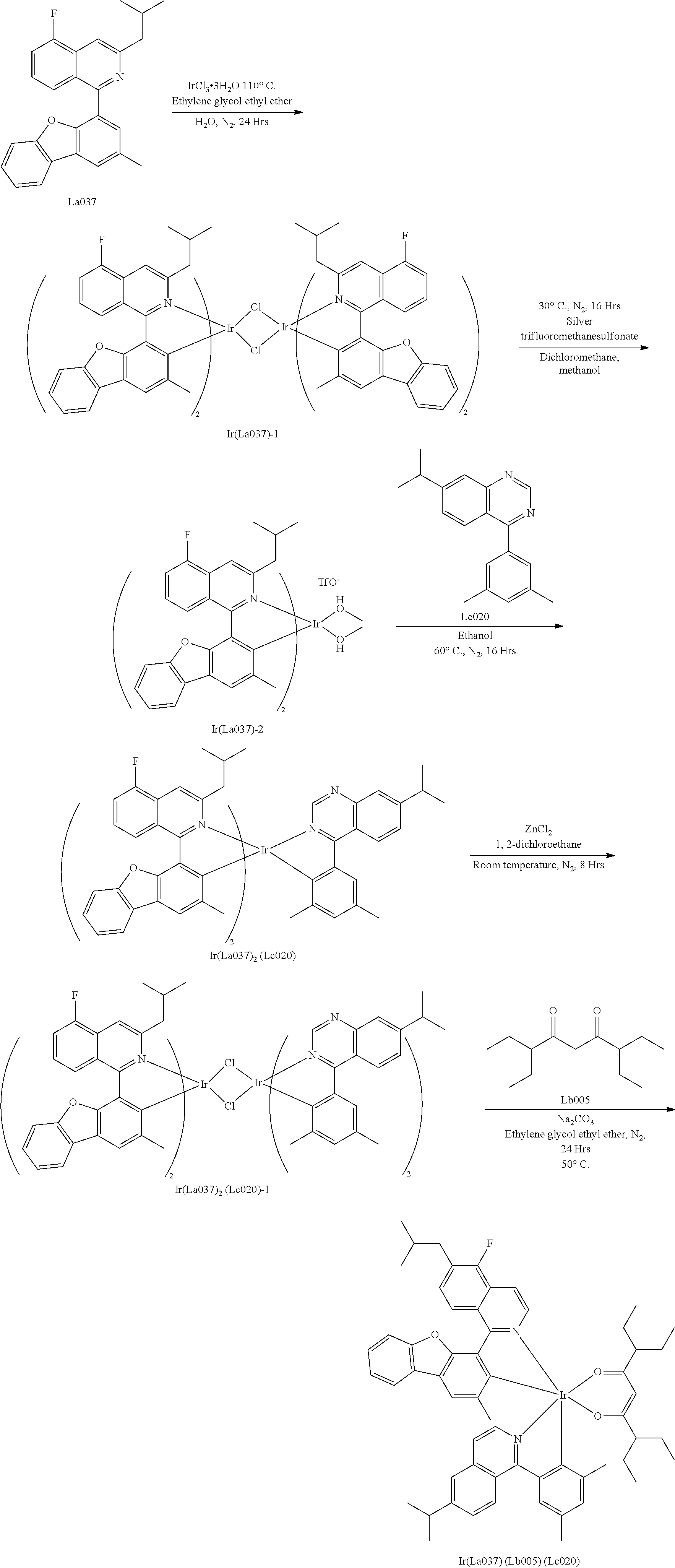

### Synthesis of a Compound Ir(La037)-1

With reference to the synthesis and purification methods of the compound Ir(La001)-1, only the corresponding raw materials were required to be changed, and a target compound Ir(La037)-1 was obtained and directly used in the next step without purification.

### Synthesis of a Compound Ir(La037)-2

With reference to the synthesis and purification methods of the compound Ir(La001)-2, only the corresponding raw materials were required to be changed, and a target compound Ir(La037)-2 was obtained and directly used in the next step without purification.

### Synthesis of a Compound Ir(La037)₂(Lc020)

With reference to the synthesis and purification methods of the compound Ir(La001)₂(Lc002), only the corresponding raw materials were required to be changed, and a target compound Ir(La037)₂(Lc020) was obtained. The mass spectrum was 1233.48 (M+H).

### Synthesis of a Compound Ir(La037)₂(Lc020)-1

With reference to the synthesis and purification methods of the compound Ir(La001)₂(Lc002)-1, only the corresponding raw materials were required to be changed, and a target compound Ir(La037)₂(Lc020)-1 was obtained and directly used in the next step without purification.

### Synthesis of a Compound Ir(La037)(Lb005)(Lc020)

With reference to the synthesis and purification methods of the compound Ir(La001)(Lb031)(Lc002), only the corresponding raw materials were required to be changed, and 1.63 g of a dark red solid, namely compound Ir(La037)(Lb005)(Lc020), with a yield of 38.94% was obtained. 1.63 g of the crude product (La037)(Lb005)(Lc020) was sublimated and purified to obtain 0.94 g of sublimated pure Ir(La037)(Lb005)(Lc020) with a yield of 57.66%. The mass spectrum was: 1062.35 (M+H). ¹H NMR (400 MHz, CDCl₃) δ 8.81 (s, 1H), 8.45(m, 1H), 8.32(s, 1H), 8.03 (d, 2H), 7.71 (m, 2H), 7.46 (m, 4H), 7.41 (m, 2H), 7.32 (m, 2H), 4.82 (s, 1H), 2.84(m, 1H), 2.42 (d, 2H), 2.27 (d, J=15.0 Hz, 9H), 1.87 (m, 1H), 1.21 (m, 12H), 1.12 — 0.85 (m, 16H), 0.72 (m, 6H).

### Synthesis of a Compound Lc024

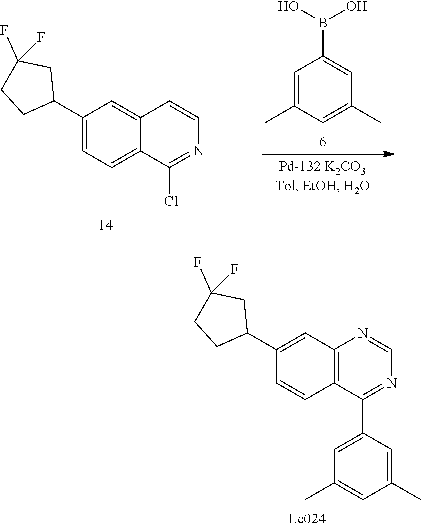

With reference to the synthesis and purification methods of the compound La001, only the corresponding raw materials were required to be changed, and a target compound Lc024 was obtained. The mass spectrum was 339.39 (M+H).

### Synthesis of a Compound Ir(La037)(Lb005)(Lc024)

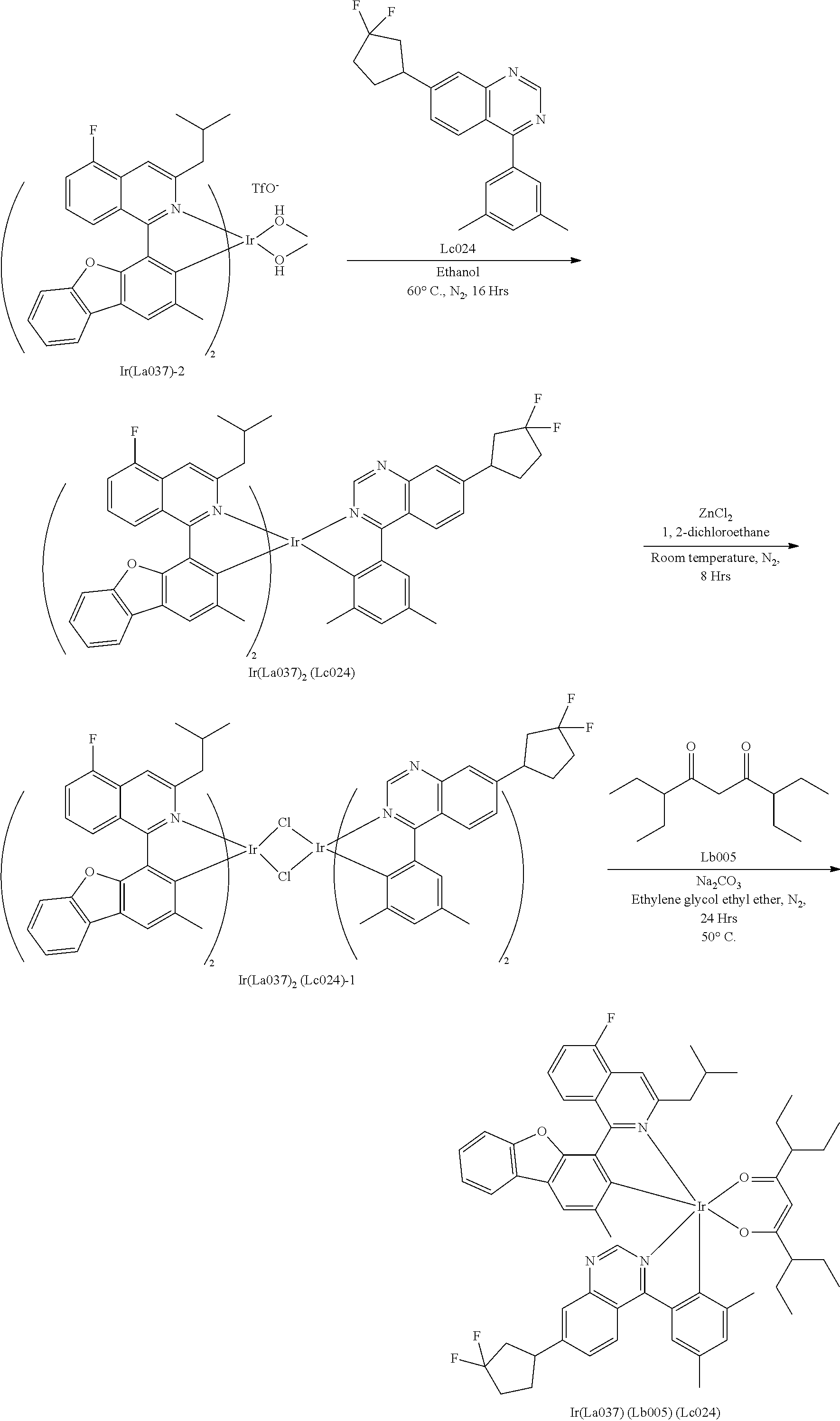

### Synthesis of a Compound Ir(La037)₂(Lc024)

With reference to the synthesis and purification methods of the compound Ir(La001)₂(Lc002), only the corresponding raw materials were required to be changed, and a target compound Ir(La037)₂(Lc024) was obtained. The mass spectrum was 1295.50 (M+H).

### Synthesis of a Compound Ir(La037)₂(Lc024)-1

With reference to the synthesis and purification methods of the compound Ir(La001)₂(Lc002)-1, only the corresponding raw materials were required to be changed, and a target compound Ir(La037)₂(Lc024)-1 was obtained and directly used in the next step without purification.

### Synthesis of a Compound Ir(La037)(Lb005)(Lc024)

With reference to the synthesis and purification methods of the compound Ir(La001)(Lb031)(Lc002), only the corresponding raw materials were required to be changed, and 1.63 g of a dark red solid, namely compound Ir(La037)(Lb005)(Lc024), with a yield of 38.94% was obtained. 1.63 g of the crude product (La037)(Lb005)(Lc024) was sublimated and purified to obtain 0.94 g of sublimated pure Ir(La037)(Lb005)(Lc024) with a yield of 57.66%. The mass spectrum was: 1124.37 (M+H). ¹H NMR (400 MHz, CDCl₃) δ 8.79(s, 1H),8.45(m, 1H), 8.32(s, 1H), 8.03 (d, 2H), 7.71 (m, 2H), 7.46 (m, 4H), 7.41 (m, 2H), 7.32 (m, 2H), 4.82 (s, 1H), 2.88(m, 1H), 2.48 (d, 2H), 2.33 (d, J=15.0 Hz, 9H), 2.22 (m, 1H), 1.88 (m, 6H), 1.27 (m, 12H), 1.09-0.89 (m, 16H).

### Synthesis of a Compound Lc025

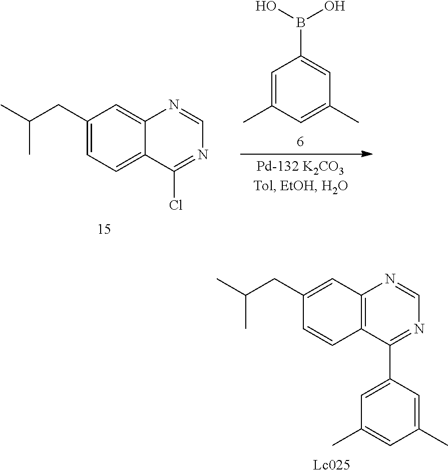

With reference to the synthesis and purification methods of the compound La001, only the corresponding raw materials were required to be changed, and a target compound Lc025 was obtained. The mass spectrum was 291.40 (M+H).

### Synthesis of a Compound Ir(La037)(Lb005)(Lc025)

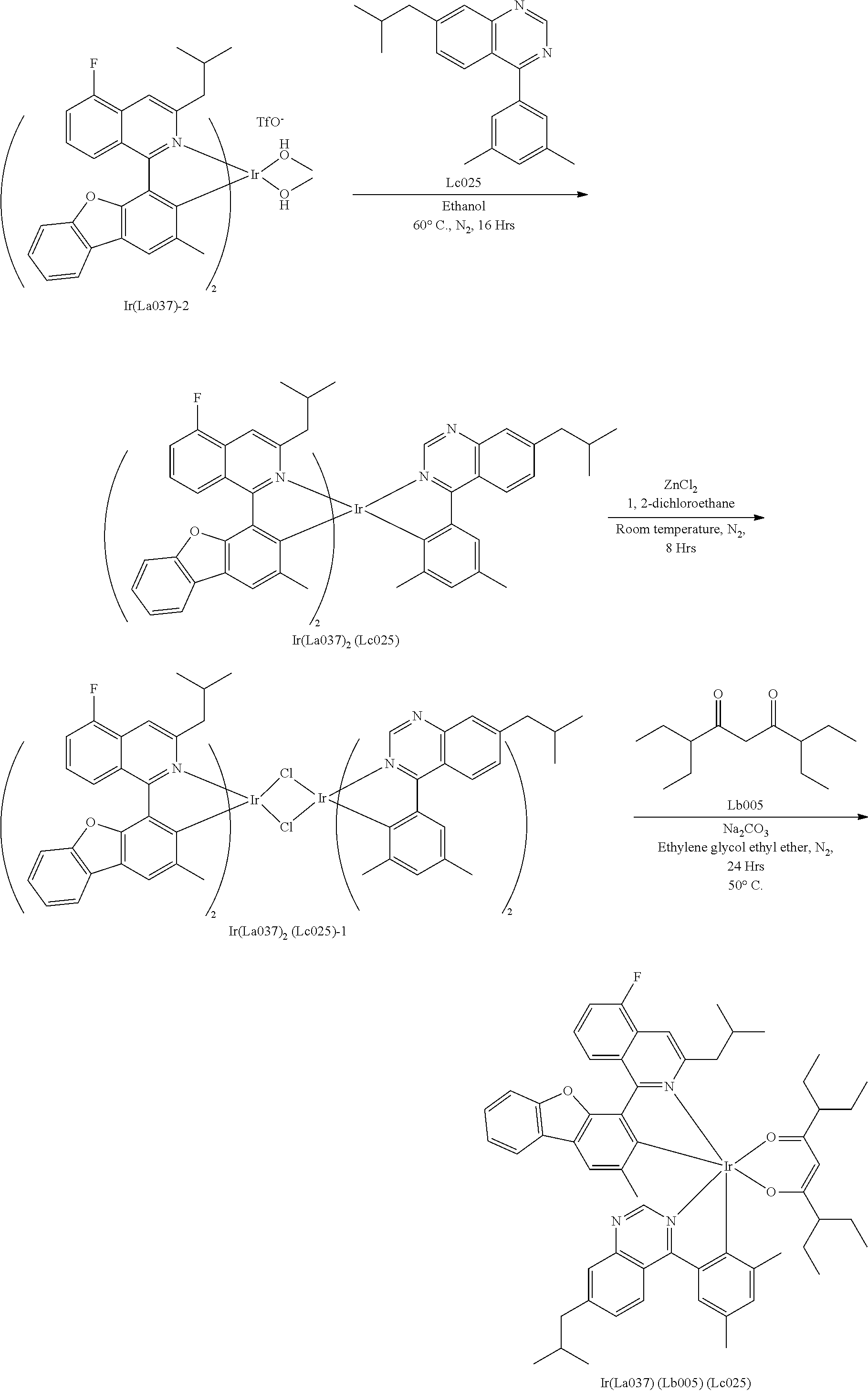

### Synthesis of a Compound Ir(La037)₂(Lc025)

With reference to the synthesis and purification methods of the compound Ir(La001)₂(Lc002), only the corresponding raw materials were required to be changed, and a target compound Ir(La037)₂(Lc025) was obtained. The mass spectrum was 1247.51 (M+H).

### Synthesis of a Compound Ir(La037)₂(Lc025)-1

With reference to the synthesis and purification methods of the compound Ir(La001)₂(Lc002)-1, only the corresponding raw materials were required to be changed, and a target compound Ir(La037)₂(Lc025)-1 was obtained and directly used in the next step without purification.

### Synthesis of a Compound Ir(La037)(Lb005)(Lc025)

With reference to the synthesis and purification methods of the compound Ir(La001)(Lb031)(Lc002), only the corresponding raw materials were required to be changed, and 1.52 g of a dark red solid, namely compound Ir(La037)(Lb005)(Lc025), with a yield of 36.74% was obtained. 1.52 g of the crude product (La037)(Lb005)(Lc025) was sublimated and purified to obtain 0.84 g of sublimated pure Ir(La037)(Lb005)(Lc025) with a yield of 55.26%. The mass spectrum was: 1076.38 (M+H).

¹H NMR (400 MHz, CDCl₃) δ 8.79(s, 1H),8.45(m, 1H), 8.32(s, 1H), 8.03 (d, 2H), 7.71 (m, 2H), 7.46 (m, 4H), 7.41 (m, 2H), 7.32 (m, 2H), 4.83 (s, 1H), 2.77(m, 1H), 2.43 (d, 2H), 2.33 (d, J=15.0 Hz, 9H), 2.22 (d, 2H),1.80 (m, 1H), 1.27 (m, 12H), 1.09-0.89 (m, 16H), 0.88(d, 6H).

### Synthesis of a Compound Lc026

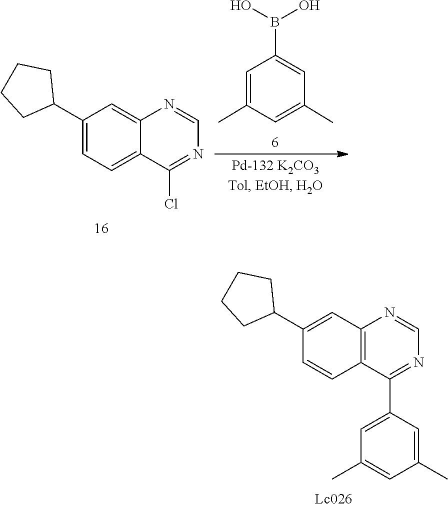

With reference to the synthesis and purification methods of the compound La001, only the corresponding raw materials were required to be changed, and a target compound Lc026 was obtained. The mass spectrum was 303.41 (M+H).

### Synthesis of a Compound Ir(La037)(Lb005)(Lc026)

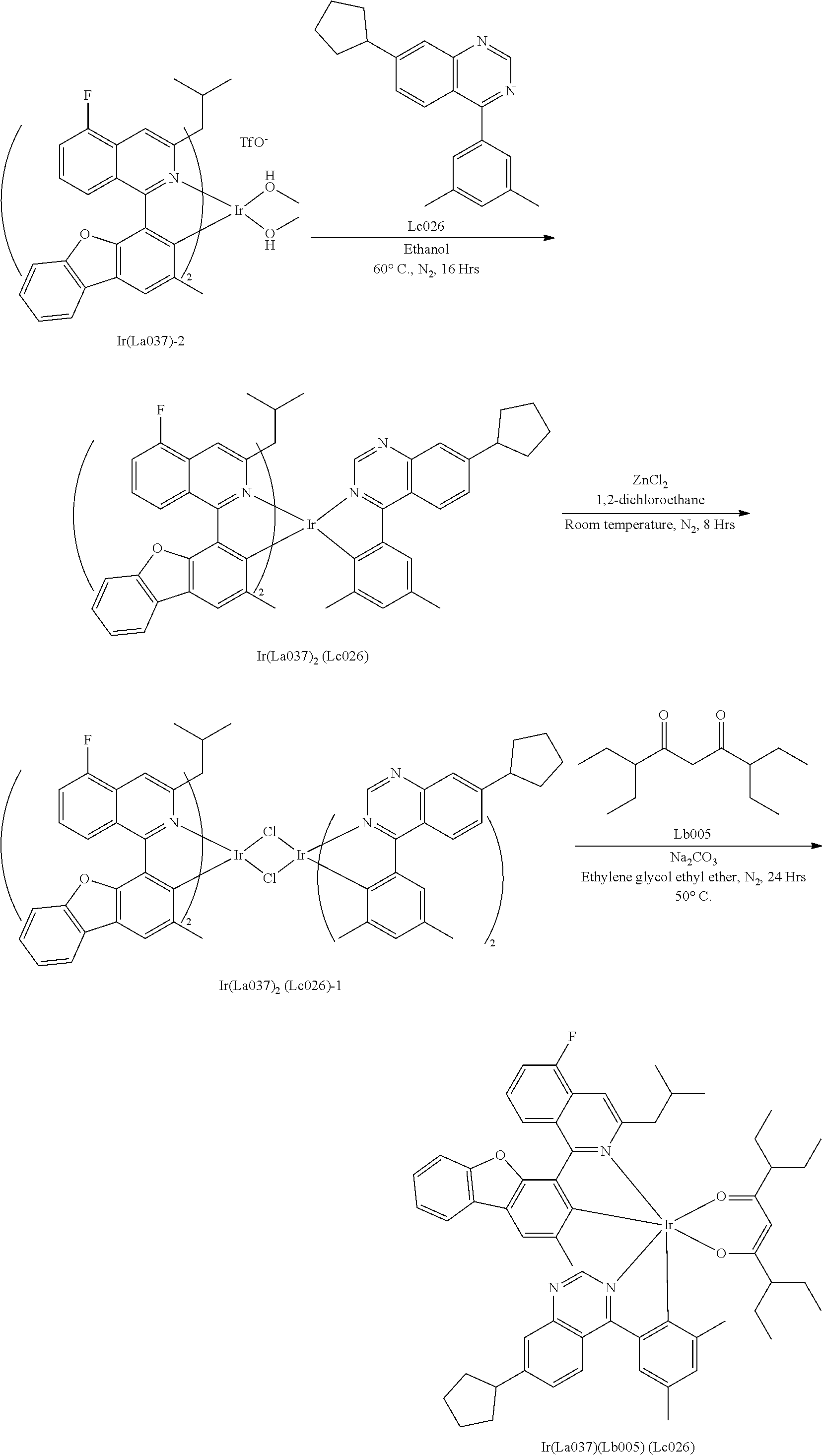

### Synthesis of a Compound Ir(La037)₂(Lc026)

With reference to the synthesis and purification methods of the compound Ir(La001)₂(Lc002), only the corresponding raw materials were required to be changed, and a target compound Ir(La037)₂(Lc026) was obtained. The mass spectrum was 1259.52 (M+H).

### Synthesis of a Compound Ir(La037)₂(Lc026)-1

With reference to the synthesis and purification methods of the compound Ir(La001)₂(Lc002)-1, only the corresponding raw materials were required to be changed, and a target compound Ir(La037)₂(Lc026)-1 was obtained and directly used in the next step without purification.

### Synthesis of a Compound Ir(La037)(Lb005)(Lc026)

With reference to the synthesis and purification methods of the compound Ir(La001)(Lb031)(Lc002), only the corresponding raw materials were required to be changed, and 1.46 g of a dark red solid, namely compound Ir(La037)(Lb005)(Lc026), with a yield of 35.68% was obtained. 1.46 g of the crude product (La037)(Lb005)(Lc026) was sublimated and purified to obtain 0.88 g of sublimated pure Ir(La037)(Lb005)(Lc026) with a yield of 60.27%. The mass spectrum was: 1088.39 (M+H). ¹H NMR (400 MHz, CDCl₃) δ 8.79(s, 1H), 8.45(m, 1H), 8.32(s, 1H), 8.03 (d, 2H), 7.71 (m, 2H), 7.46 (m, 4H), 7.41 (m, 2H), 7.32 (m, 2H), 4.83 (s, 1H), 2.77(m, 1H), 2.43 (d, 2H), 2.33 (s, 3H), 2.30 (s, 6H), 2.22 (d, 2H),1.80 (m, 1H), 1.33 (m, 8H), 1.27 (m, 6H), 1.09-0.89 (m, 16H), 0.88(d, 6H).

### Synthesis of a Compound La080

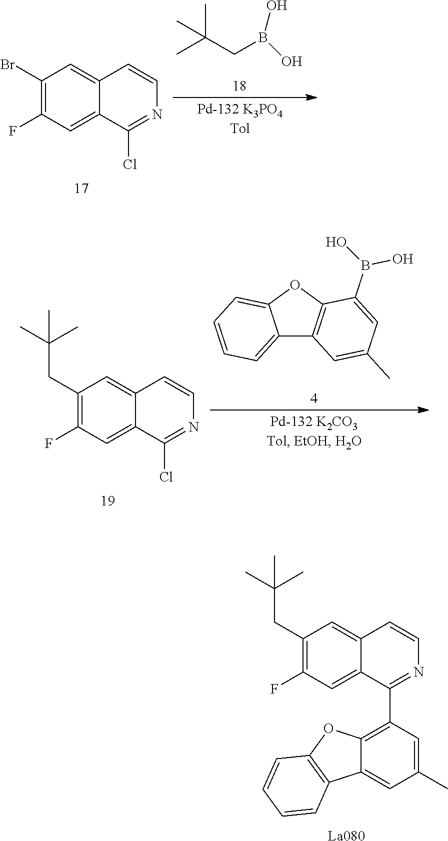

### Synthesis of a Compound 19

With reference to the synthesis and purification methods of the compound 3, only the corresponding raw materials were required to be changed, and a target compound 19 was obtained. The mass spectrum was 252.73 (M+H).

### Synthesis of a Compound La080

With reference to the synthesis and purification methods of the compound La001, only the corresponding raw materials were required to be changed, and a target compound La080 was obtained. The mass spectrum was 398.48 (M+H).

### Synthesis of a Compound Lc048

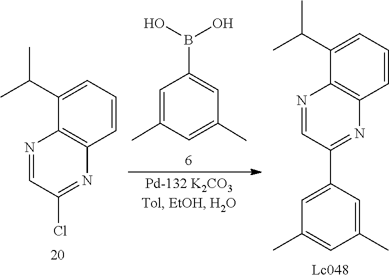

With reference to the synthesis and purification methods of the compound La001, only the corresponding raw materials were required to be changed, and a target compound Lc048 was obtained. The mass spectrum was 377.38 (M+H).

### Synthesis of a Compound Ir(La080)(Lb018)(Lc048)

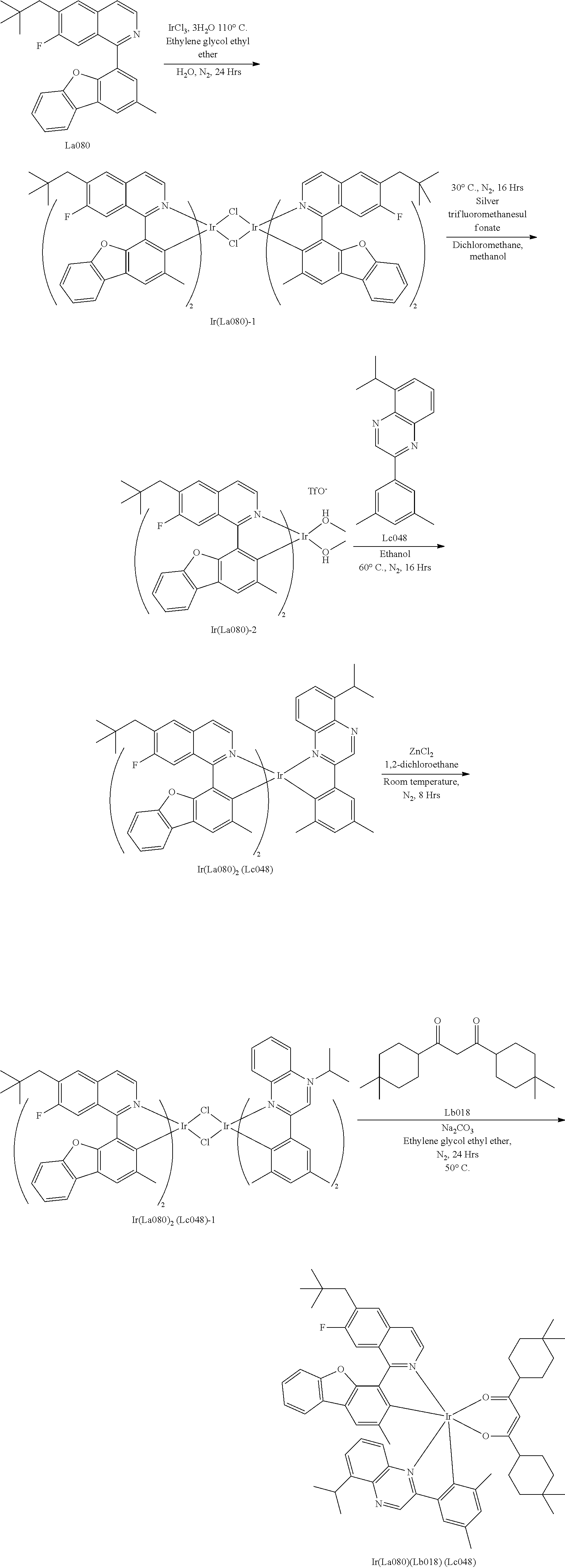

### Synthesis of a Compound Ir(La080)-1

With reference to the synthesis and purification methods of the compound Ir(La001)-1, only the corresponding raw materials were required to be changed, and a target compound Ir(La080)-1 was obtained and directly used in the next step without purification.

### Synthesis of a Compound Ir(La080)-2

With reference to the synthesis and purification methods of the compound Ir(La001)-2, only the corresponding raw materials were required to be changed, and a target compound Ir(La080)-2 was obtained and directly used in the next step without purification.

### Synthesis of a Compound Ir(La080)₂(Lc048)

With reference to the synthesis and purification methods of the compound Ir(La001)₂(Lc002), only the corresponding raw materials were required to be changed, and a target compound Ir(La080)₂(Lc048) was obtained. The mass spectrum was 1261.54 (M+H).

### Synthesis of a Compound Ir(La080)₂(Lc048)-1

With reference to the synthesis and purification methods of the compound Ir(La001)₂(Lc002)-1, only the corresponding raw materials were required to be changed, and a target compound Ir(La080)₂(Lc048)-1 was obtained and directly used in the next step without purification.

### Synthesis of a Compound Ir(La080)(Lb018)(Lc048)

With reference to the synthesis and purification methods of the compound Ir(La001)(Lb031)(Lc002), only the corresponding raw materials were required to be changed, and 1.71 g of a dark red solid, namely compound Ir(La080)(Lb018)(Lc048), with a yield of 39.2% was obtained. 1.71 g of the crude product (La080)(Lb018)(Lc048) was sublimated and purified to obtain 1.06 g of sublimated pure Ir(La080)(Lb018)(Lc048) with a yield of 61.98%. The mass spectrum was: 1156.51 (M+H). ¹H NMR (400 MHz, CDCl₃) δ 8.75(d, 1H), 8.40(m, 1H), 8.27(s, 1H), 8.03 (d, 2H), 7.65 (m, 2H), 7.49 (m, 4H), 7.32 (m, 4H), 4.83 (s, 1H), 2.87 (m, 1H), 2.65 (m, 2H), 2.32 (s, 3H), 2.16(s, 6H), 1.52 (m, 4H), 1.34 (m, 4H), 1.17 (m, 8H), 1.00 (m, 9H), 0.86-0.71 (m, 20H).

### Synthesis of a Compound Lc049

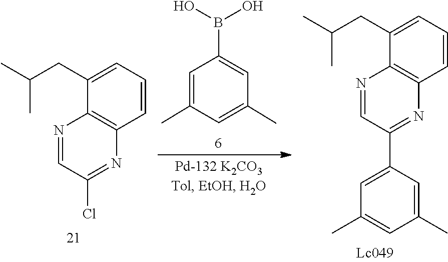

With reference to the synthesis and purification methods of the compound La001, only the corresponding raw materials were required to be changed, and a target compound Lc049 was obtained. The mass spectrum was 291.41 (M+H).

### Synthesis of a Compound Ir(La080)(Lb018)(Lc049)

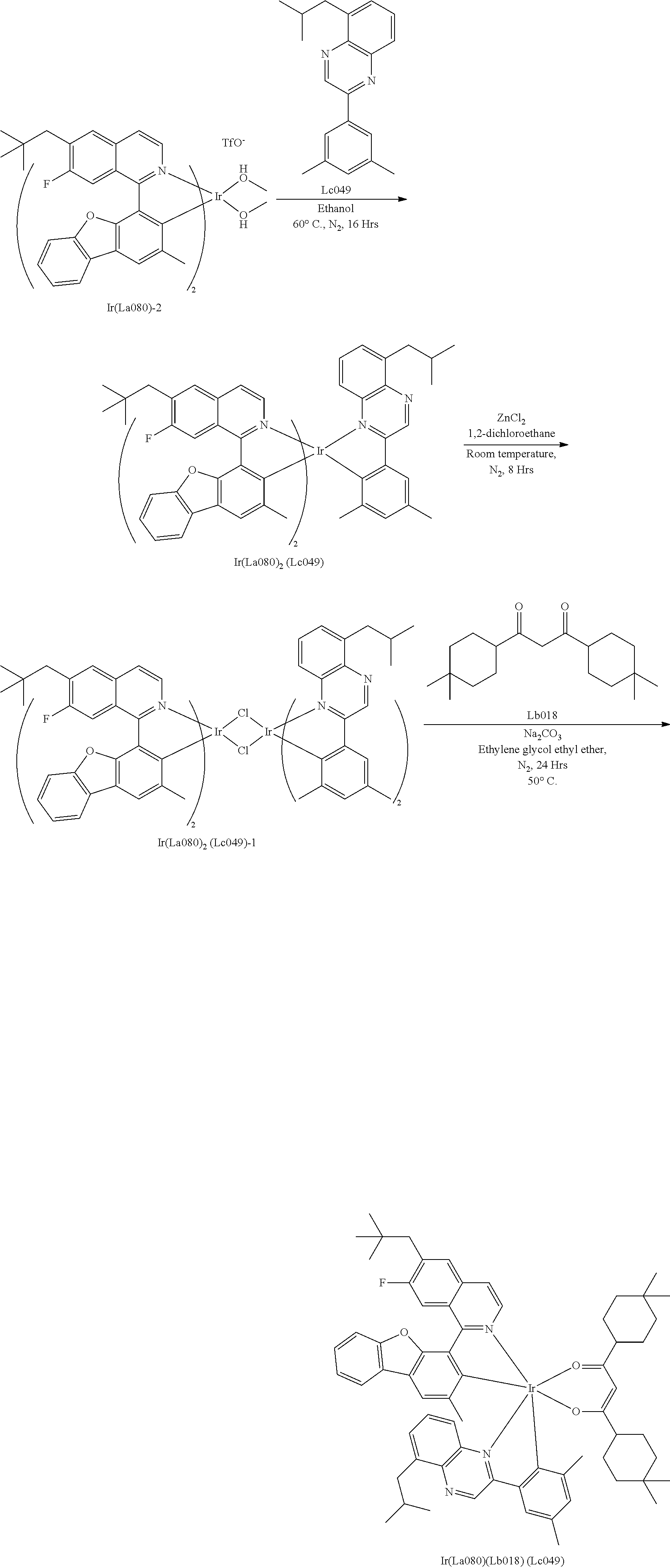

### Synthesis of a Compound Ir(La080)₂(Lc049)

With reference to the synthesis and purification methods of the compound Ir(La001)₂(Lc002), only the corresponding raw materials were required to be changed, and a target compound Ir(La080)₂(Lc049) was obtained. The mass spectrum was 1275.56 (M+H).

### Synthesis of a Compound Ir(La080)₂(Lc049)-1

With reference to the synthesis and purification methods of the compound Ir(La001)₂(Lc002)-1, only the corresponding raw materials were required to be changed, and a target compound Ir(La080)₂(Lc049)-1 was obtained and directly used in the next step without purification.

### Synthesis of a Compound Ir(La080)(Lb018)(Lc049)

With reference to the synthesis and purification methods of the compound Ir(La001)(Lb031)(Lc002), only the corresponding raw materials were required to be changed, and 1.55 g of a dark red solid, namely compound Ir(La080)(Lb018)(Lc049), with a yield of 37.98% was obtained. 1.55 g of the crude product (La080)(Lb018)(Lc049) was sublimated and purified to obtain 0.93 g of sublimated pure Ir(La080)(Lb018)(Lc049) with a yield of 60%. The mass spectrum was: 1170.54 (M+H). ¹H NMR (400 MHz, CDCl₃) δ 8.74(d, 1H), 8.38(m, 1H), 8.25(s, 1H), 8.04 (d, 2H), 7.65 (m, 2H), 7.37 (m, 4H), 7.32 (m, 4H), 4.83 (s, 1H), 2.83 (m, 1H), 2.61 (m, 2H), 2.42 (d, 2H), 2.32 (s, 3H), 2.16(s, 6H), 1.52 (m, 4H), 1.34 (m, 4H), 1.14 (m, 8H), 1.02 (m, 9H), 0.86-0.71 (m, 20H).

### Synthesis of a Compound Lc050

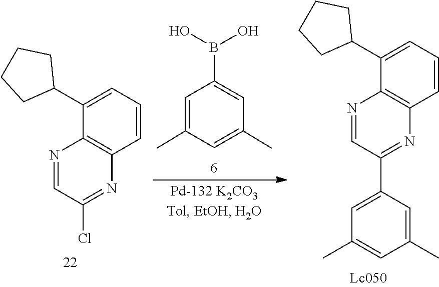

With reference to the synthesis and purification methods of the compound La001, only the corresponding raw materials were required to be changed, and a target compound Lc050 was obtained. The mass spectrum was 303.41 (M+H).

### Synthesis of a Compound Ir(La080)(Lb018)(Lc050)

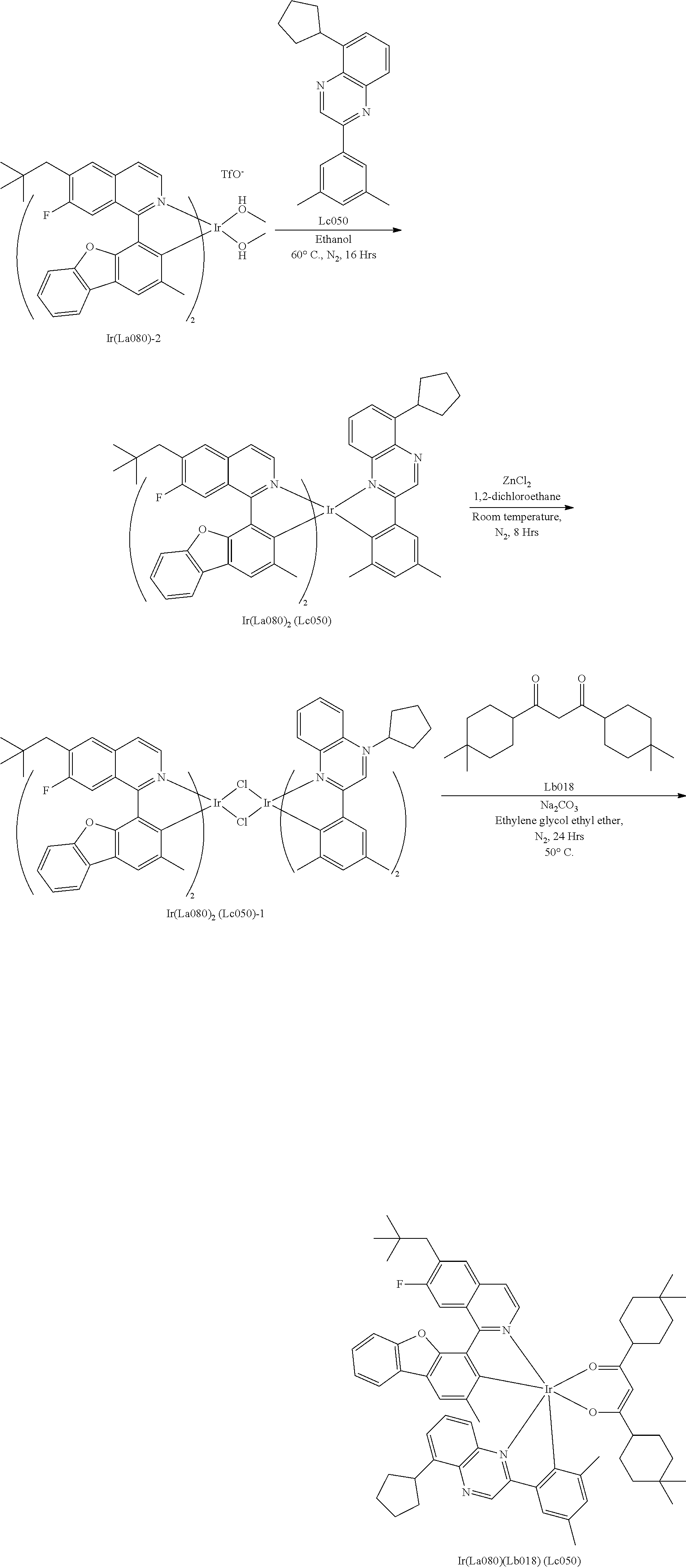

### Synthesis of a Compound Ir(La080)₂(Lc050)

With reference to the synthesis and purification methods of the compound Ir(La001)₂(Lc002), only the corresponding raw materials were required to be changed, and a target compound Ir(La080)₂(Lc050) was obtained. The mass spectrum was 1287.57 (M+H).

### Synthesis of a Compound Ir(La080)₂(Lc050)-1

With reference to the synthesis and purification methods of the compound Ir(La001)₂(Lc002)-1, only the corresponding raw materials were required to be changed, and a target compound Ir(La080)₂(Lc050)-1 was obtained and directly used in the next step without purification.

### Synthesis of a Compound Ir(La080)(Lb018)(Lc050)

With reference to the synthesis and purification methods of the compound Ir(La001)(Lb031)(Lc002), only the corresponding raw materials were required to be changed, and 1.79 g of a dark red solid, namely compound Ir(La080)(Lb018)(Lc050), with a yield of 43.17% was obtained. 1.79 g of the crude product (La080)(Lb018)(Lc050) was sublimated and purified to obtain 1.12 g of sublimated pure Ir(La080)(Lb018)(Lc050) with a yield of 62.56%. The mass spectrum was: 1182.55 (M+H). ¹H NMR (400 MHz, CDCl₃) δ 8.75(d, 1H), 8.32(m, 1H), 8.25(s, 1H), 8.04 (d, 2H), 7.65 (m, 2H), 7.37 (m, 4H), 7.32 (m, 4H), 4.81 (s, 1H), 2.83 (m, 1H), 2.61 (m, 2H), 2.32 (s, 3H), 2.16(s, 6H), 1.52 (m, 6H), 1.34 (m, 6H), 1.14 (m, 8H), 1.02 (m, 9H), 0.86-0.71 (m, 18H).

### Synthesis of a Compound La171

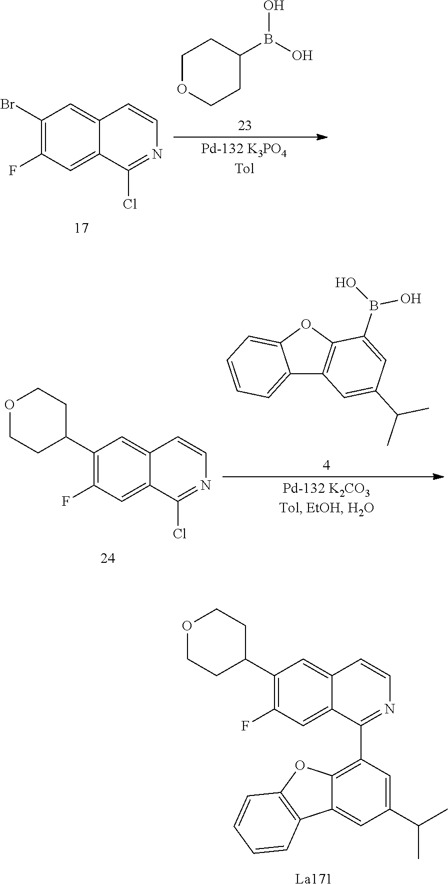

### Synthesis of a Compound 24

With reference to the synthesis and purification methods of the compound 3, only the corresponding raw materials were required to be changed, and a target compound 24 was obtained. The mass spectrum was 266.71 (M+H).

### Synthesis of a Compound La171

With reference to the synthesis and purification methods of the compound La001, only the corresponding raw materials were required to be changed, and a target compound La171 was obtained. The mass spectrum was 440.52 (M+H).

### Synthesis of a Compound Lc054

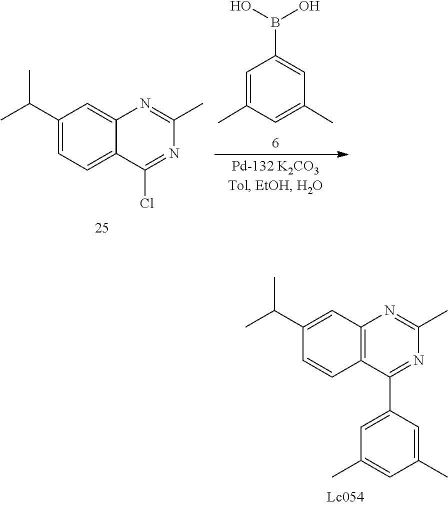

With reference to the synthesis and purification methods of the compound La001, only the corresponding raw materials were required to be changed, and a target compound Lc054 was obtained. The mass spectrum was 291.41 (M+H).

### Synthesis of a Compound Ir(La171)(Lb033)(Lc054)

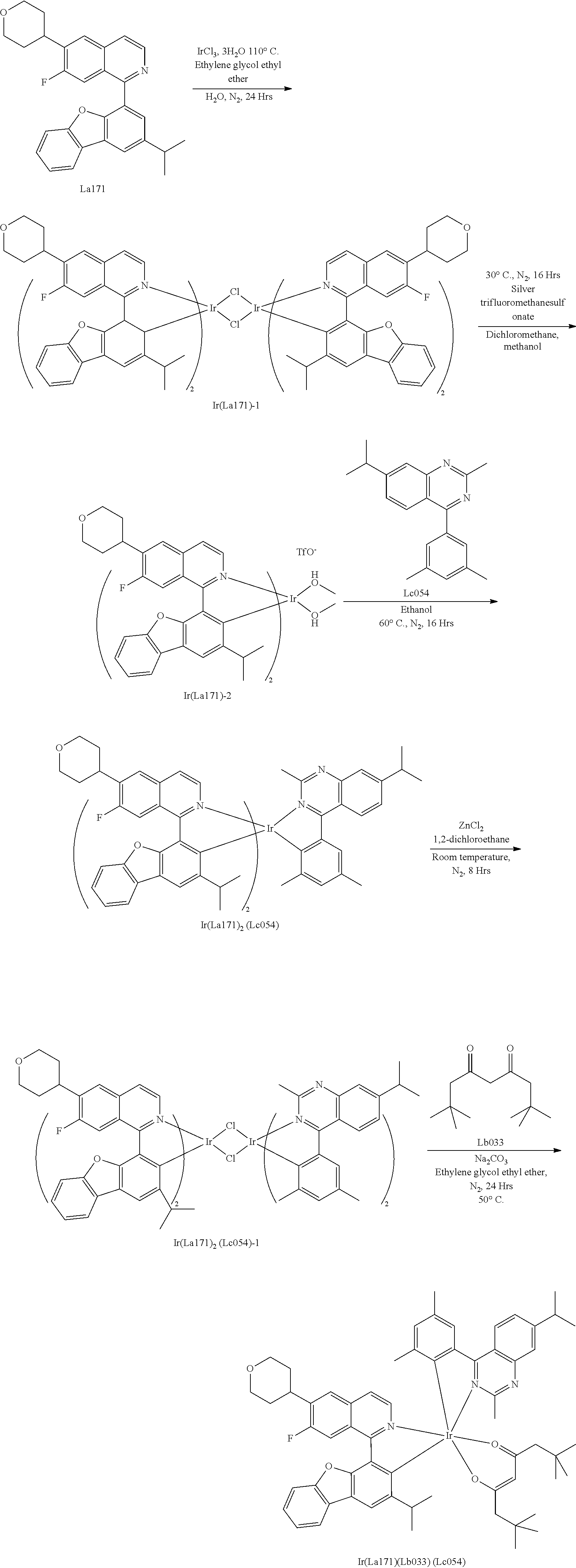

### Synthesis of a Compound Ir(La171)-1

With reference to the synthesis and purification methods of the compound Ir(La001)-1, only the corresponding raw materials were required to be changed, and a target compound Ir(La171)-1 was obtained and directly used in the next step without purification.

### Synthesis of a Compound Ir(La171)-2

With reference to the synthesis and purification methods of the compound Ir(La001)-2, only the corresponding raw materials were required to be changed, and a target compound Ir(La171)-2 was obtained and directly used in the next step without purification.

### Synthesis of a Compound Ir(La171)₂(Lc054)

With reference to the synthesis and purification methods of the compound Ir(La001)₂(Lc002), only the corresponding raw materials were required to be changed, and a target compound Ir(La171)₂(Lc054) was obtained. The mass spectrum was 1259.64 (M+H).

### Synthesis of a Compound Ir(La171)₂(Lc054)-1

With reference to the synthesis and purification methods of the compound Ir(La001)₂(Lc002)-1, only the corresponding raw materials were required to be changed, and a target compound Ir(La171)₂(Lc054)-1 was obtained and directly used in the next step without purification.

### Synthesis of a Compound Ir(La171)(Lb033)(Lc054)

With reference to the synthesis and purification methods of the compound Ir(La001)(Lb031)(Lc002), only the corresponding raw materials were required to be changed, and 1.59 g of a dark red solid, namely compound Ir(La171)(Lb033)(Lc054), with a yield of 38.77% was obtained. 1.59 g of the crude product (La171)(Lb033)(Lc054) was sublimated and purified to obtain 0.93 g of sublimated pure Ir(La171)(Lb033)(Lc054) with a yield of 58.49%. The mass spectrum was: 1132.44 (M+H). ¹H NMR (400 MHz, CDCl₃) δ 8.75(d, 1H), 8.32(m, 1H), 8.25(s, 1H), 8.04 (d, 2H), 7.65 (m, 2H), 7.37 (m, 4H), 7.32 (m, 3H), 4.81 (s, 1H), 2.83 (m, 1H), 2.77 (m, 1H), 2.61 (m, 4H), 2.44 (s, 3H), 2.32 (d, J=15.0 Hz, 6H) , 1.49 (m, 6H), 1.27 (m, 6H), 1.15(m, 9H), 0.72-0.66 (m, 18H).

### Synthesis of a Compound Lc055

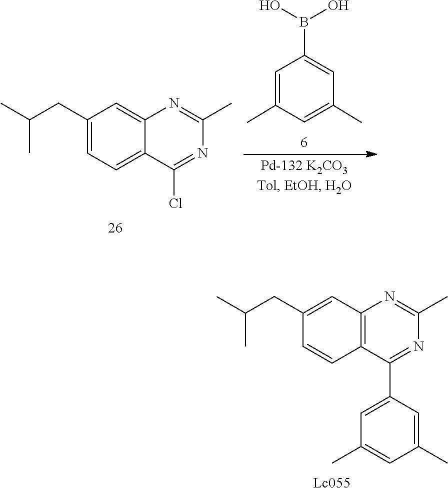

With reference to the synthesis and purification methods of the compound La001, only the corresponding raw materials were required to be changed, and a target compound Lc055 was obtained. The mass spectrum was 305.43 (M+H).

### Synthesis of a Compound Ir(La171)(Lb033)(Lc055)

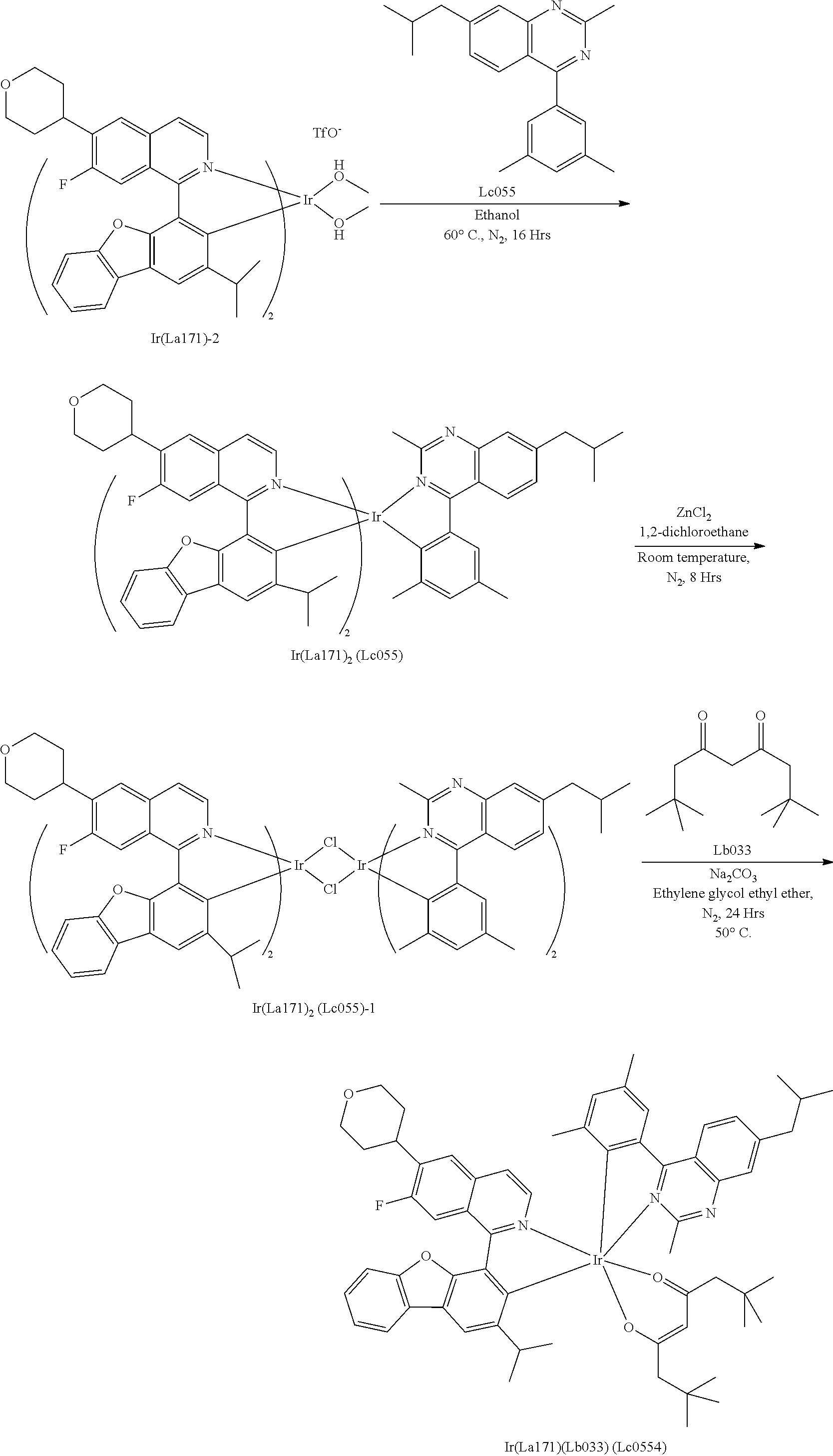

### Synthesis of a Compound Ir(La171)₂(Lc055)

With reference to the synthesis and purification methods of the compound Ir(La001)₂(Lc002), only the corresponding raw materials were required to be changed, and a target compound Ir(La171)₂(Lc055) was obtained. The mass spectrum was 1373.66 (M+H).

### Synthesis of a Compound Ir(La171)₂(Lc055)-1

With reference to the synthesis and purification methods of the compound Ir(La001)₂(Lc002)-1, only the corresponding raw materials were required to be changed, and a target compound Ir(La171)₂(Lc055)-1 was obtained and directly used in the next step without purification.

### Synthesis of a Compound Ir(La171)(Lb033)(Lc055)

With reference to the synthesis and purification methods of the compound Ir(La001)(Lb031)(Lc002), only the corresponding raw materials were required to be changed, and 1.66 g of a dark red solid, namely compound Ir(La171)(Lb033)(Lc055), with a yield of 41.17% was obtained. 1.66 g of the crude product (La171)(Lb033)(Lc055) was sublimated and purified to obtain 0.97 g of sublimated pure Ir(La171)(Lb033)(Lc055) with a yield of 58.43%. The mass spectrum was: 1146.47 (M+H). ¹H NMR (400 MHz, CDCl₃) δ 8.76(d, 1H), 8.29(m, 1H), 8.21(s, 1H), 8.01 (d, 2H), 7.64 (m, 2H), 7.33 (m, 4H), 7.29 (m, 3H), 4.81 (s, 1H), 2.83 (m, 1H), 2.69 (m, 1H), 2.57(m, 4H), 2.47(d, 2H), 2.32(s, 3H), 2.19 (d, J=15.0 Hz, 6H) , 1.46(m, 6H), 1.28(m, 6H), 1.14(m, 9H), 0.72-0.66 (m, 18H).

### Synthesis of a Compound Lc056

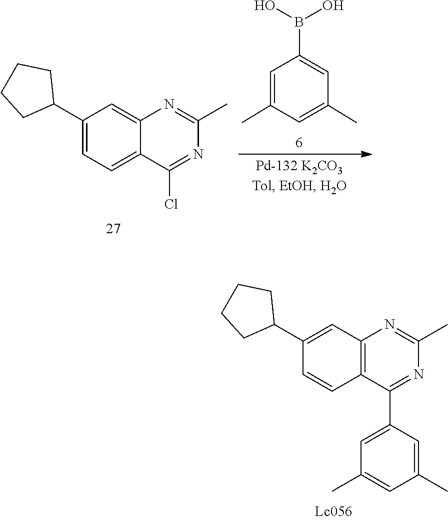

With reference to the synthesis and purification methods of the compound La001, only the corresponding raw materials were required to be changed, and a target compound Lc056 was obtained. The mass spectrum was 317.44 (M+H).

### Synthesis of a Compound Ir(La171)(Lb033)(Lc056)

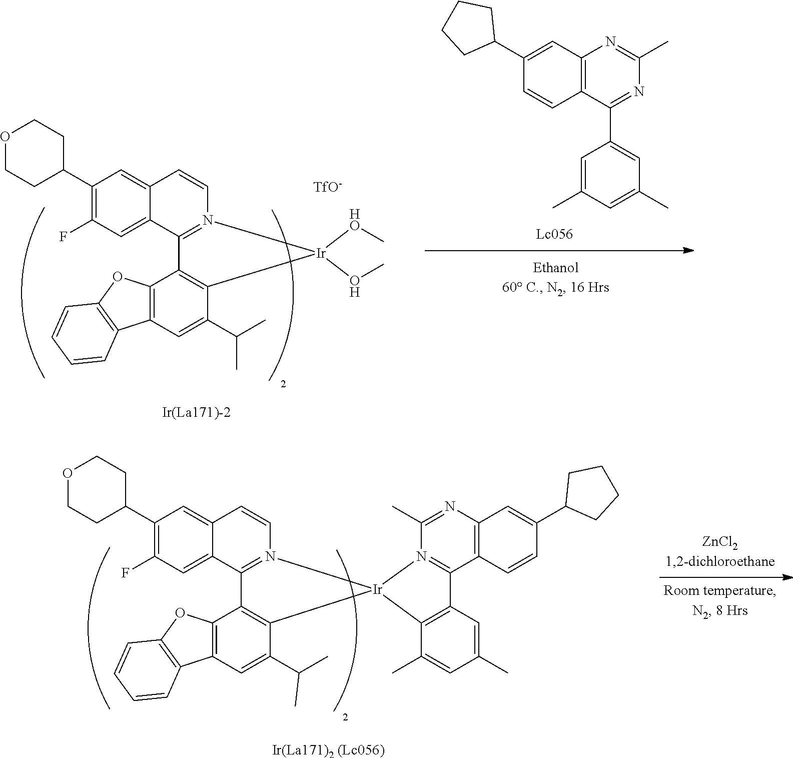

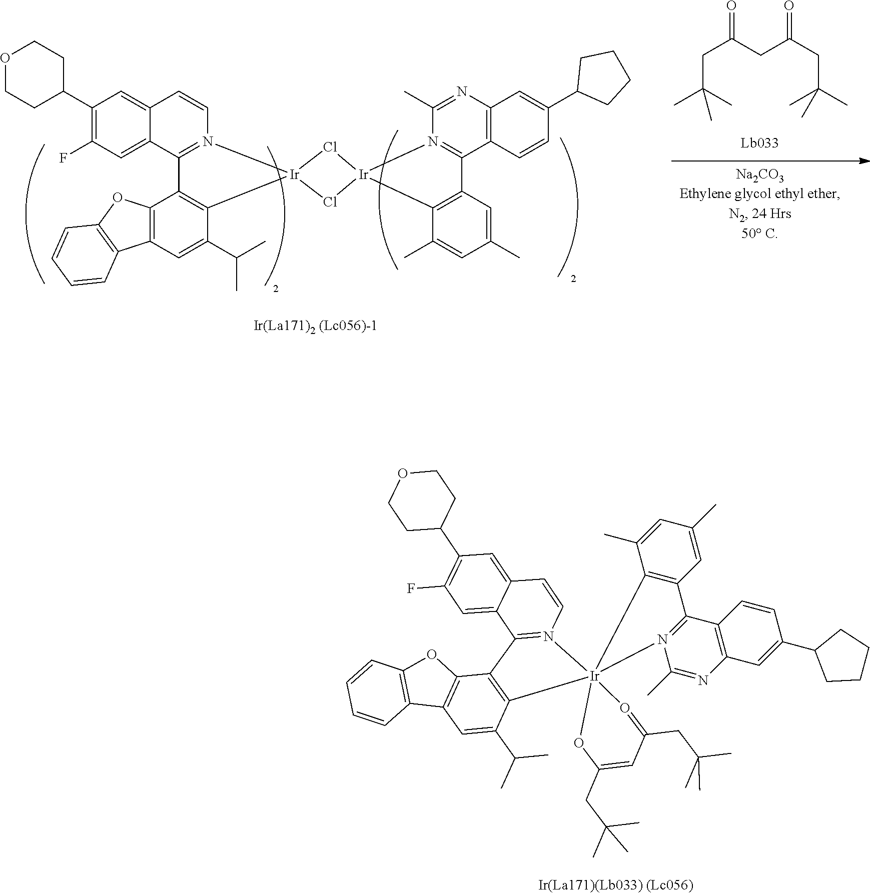

### Synthesis of a Compound Ir(La171)₂(Lc056)

With reference to the synthesis and purification methods of the compound Ir(La001)₂(Lc002), only the corresponding raw materials were required to be changed, and a target compound Ir(La171)₂(Lc056) was obtained. The mass spectrum was 1385.67 (M+H).

### Synthesis of a Compound Ir(La171)₂(Lc056)-1

With reference to the synthesis and purification methods of the compound Ir(La001)₂(Lc002)-1, only the corresponding raw materials were required to be changed, and a target compound Ir(La171)₂(Lc056)-1 was obtained and directly used in the next step without purification.

### Synthesis of a Compound Ir(La171)(Lb033)(Lc056)

With reference to the synthesis and purification methods of the compound Ir(La001)(Lb031)(Lc002), only the corresponding raw materials were required to be changed, and 1.72 g of a dark red solid, namely compound Ir(La171)(Lb033)(Lc056), with a yield of 40.64% was obtained. 1.72 g of the crude product (La171)(Lb033)(Lc056) was sublimated and purified to obtain 1.03 g of sublimated pure Ir(La171)(Lb033)(Lc056) with a yield of 59.88%. The mass spectrum was: 1158.48 (M+H). ¹H NMR (400 MHz, CDCl₃) δ 8.75(d, 1H), 8.27(m, 1H), 8.19(s, 1H),7.96 (d, 2H), 7.61(m, 2H), 7.30 (m, 4H), 7.22 (m, 3H), 4.80 (s, 1H), 2.81 (m, 1H), 2.67 (m, 1H), 2.55(m, 4H), 2.29(s, 3H), 2.17(d, J=15.0 Hz, 6H), 1.49(m, 8H), 1.28(m, 6H), 1.14(m, 9H), 0.77-0.68 (m, 18H).

### Application Example: Manufacture of an Organic Electroluminescent Device

A glass substrate with a size of 50 mm*50 mm*1.0 mm including an ITO anode electrode (70 Å/1,000 Å/110 Å) was ultrasonically cleaned in ethanol for 10 minutes, dried at 150° C., and then treated with N₂ plasma for 30 minutes. The washed glass substrate was installed on a substrate support of a vacuum evaporation device. First, compounds HTM1 and P-dopant (at a ratio of 97%:3%) for covering the electrode were co-evaporated on the surface of the side having an anode electrode line to form a thin film having a thickness of 100 Å. Then, a layer of HTM1 was evaporated to form a thin film having a thickness of 1,720 Å. Then, a layer of HTM2 was evaporated on the HTM1 thin film to form a thin film having a thickness of 100 Å. After that, a main material 1, a main material 2 and a doping compound (including a reference compound X or the compound of the present invention) were C₀-evaporated on the HTM2 film layer at a ratio of 48.5%:48.5%:3% to form a film having a thickness of 400 Å, where the ratio of the main materials to the doping material was 90%:10%. ETL and LiQ were co-evaporated on a light-emitting layer at a ratio of 50%:50% to obtain reach a thickness of 350 Å. Then, Yb was evaporated on an electron transport layer to reach a thickness of 10 Å. Finally, a layer of metal Ag was evaporated to serve as an electrode having a thickness of 150 Å.

| | HIL | HTL | EBL | | Electron |
|---|---|---|---|---|---|
| | Thick- | Thick- | Thick- | Emission layer | transport layer |
| Example | ness/Å | ness/Å | ness/Å | Thickness/Å | Thickness/Å |
| A1 | HTM1: | HTM1 | HTM2 | H1:H2:Ir(La001)(Lb031)(Lc002) | ETL: LiQ |
| | NDP-9 | 1720 | 100 | 400 | 350 |
| | 100 | | | | |
| A2 | HTM1: | HTM1 | HTM2 | H1:H2:Ir(La001)(Lb031)(Lc003) | ETL: LiQ |
| | NDP-9 | 1720 | 100 | 400 | 350 |
| | 100 | | | | |
| A3 | HTM1: | HTM1 | HTM2 | H1:H2:Ir(La001)(Lb031)(Lc005) | ETL: LiQ |
| | NDP-9 | 1720 | 100 | 400 | 350 |
| | 100 | | | | |
| A4 | HTM1: | HTM1 | HTM2 | H1:H2:Ir(La027)(Lb005)(Lc002) | ETL: LiQ |
| | NDP-9 | 1720 | 100 | 400 | 350 |
| | 100 | | | | |
| A5 | HTM1: | HTM1 | HTM2 | H1:H2:Ir(La027)(Lb005)(Lc003) | ETL: LiQ |
| | NDP-9 | 1720 | 100 | 400 | 350 |
| | 100 | | | | |
| A6 | HTM1: | HTM1 | HTM2 | H1:H2:Ir(La027)(Lb005)(Lc005) | ETL: LiQ |
| | NDP-9 | 1720 | 100 | 400 | 350 |
| | 100 | | | | |
| A7 | HTM1: | HTM1 | HTM2 | H1:H2:Ir(La037)(Lb005)(Lc020) | ETL: LiQ |
| | NDP-9 | 1720 | 100 | 400 | 350 |
| | 100 | | | | |
| A8 | HTM1: | HTM1 | HTM2 | H1:H2:Ir(La037)(Lb005)(Lc024) | ETL: LiQ |
| | NDP-9 | 1720 | 100 | 400 | 350 |
| | 100 | | | | |
| A9 | HTM1: | HTM1 | HTM2 | H1:H2:Ir(La037)(Lb005)(Lc025) | ETL: LiQ |
| | NDP-9 | 1720 | 100 | 400 | 350 |
| | 100 | | | | |
| A10 | HTM1: | HTM1 | HTM2 | H1:H2:Ir(La037)(Lb005)(Lc026) | ETL: LiQ |
| | NDP-9 | 1720 | 100 | 400 | 350 |
| | 100 | | | | |
| A11 | HTM1: | HTM1 | HTM2 | H1:H2:Ir(La080)(Lb018)(Lc048) | ETL: LiQ |
| | NDP-9 | 1720 | 100 | 400 | 350 |
| | 100 | | | | |
| A12 | HTM1: | HTM1 | HTM2 | H1:H2:Ir(La080)(Lb018)(Lc049) | ETL: LiQ |
| | NDP-9 | 1720 | 100 | 400 | 350 |
| | 100 | | | | |
| A13 | HTM1: | HTM1 | HTM2 | H1:H2:Ir(La080)(Lb018)(Lc050) | ETL: LiQ |
| | NDP-9 | 1720 | 100 | 400 | 350 |
| | 100 | | | | |
| A14 | HTM1: | HTM1 | HTM2 | H1:H2:Ir(La171)(Lb033)(Lc054) | ETL: LiQ |
| | NDP-9 | 1720 | 100 | 400 | 350 |
| | 100 | | | | |
| A15 | HTM1: | HTM1 | HTM2 | H1:H2:Ir(La037)(Lb005)(Lc055) | ETL: LiQ |
| | NDP-9 | 1720 | 100 | 400 | 350 |
| | 100 | | | | |
| A16 | HTM1: | HTM1 | HTM2 | H1:H2:Ir(La171)(Lb033)(Lc056) | ETL: LiQ |
| | NDP-9 | 1720 | 100 | 400 | 350 |
| | 100 | | | | |
| Compa- | HTM1: | HTM1 | HTM2 | H1:H2:reference | ETL: LiQ |
| rative | NDP-9 | 1720 | 100 | compound 1 | 350 |
| Exam- | 100 | | | 400 | |
| ple 1 | | | | | |
| Compa- | HTM1: | HTM1 | HTM2 | H1:H2:reference | ETL: LiQ |
| rative | NDP-9 | 1720 | 100 | compound 2 | 350 |
| Exam- | 100 | | | 400 | |
| ple 2 | | | | | |
| Compa- | HTM1: | HTM1 | HTM2 | H1:H2:reference | ETL: LiQ |
| rative | NDP-9 | 1720 | 100 | compound 3 | 350Q |
| Exam- | 100 | | | 400 | |
| ple 3 | | | | | |
| Compa- | HTM1: | HTM1 | HTM2 | H1:H2:reference | ETL: LiQ |
| rative | NDP-9 | 1720 | 100 | compound 4 | 350 |
| Exam- | 100 | | | 400 | |
| ple 4 | | | | | |
| Compa- | HTM1: | HTM1 | HTM2 | H1:H2:reference | ETL: LiQ |
| rative | NDP-9 | 1720 | 100 | compound 5 | 350 |
| Exam- | 100 | | | 400 | |
| ple 5 | | | | | |
| Compa- | HTM1: | HTM1 | HTM2 | H1:H2:reference | ETL: LiQ |
| rative | NDP-9 | 1720 | 100 | compound 6 | 350 |
| Exam- | 100 | | | 400 | |
| ple 6 | | | | | |

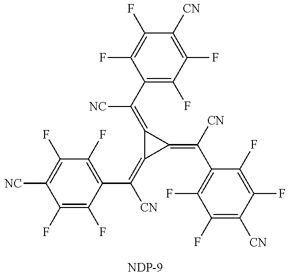

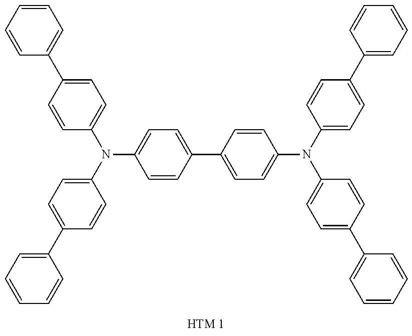 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

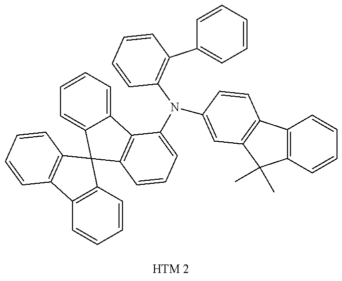 [SMILES: CC1(C)c2ccccc2-c2ccc(N(c3ccccc3-c3ccccc3)c3cccc4c3-c3ccccc3C43c4ccccc4-c4ccccc43)cc21]

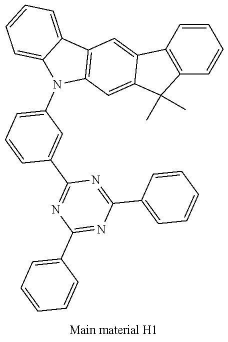 [SMILES: CC1(C)c2ccccc2-c2cc3c4ccccc4n(-c4cccc(-c5nc(-c6ccccc6)nc(-c6ccccc6)n5)c4)c3cc21]

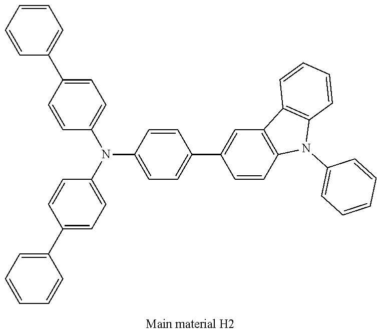 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

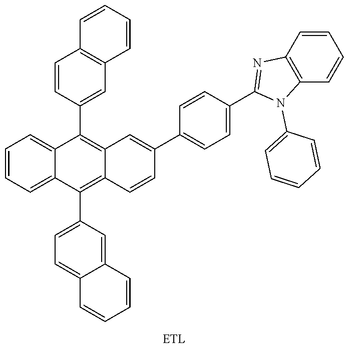 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

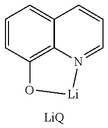

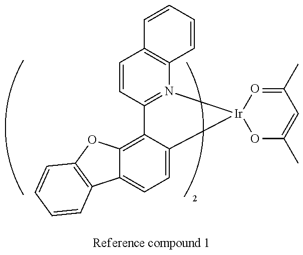

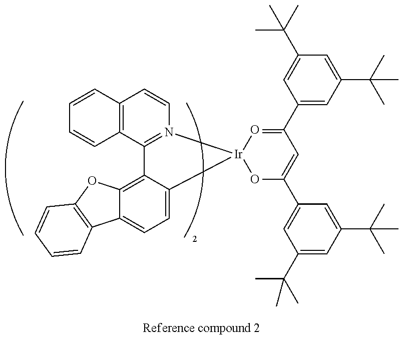

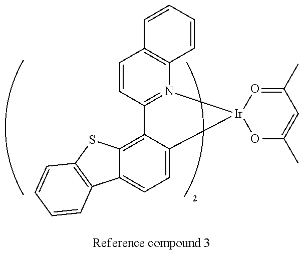

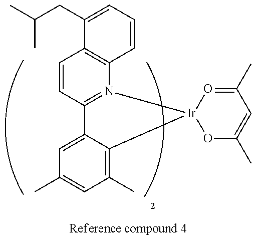

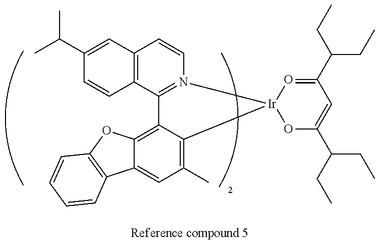

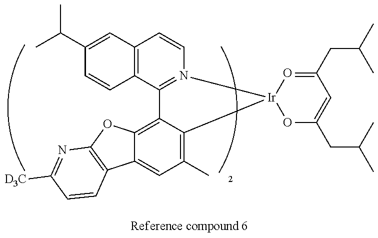

Evaluation: Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT90) when the brightness was reduced to 90% of the initial brightness was tested. Results are as follows. The current efficiency and the device service life are calculated with the valve, of the reference rnmnniind 5 as 100%.

| | Starting | | Chromaticity | |
|---|---|---|---|---|
| | voltage | Current | coordinate | |
| | @20 mA/ | efficiency | @20 mA/ | LT90@ |
| | cm² | @20 mA/ | cm² | 8000 |
| | V | cm² | CIEx, CIEy | nits |
| Example A1 | 4.38 | 129 | 0.701, 0.298 | 130 |
| Example A2 | 4.40 | 131 | 0.703, 0.296 | 132 |
| Example A3 | 4.41 | 133 | 0.702, 0.297 | 132 |
| Example A4 | 4.46 | 132 | 0.702, 0.298 | 133 |
| Example A5 | 4.45 | 137 | 0.701, 0.298 | 136 |
| Example A6 | 4.46 | 139 | 0.702, 0.297 | 138 |
| Example A7 | 4.43 | 140 | 0.702, 0.296 | 132 |
| Example A8 | 4.45 | 145 | 0.700, 0.299 | 136 |
| Example A9 | 4.42 | 141 | 0.701, 0.298 | 139 |
| Example A10 | 4.44 | 142 | 0.703, 0.296 | 140 |
| Example A11 | 4.39 | 136 | 0.700, 0.299 | 141 |
| Example A12 | 4.41 | 139 | 0.702, 0.296 | 139 |
| Example A13 | 4.40 | 140 | 0.701, 0.298 | 143 |
| Example A14 | 4.42 | 137 | 0.702, 0.297 | 155 |
| Example A15 | 4.43 | 142 | 0.702, 0.297 | 157 |
| Example A16 | 4.42 | 144 | 0.701, 0.298 | 162 |
| Comparative | 5.23 | 75 | 0.700, 0.299 | 51 |
| Example 1 | | | | |
| Comparative | 5.15 | 72 | 0.701, 0.298 | 50 |
| Example 2 | | | | |
| Comparative | 5.34 | 74 | 0.703, 0.296 | 42 |
| Example 3 | | | | |
| Comparative | 5.52 | 63 | 0.702, 0.297 | 37 |
| Example 4 | | | | |
| Comparative | 4.88 | 100 | 0.701, 0.298 | 100 |
| Example 5 | | | | |
| Comparative | 4.74 | 95 | 0.702, 0.298 | 118 |
| Example 6 | | | | |

Through comparison of the data in the above table, it can be seen that compared with reference compounds, the compound of the present invention used as a dopant in organic electroluminescent devices with the same chromaticity coordinate has more excellent properties, such as driving voltage, luminous efficiency, and device service life.

The comparison of emission wavelengths in a dichloromethane solution is defined as follows. A corresponding compound is prepared into a 10⁻⁵ mol/L solution with dichloromethane, and the emission wavelength is tested by Hitachi (HITACH) F2700 fluorescence spectrophotometer to obtain the wavelength at a maximum emission peak. Test results are shown as follows.

| | PL peak |
|---|---|
| Material | wavelength/nm |
| Ir(La001)(Lb031)(Lc002) | 626 |
| Ir(La027)(Lb005)(Lc003) | 627 |
| Ir(La037)(Lb005)(Lc024) | 629 |
| Ir(La171)(Lb033)(Lc055) | 630 |
| Reference compound 1 | 610 |
| Reference compound 2 | 637 |
| Reference compound 3 | 611 |
| Reference compound 4 | 608 |
| Reference compound 5 | 616 |

Through comparison of the data in the above table, it can be seen that compared with reference compounds, the metal iridium complex of the present invention has a larger red shift, so that industrial demands for dark red light, especially the BT2020 color gamut, can be met.

Comparison of the sublimation temperature is as follows. The sublimation temperature is defined as the temperature corresponding to an evaporation rate of 1 Å/s at a vacuum degree of 10⁻⁷ Torr. Test results are shown as follows.

| | Sublimation |
|---|---|
| Material | temperature |
| Ir(La001)(Lb031)(Lc002) | 259 |
| Ir(La027)(Lb005)(Lc003) | 262 |
| Ir(La037)(Lb005)(Lc024) | 255 |
| Ir(La171)(Lb033)(Lc055) | 265 |
| Reference compound 1 | 280 |
| Reference compound 2 | 288 |
| Reference compound 3 | 286 |
| Reference compound 4 | 276 |
| Reference compound 5 | 268 |

Through comparison of the data in the above table, it can be seen that the metal iridium complex of the present invention has low sublimation temperature, and industrial application is facilitated.

Compared with the prior art, the present invention unexpectedly provides better device luminous efficiency, improved service life, lower sublimation temperature and more saturated red luminescence through special collocation of substituents. According to the above results, it is indicated that the compound of the present invention has the advantages of low sublimation temperature, high optical and electrochemical stability, high color saturation, high luminous efficiency, and long device service life, and can be used in organic electroluminescent devices. In particular, the metal complex has the potential for application in the OLED industry as a red light-emitting dopant, especially in displays, lighting and car tail lights.

The compound of the present invention has the advantages of high optical and electrochemical stability, high color saturation, high luminous efficiency, and long device service life, and can be used in organic electroluminescent devices. In particular, the iridium complex has the potential for application in the OLED industry as a red light-emitting dopant.

1. An iridium complex, having a structure of Ir(La)(Lb)(Lc),
wherein La, Lb, and Lc are different from each other, the “different from each other” refers to having different parent nuclear structures, having same parent nuclear structures but different substituents, or having same parent nuclear structures and same substituents but different positions of the substituents, all the La, the Lb, and the Lc are a monoanionic bidentate ligand, any two of the La, the Lb, and the Lc are connected to each other to form a multidentate ligand, or the La, the Lb, and the Lc are connected by a group;
the ligand La is as shown in a formula (1): 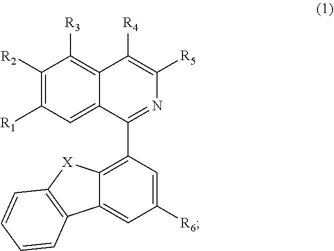
X is independently selected from O, S, and Se;
R₁-R₅ are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, substituted or unsubstituted C₃-C₂₀ heterocycloalkyl, substituted or unsubstituted C₃-C₃₀ alkylsilyl, substituted or unsubstituted C₁-C₁₀ alkoxyl, substituted or unsubstituted C₇-C₃₀ aralkyl, substituted or unsubstituted C₆-C₃₀ aryloxyl, substituted or unsubstituted C₂-C₂₀ alkenyl, substituted or unsubstituted C₂-C₂₀ alkynyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino;
at least one of the R₁-R5 is F, and another one is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;
R₆ is substituted or unsubstituted C₁-C₁₀ alkyl, substituted or unsubstituted C₃-C₂₀ cycloalkyl, substituted or unsubstituted C₁-C₁₀ heteroalkyl, or substituted or unsubstituted C₃-C₂₀ heterocycloalkyl;
the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino;
and the heteroalkyl, the heterocycloalkyl, or the heteroaryl comprises at least one of S, O, and N heteroatoms.

2. The iridium complex according to claim 1, wherein the Lb has a structure as shown in a formula (2): 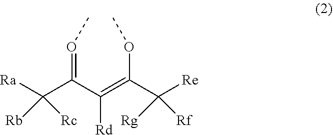
wherein a dotted line refers to a position connected to metal Ir;
Rₐ-R_{g} are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocycloalkyl, or any two of Rₐ , R_{b}, and R_{c} are connected to each other to form an aliphatic ring structure, and any two of Rₑ, R_{f}, and R_{g} are connected to each other to form an aliphatic ring structure; the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, nitrile, isonitrile, or phosphino; and the heteroalkyl or the heterocycloalkyl comprises at least one of S, O, and N heteroatoms.

3. The iridium complex according to claim 2, wherein the Rₐ , the R_{b}, and the R_{c} are the same as the Rₑ, the R_{f}, and the R_{g}, respectively.

4. The iridium complex according to claim 3, wherein the Rₐ , the R_{b}, the R_{c}, the Rₑ, the R_{f}, and the R_{g} are independently selected from hydrogen, deuterium, halogen, substituted or unsubstituted alkyl containing 1-10 carbon atoms on a main chain, and substituted or unsubstituted cycloalkyl containing 3-20 ring forming carbon atoms, or any two of the Rₐ, the R_{b}, and the R_{c} are connected to each other to form an aliphatic ring structure, and any two of the Rₑ, the R_{f}, and the R_{g} are connected to each other to form an aliphatic ring structure; R_{d} is selected from hydrogen, deuterium, halogen, and substituted or unsubstituted alkyl containing 1-10 carbon atoms on a main chain; and the “substituted” refers to substitution with deuterium, F, Cl, Br, C₁-C₄ alkyl, or C₃-C₆ cycloalkyl.

5. The iridium complex according to claim 2, wherein the Lc has any one structure as shown in a formula (3) to a formula (5): 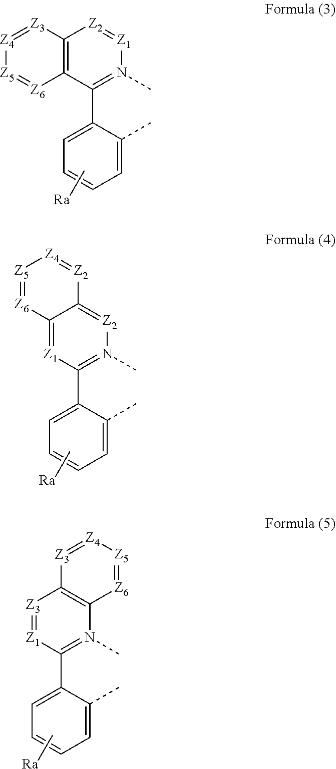
wherein Z₁-Z₆ are independently N or CR₀;
the number of Rₐ ranges from a minimum substitution number to a maximum substitution number;
R₀ and the Rₐ are independently selected from hydrogen, deuterium, halogen, substituted or unsubstituted C₁-C₂₀ alkyl, substituted or unsubstituted C₃-C₃₀ cycloalkyl, substituted or unsubstituted C₁-C₃₀ heteroalkyl, substituted or unsubstituted C₃-C₃₀ heterocycloalkyl, substituted or unsubstituted C₇-C₃₀ aralkyl, substituted or unsubstituted C₁-C₂₀ alkoxyl, substituted or unsubstituted C₆-C₃₀ aryloxyl, substituted or unsubstituted C₂-C₂₀ alkenyl, substituted or unsubstituted C₃-C₃₀ alkylsilyl, substituted or unsubstituted C₆-C₃₀ aryl, substituted or unsubstituted C₃-C₃₀ heteroaryl, substituted or unsubstituted C₃-C₃₀ arylsilyl, substituted or unsubstituted C₀-C₂₀ amino, cyano, nitrile, isonitrile, and phosphino, or two adjacent substituents may be optionally connected to form a ring or a fused structure;
the “substituted” refers to substitution with deuterium, F, Cl, Br, C₁-C₁₀ alkyl, C₁-C₁₀ alkoxyl, C₃-C₁₀ cycloalkyl, amino substituted with C₁-C₁₀ alkyl, C₆-C₃₀ aryl, C₇-C₃₀ aralkyl, cyano, nitrile, isonitrile, or phosphino;
and the heteroalkyl, the heterocycloalkyl, or the heteroaryl comprises at least one of S, O, and N heteroatoms.

6. The iridium complex according to claim 5, wherein at least two of the Rₐ are not hydrogen; and at least one of the Z₁-Z₆ is CR₀.

7. The iridium complex according to claim 6, wherein the Rₐ is substituted or unsubstituted C₁-C₈ alkyl, the R₀ is selected from substituted or unsubstituted C₁-C₈ alkyl and substituted or unsubstituted C₃-C₆ cycloalkyl, and the “substituted” refers to substitution with deuterium, F, Cl, Br, or C₁-C₄ alkyl.

8. The iridium complex according to any one of claims 1-7, wherein the R₆ is substituted or unsubstituted C₁-C₄ alkyl, or substituted or unsubstituted C₃-C₆ cycloalkyl.

9. The iridium complex according to claim 8, wherein the F is not positioned at the R₅; and the X is an O atom.

10. The iridium complex according to claim 9, wherein one of the R₁-R₅ is F, another one is substituted or unsubstituted alkyl containing no more than 4 carbon atoms on a main chain, or substituted or unsubstituted cycloalkyl containing no more than 6 ring forming carbon atoms, and the other three are hydrogen.

11. The iridium complex according to claim 10, wherein when one of the R₁-R₅ is F, another one is branched C₁-C₄ alkyl substituted with C₁-C₄ alkyl.

12. The iridium complex according to claim 1, wherein the La is independently selected from one of the following structural formulas, or corresponding parts or complete deuterides or fluorides thereof:

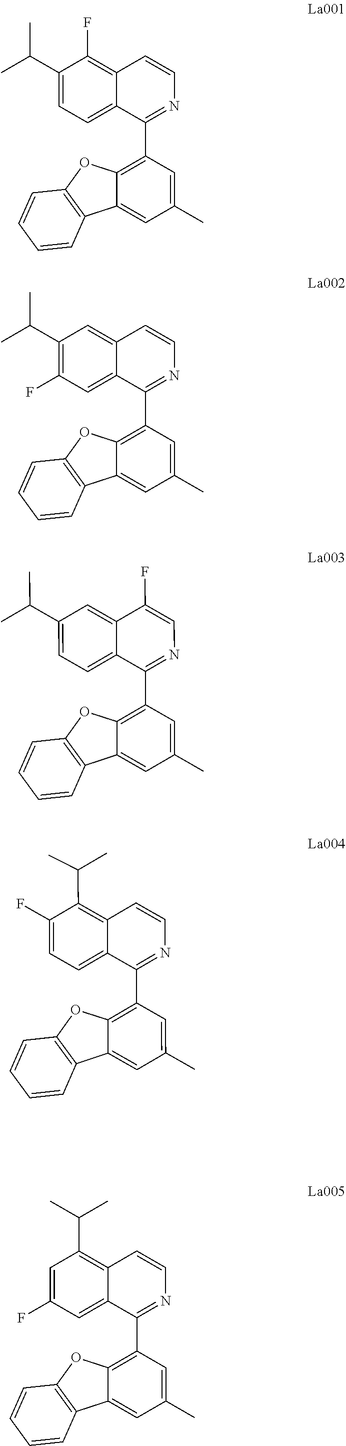

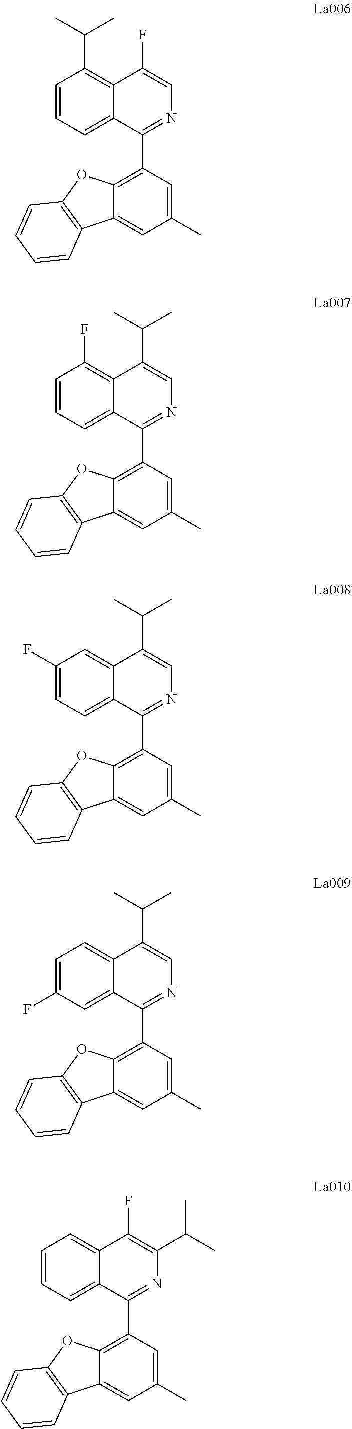 [SMILES: Cc1cc(-c2ncc(F)c3c(C(C)C)cccc23)c2oc3ccccc3c2c1 ; Cc1cc(-c2ncc(C(C)C)c3c(F)cccc23)c2oc3ccccc3c2c1 ; Cc1cc(-c2ncc(C(C)C)c3cc(F)ccc23)c2oc3ccccc3c2c1 ; Cc1cc(-c2ncc(C(C)C)c3ccc(F)cc23)c2oc3ccccc3c2c1 ; Cc1cc(-c2nc(C(C)C)c(F)c3ccccc23)c2oc3ccccc3c2c1]

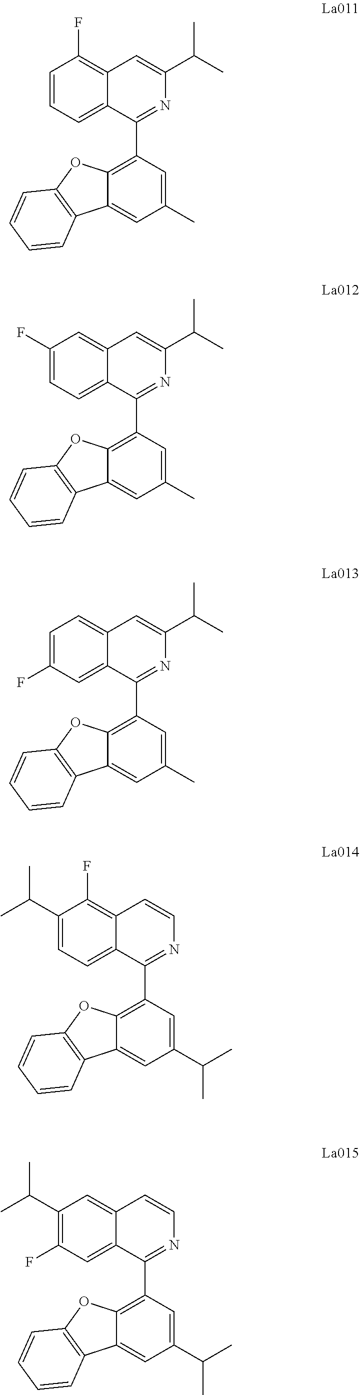

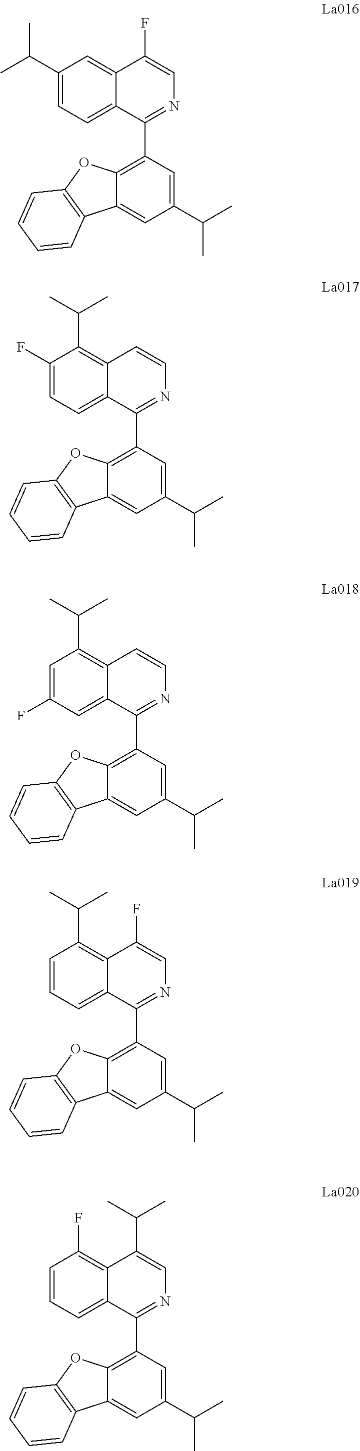 [SMILES: CC(C)c1ccc2c(-c3cc(C(C)C)cc4c3oc3ccccc34)ncc(F)c2c1 ; CC(C)c1cc(-c2nccc3c(C(C)C)c(F)ccc23)c2oc3ccccc3c2c1 ; CC(C)c1cc(-c2nccc3c(C(C)C)cc(F)cc23)c2oc3ccccc3c2c1 ; CC(C)c1cc(-c2ncc(F)c3c(C(C)C)cccc23)c2oc3ccccc3c2c1 ; CC(C)c1cc(-c2ncc(C(C)C)c3c(F)cccc23)c2oc3ccccc3c2c1]

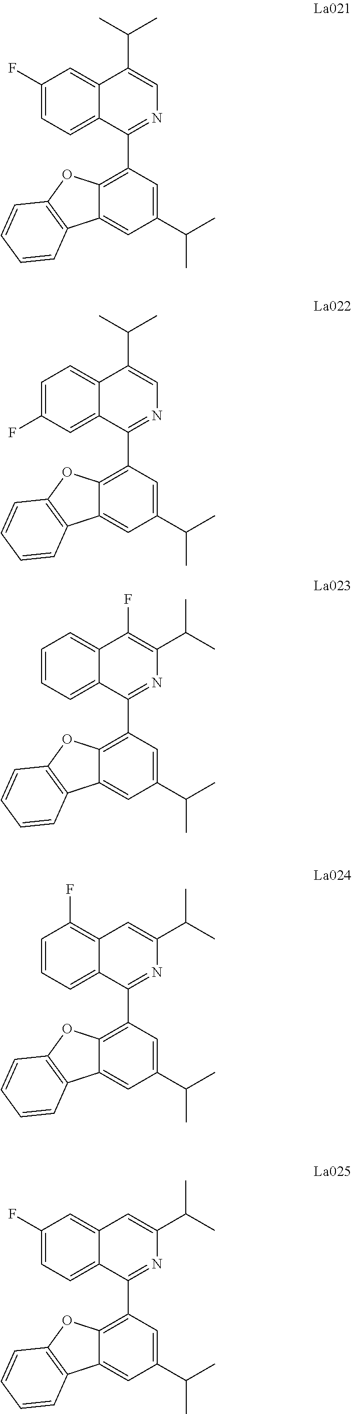

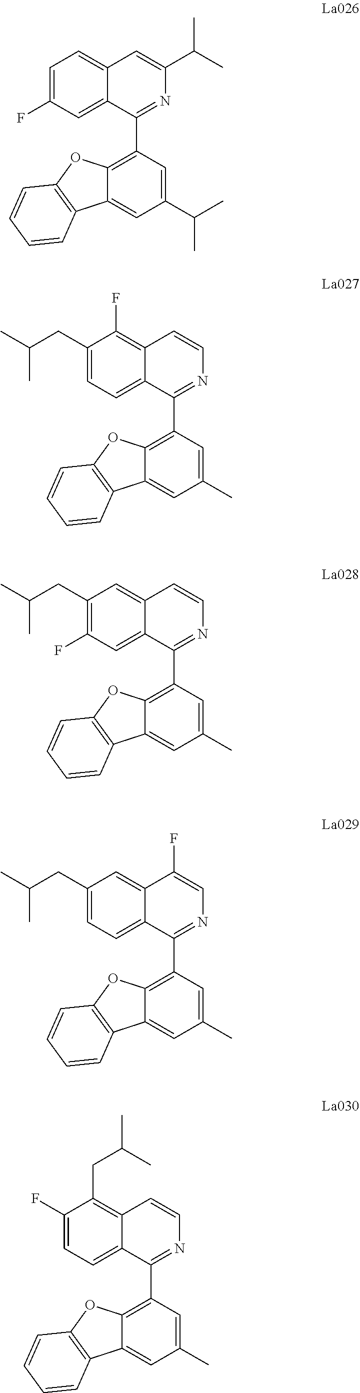

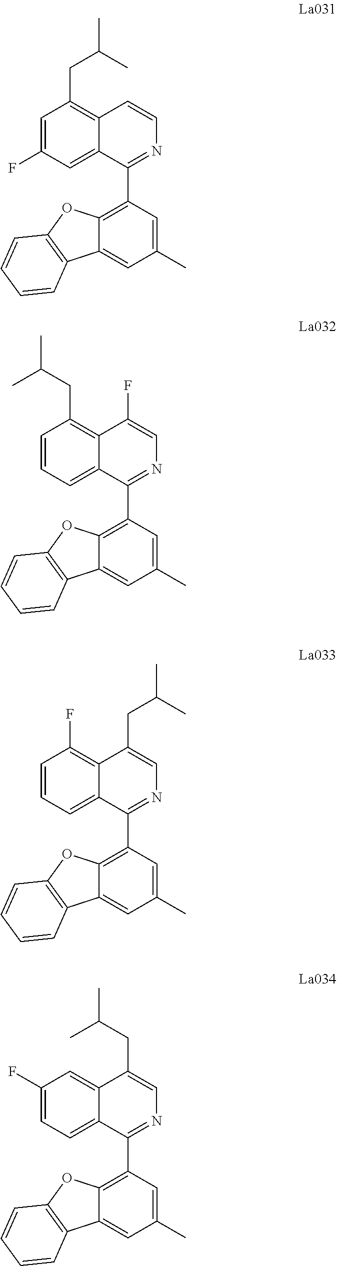

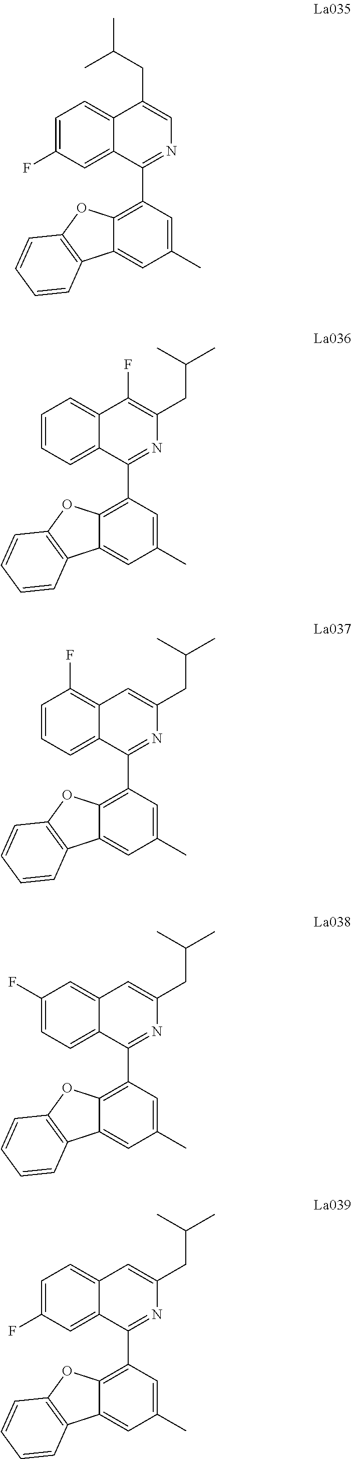 [SMILES: Cc1cc(-c2ncc(CC(C)C)c3ccc(F)cc23)c2oc3ccccc3c2c1 ; Cc1cc(-c2nc(CC(C)C)c(F)c3ccccc23)c2oc3ccccc3c2c1 ; Cc1cc(-c2nc(CC(C)C)cc3c(F)cccc23)c2oc3ccccc3c2c1 ; Cc1cc(-c2nc(CC(C)C)cc3cc(F)ccc23)c2oc3ccccc3c2c1 ; Cc1cc(-c2nc(CC(C)C)cc3ccc(F)cc23)c2oc3ccccc3c2c1]

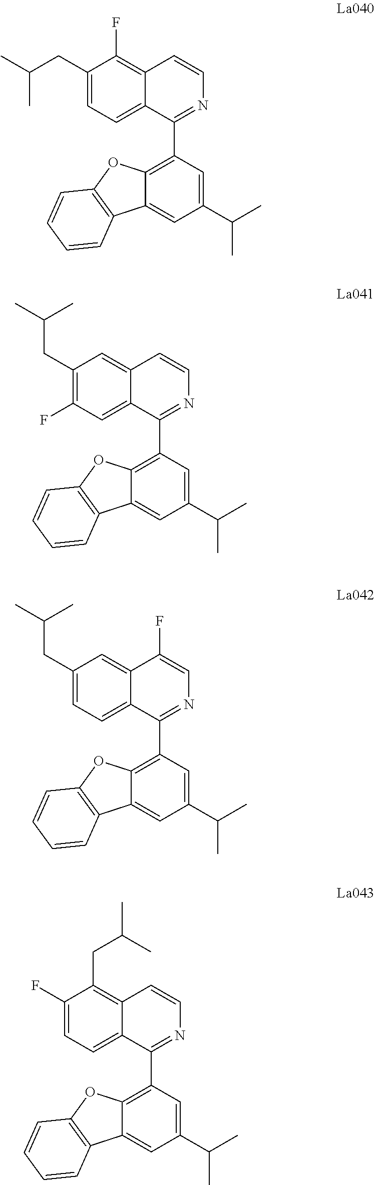

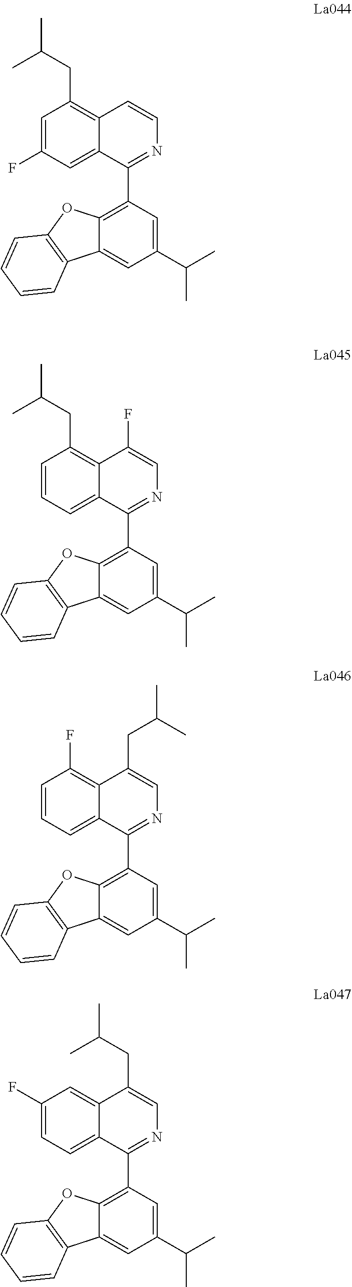 [SMILES: CC(C)Cc1cc(F)cc2c(-c3cc(C(C)C)cc4c3oc3ccccc34)nccc12 ; CC(C)Cc1cccc2c(-c3cc(C(C)C)cc4c3oc3ccccc34)ncc(F)c12 ; CC(C)Cc1cnc(-c2cc(C(C)C)cc3c2oc2ccccc23)c2cccc(F)c12 ; CC(C)Cc1cnc(-c2cc(C(C)C)cc3c2oc2ccccc23)c2ccc(F)cc12]

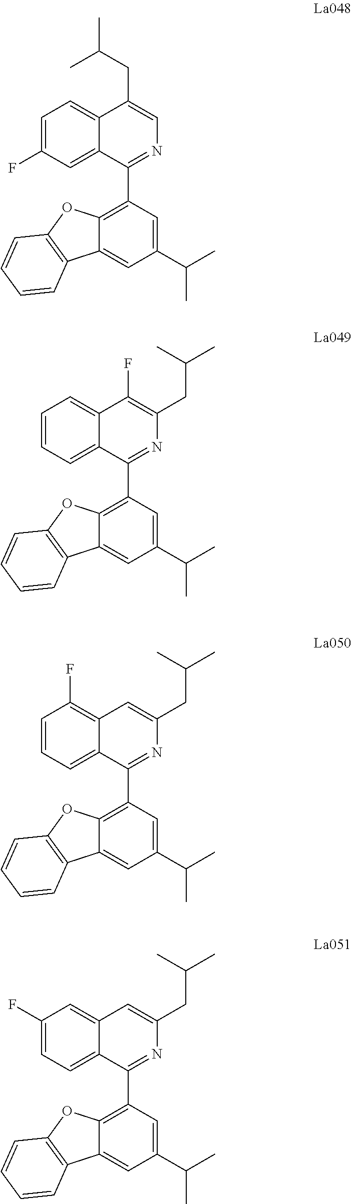 [SMILES: CC(C)Cc1cnc(-c2cc(C(C)C)cc3c2oc2ccccc23)c2cc(F)ccc12 ; CC(C)Cc1nc(-c2cc(C(C)C)cc3c2oc2ccccc23)c2ccccc2c1F ; CC(C)Cc1cc2c(F)cccc2c(-c2cc(C(C)C)cc3c2oc2ccccc23)n1 ; CC(C)Cc1cc2cc(F)ccc2c(-c2cc(C(C)C)cc3c2oc2ccccc23)n1]

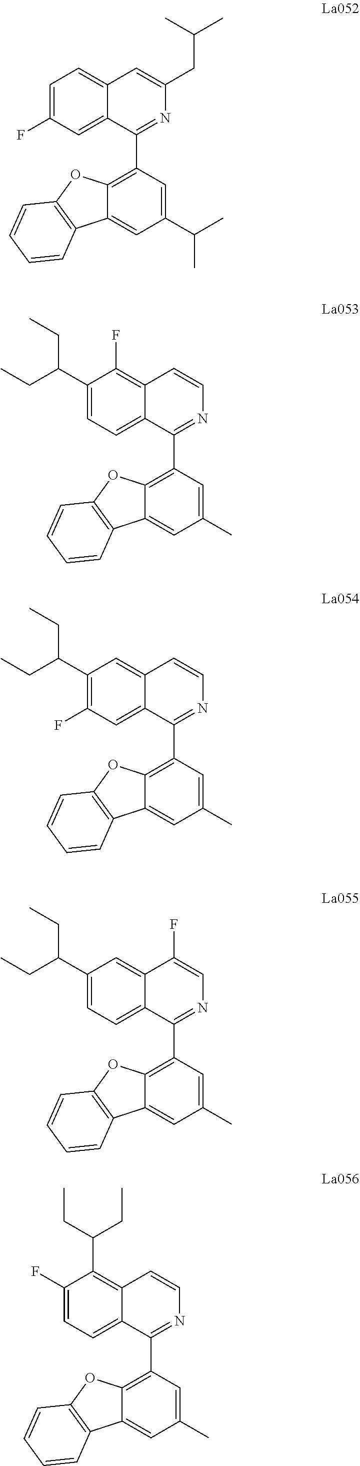

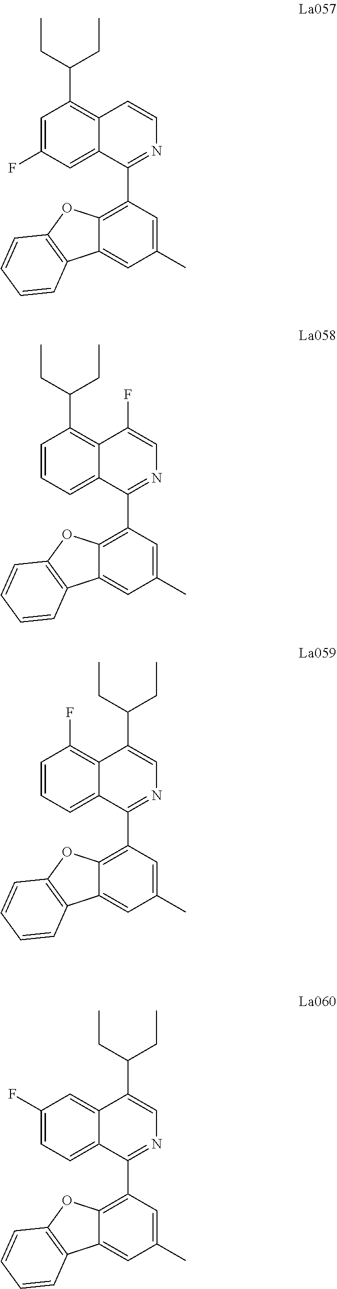 [SMILES: CCC(CC)c1cc(F)cc2c(-c3cc(C)cc4c3oc3ccccc34)nccc12 ; CCC(CC)c1cccc2c(-c3cc(C)cc4c3oc3ccccc34)ncc(F)c12 ; CCC(CC)c1cnc(-c2cc(C)cc3c2oc2ccccc23)c2cccc(F)c12 ; CCC(CC)c1cnc(-c2cc(C)cc3c2oc2ccccc23)c2ccc(F)cc12]

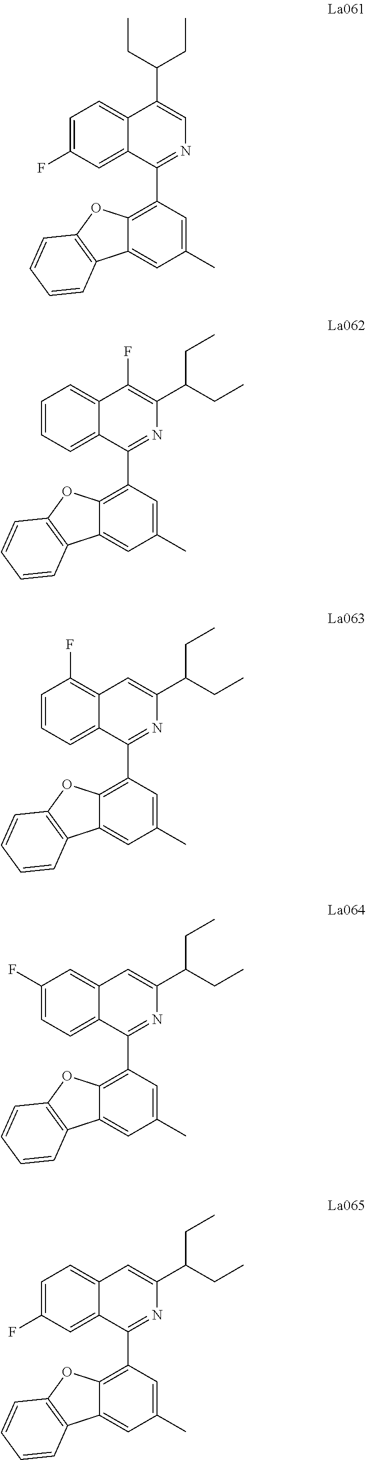 [SMILES: CCC(CC)c1cnc(-c2cc(C)cc3c2oc2ccccc23)c2cc(F)ccc12 ; CCC(CC)c1nc(-c2cc(C)cc3c2oc2ccccc23)c2ccccc2c1F ; CCC(CC)c1cc2c(F)cccc2c(-c2cc(C)cc3c2oc2ccccc23)n1 ; CCC(CC)c1cc2cc(F)ccc2c(-c2cc(C)cc3c2oc2ccccc23)n1 ; CCC(CC)c1cc2ccc(F)cc2c(-c2cc(C)cc3c2oc2ccccc23)n1]

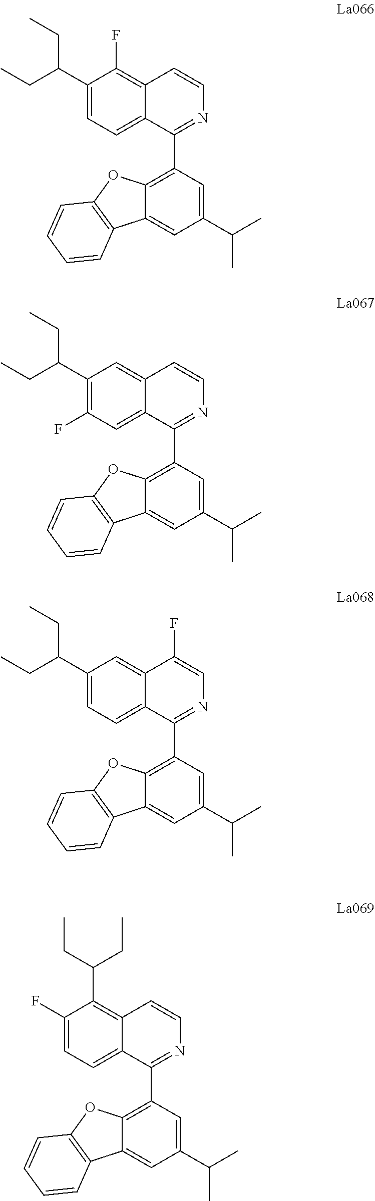

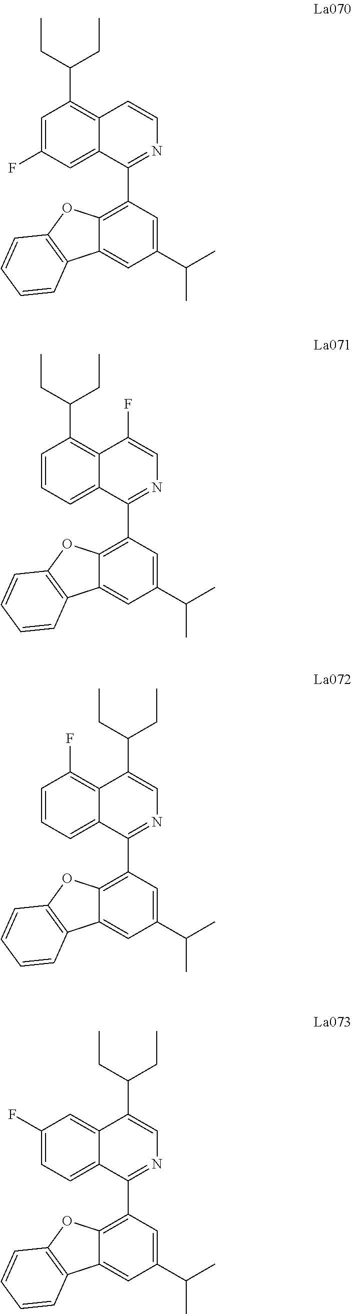 [SMILES: CCC(CC)c1cc(F)cc2c(-c3cc(C(C)C)cc4c3oc3ccccc34)nccc12 ; CCC(CC)c1cccc2c(-c3cc(C(C)C)cc4c3oc3ccccc34)ncc(F)c12 ; CCC(CC)c1cnc(-c2cc(C(C)C)cc3c2oc2ccccc23)c2cccc(F)c12 ; CCC(CC)c1cnc(-c2cc(C(C)C)cc3c2oc2ccccc23)c2ccc(F)cc12]

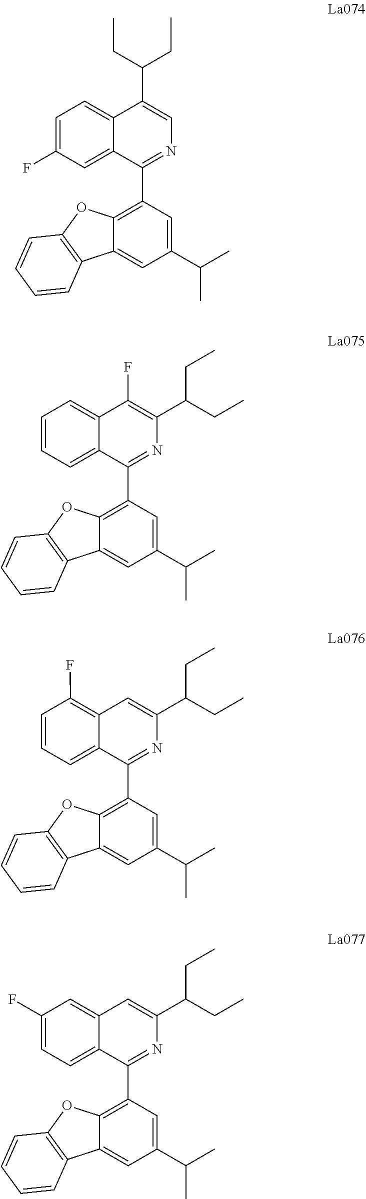 [SMILES: CCC(CC)c1cnc(-c2cc(C(C)C)cc3c2oc2ccccc23)c2cc(F)ccc12 ; CCC(CC)c1nc(-c2cc(C(C)C)cc3c2oc2ccccc23)c2ccccc2c1F ; CCC(CC)c1cc2c(F)cccc2c(-c2cc(C(C)C)cc3c2oc2ccccc23)n1 ; CCC(CC)c1cc2cc(F)ccc2c(-c2cc(C(C)C)cc3c2oc2ccccc23)n1]

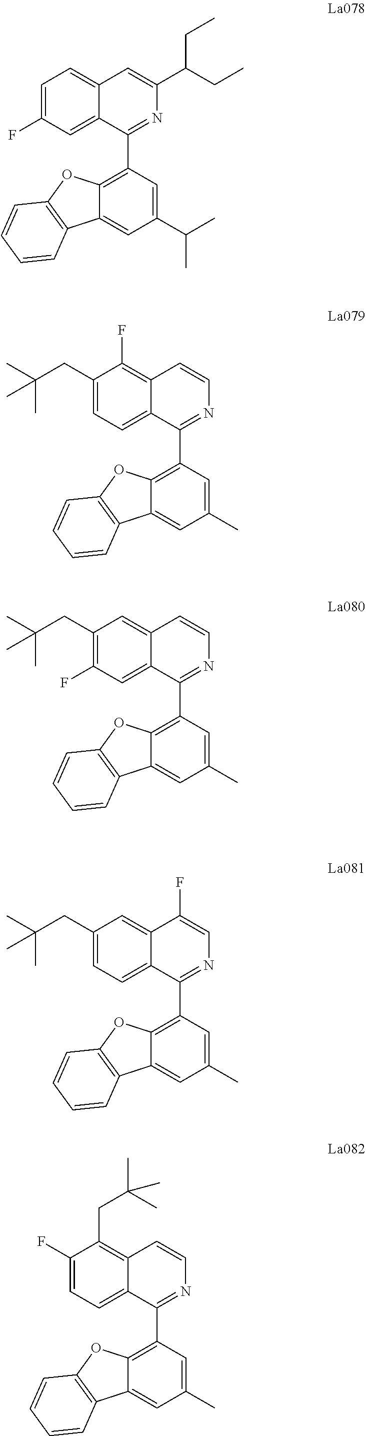

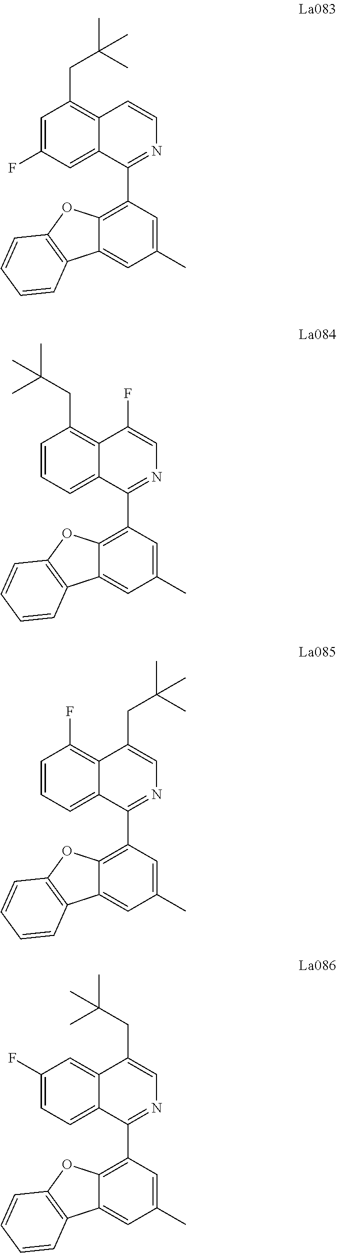 [SMILES: Cc1cc(-c2nccc3c(CC(C)(C)C)cc(F)cc23)c2oc3ccccc3c2c1 ; Cc1cc(-c2ncc(F)c3c(CC(C)(C)C)cccc23)c2oc3ccccc3c2c1 ; Cc1cc(-c2ncc(CC(C)(C)C)c3c(F)cccc23)c2oc3ccccc3c2c1 ; Cc1cc(-c2ncc(CC(C)(C)C)c3cc(F)ccc23)c2oc3ccccc3c2c1]

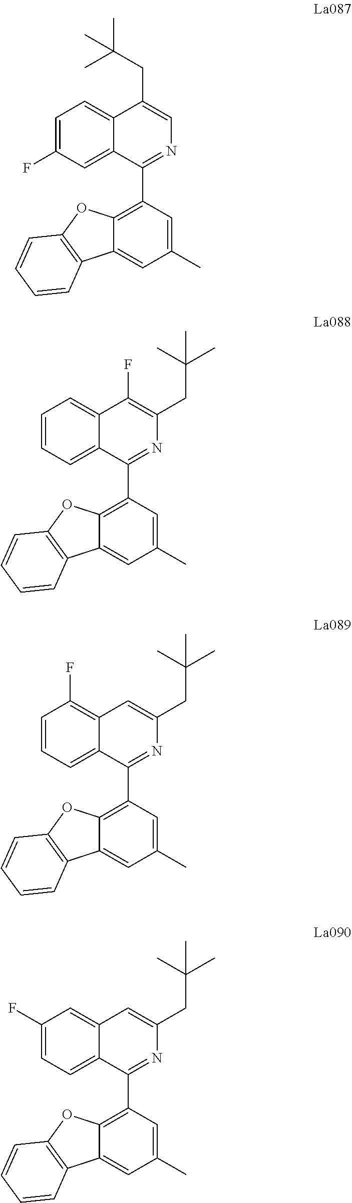 [SMILES: Cc1cc(-c2ncc(CC(C)(C)C)c3ccc(F)cc23)c2oc3ccccc3c2c1 ; Cc1cc(-c2nc(CC(C)(C)C)c(F)c3ccccc23)c2oc3ccccc3c2c1 ; Cc1cc(-c2nc(CC(C)(C)C)cc3c(F)cccc23)c2oc3ccccc3c2c1 ; Cc1cc(-c2nc(CC(C)(C)C)cc3cc(F)ccc23)c2oc3ccccc3c2c1]

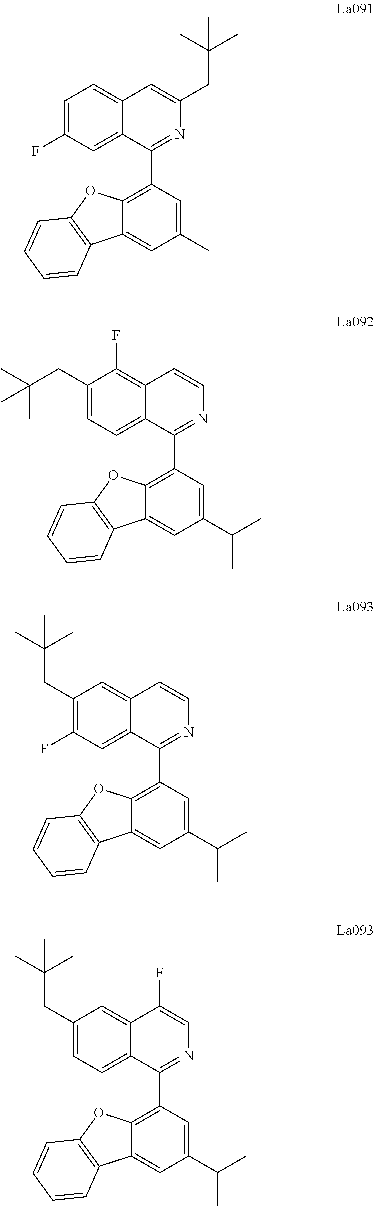

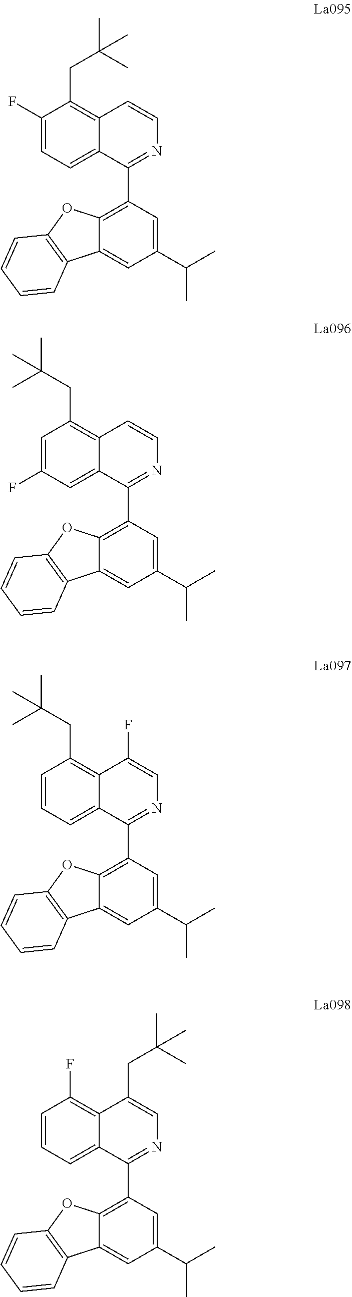

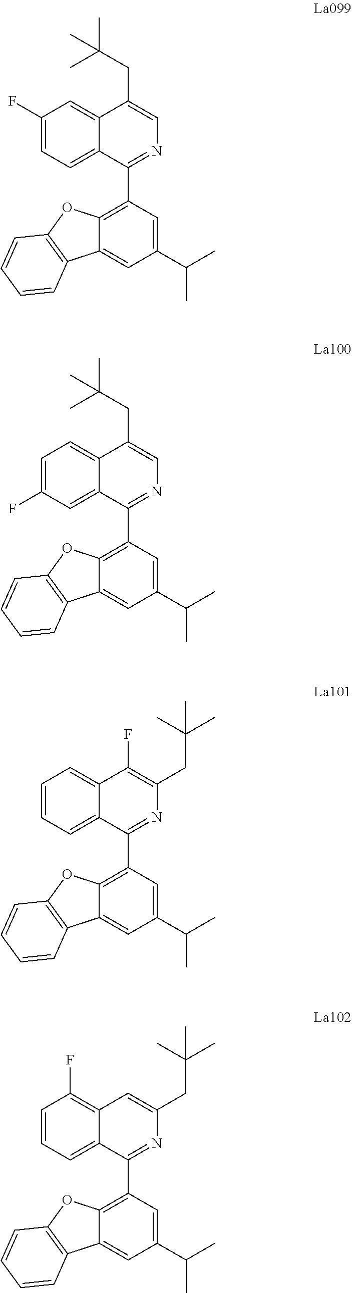 [SMILES: CC(C)c1cc(-c2ncc(CC(C)(C)C)c3cc(F)ccc23)c2oc3ccccc3c2c1 ; CC(C)c1cc(-c2ncc(CC(C)(C)C)c3ccc(F)cc23)c2oc3ccccc3c2c1 ; CC(C)c1cc(-c2nc(CC(C)(C)C)c(F)c3ccccc23)c2oc3ccccc3c2c1 ; CC(C)c1cc(-c2nc(CC(C)(C)C)cc3c(F)cccc23)c2oc3ccccc3c2c1]

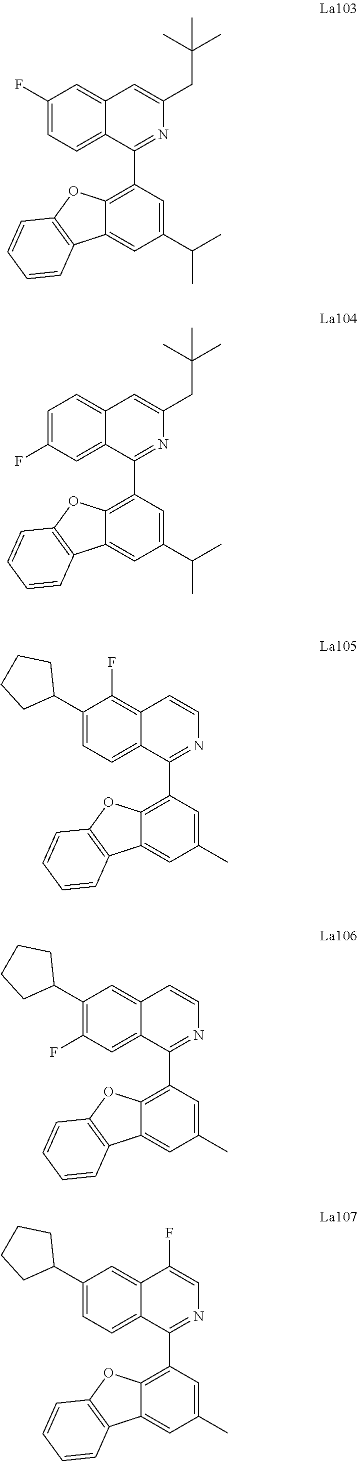

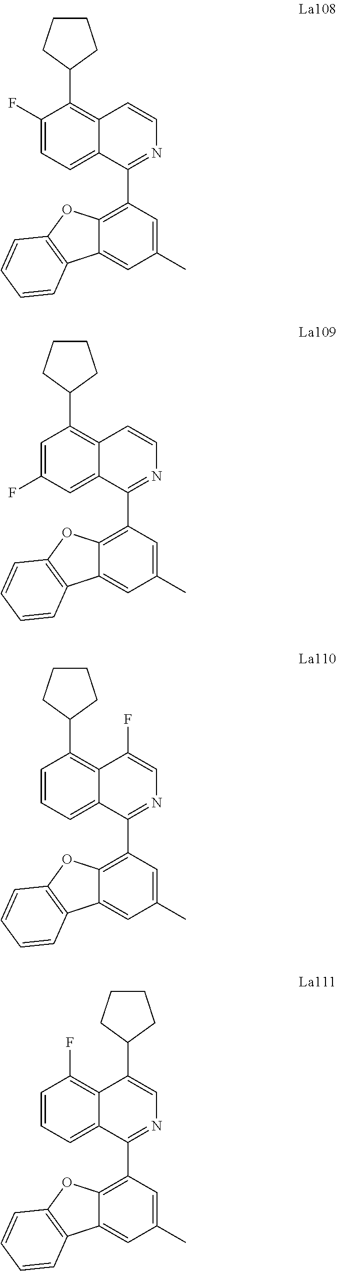 [SMILES: Cc1cc(-c2nccc3c(C4CCCC4)c(F)ccc23)c2oc3ccccc3c2c1 ; Cc1cc(-c2nccc3c(C4CCCC4)cc(F)cc23)c2oc3ccccc3c2c1 ; Cc1cc(-c2ncc(F)c3c(C4CCCC4)cccc23)c2oc3ccccc3c2c1 ; Cc1cc(-c2ncc(C3CCCC3)c3c(F)cccc23)c2oc3ccccc3c2c1]

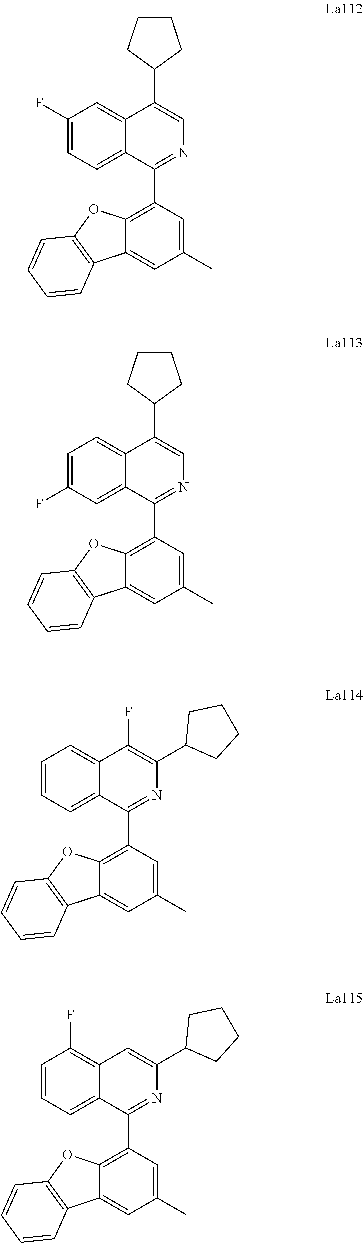 [SMILES: Cc1cc(-c2ncc(C3CCCC3)c3cc(F)ccc23)c2oc3ccccc3c2c1 ; Cc1cc(-c2ncc(C3CCCC3)c3ccc(F)cc23)c2oc3ccccc3c2c1 ; Cc1cc(-c2nc(C3CCCC3)c(F)c3ccccc23)c2oc3ccccc3c2c1 ; Cc1cc(-c2nc(C3CCCC3)cc3c(F)cccc23)c2oc3ccccc3c2c1]

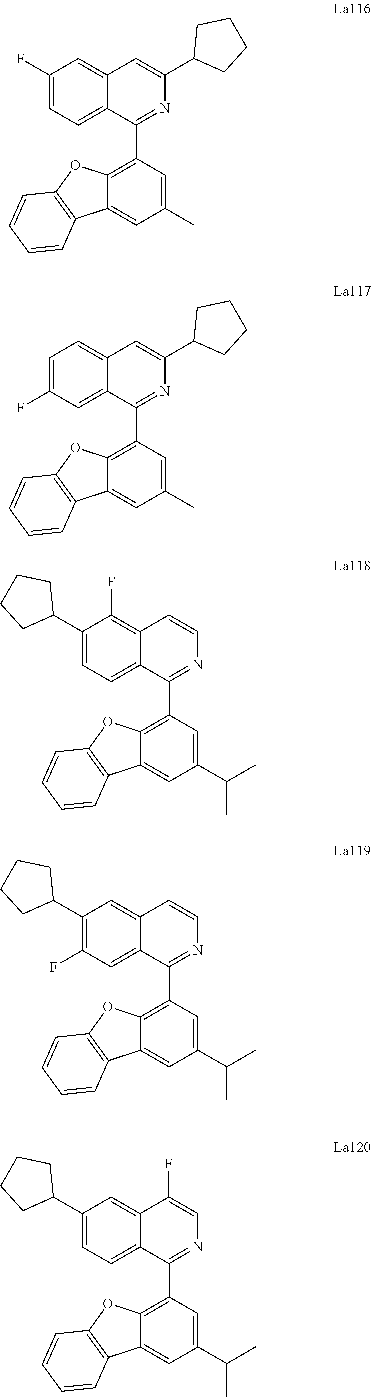

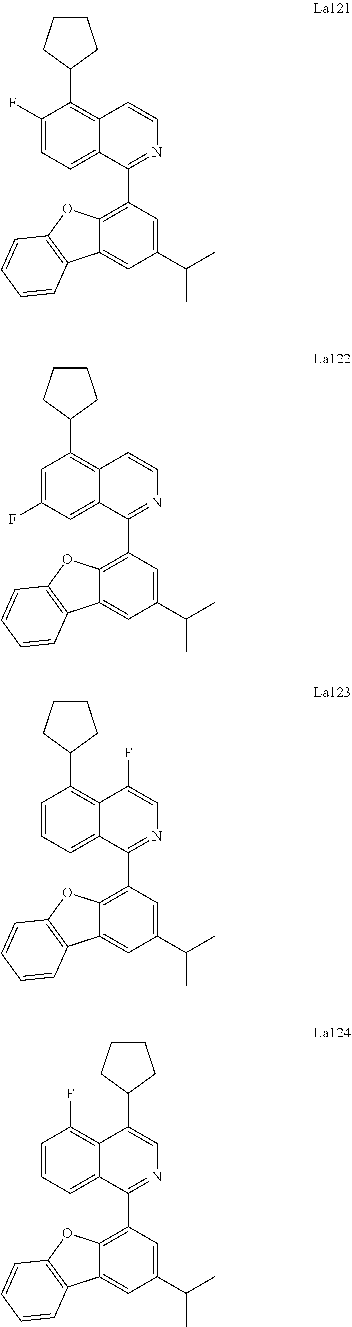 [SMILES: CC(C)c1cc(-c2nccc3c(C4CCCC4)c(F)ccc23)c2oc3ccccc3c2c1 ; CC(C)c1cc(-c2nccc3c(C4CCCC4)cc(F)cc23)c2oc3ccccc3c2c1 ; CC(C)c1cc(-c2ncc(F)c3c(C4CCCC4)cccc23)c2oc3ccccc3c2c1 ; CC(C)c1cc(-c2ncc(C3CCCC3)c3c(F)cccc23)c2oc3ccccc3c2c1]

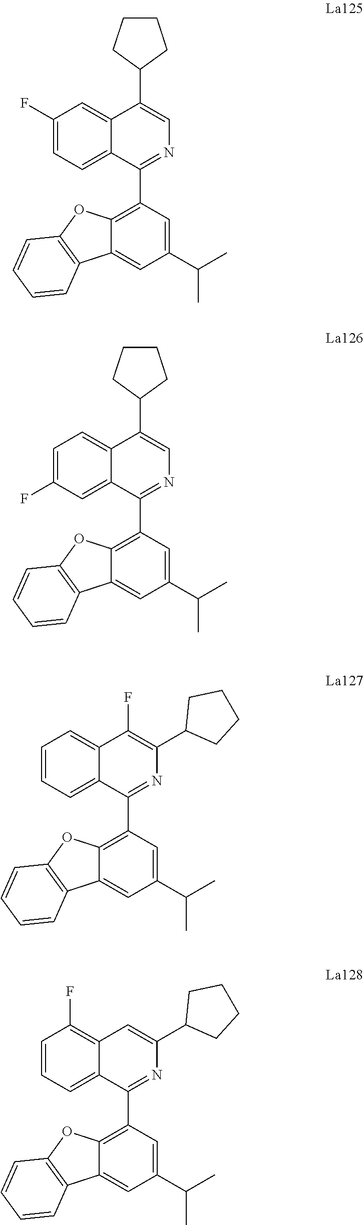 [SMILES: CC(C)c1cc(-c2ncc(C3CCCC3)c3cc(F)ccc23)c2oc3ccccc3c2c1 ; CC(C)c1cc(-c2ncc(C3CCCC3)c3ccc(F)cc23)c2oc3ccccc3c2c1 ; CC(C)c1cc(-c2nc(C3CCCC3)c(F)c3ccccc23)c2oc3ccccc3c2c1 ; CC(C)c1cc(-c2nc(C3CCCC3)cc3c(F)cccc23)c2oc3ccccc3c2c1]

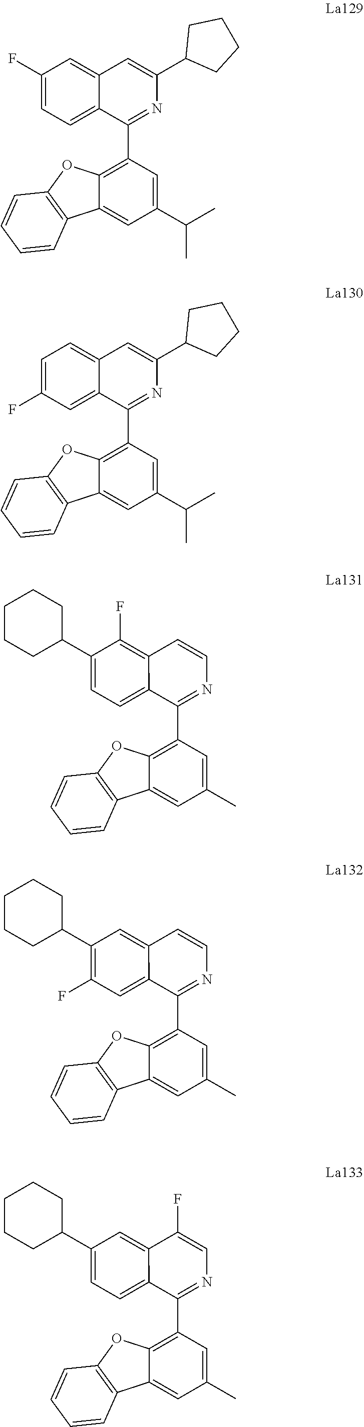 [SMILES: CC(C)c1cc(-c2nc(C3CCCC3)cc3cc(F)ccc23)c2oc3ccccc3c2c1 ; CC(C)c1cc(-c2nc(C3CCCC3)cc3ccc(F)cc23)c2oc3ccccc3c2c1 ; Cc1cc(-c2nccc3c(F)c(C4CCCCC4)ccc23)c2oc3ccccc3c2c1 ; Cc1cc(-c2nccc3cc(C4CCCCC4)c(F)cc23)c2oc3ccccc3c2c1 ; Cc1cc(-c2ncc(F)c3cc(C4CCCCC4)ccc23)c2oc3ccccc3c2c1]

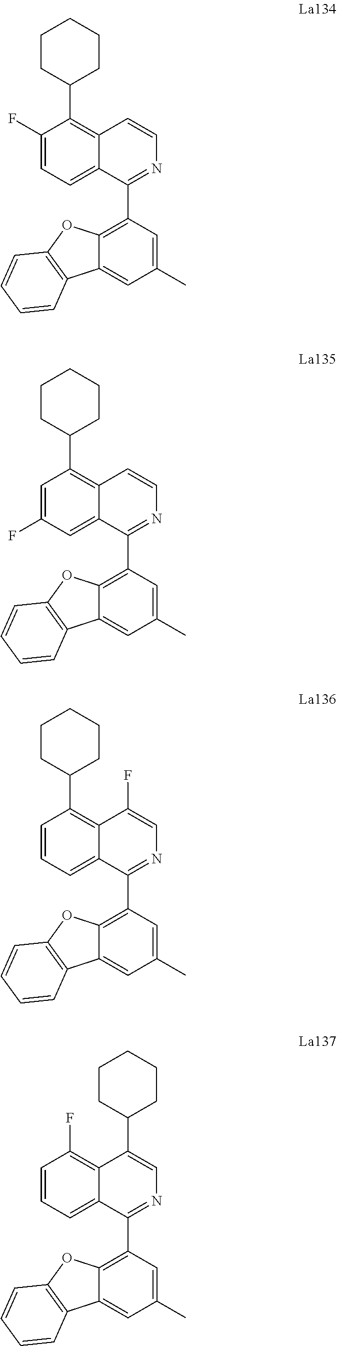 [SMILES: Cc1cc(-c2nccc3c(C4CCCCC4)c(F)ccc23)c2oc3ccccc3c2c1 ; Cc1cc(-c2nccc3c(C4CCCCC4)cc(F)cc23)c2oc3ccccc3c2c1 ; Cc1cc(-c2ncc(F)c3c(C4CCCCC4)cccc23)c2oc3ccccc3c2c1 ; Cc1cc(-c2ncc(C3CCCCC3)c3c(F)cccc23)c2oc3ccccc3c2c1]

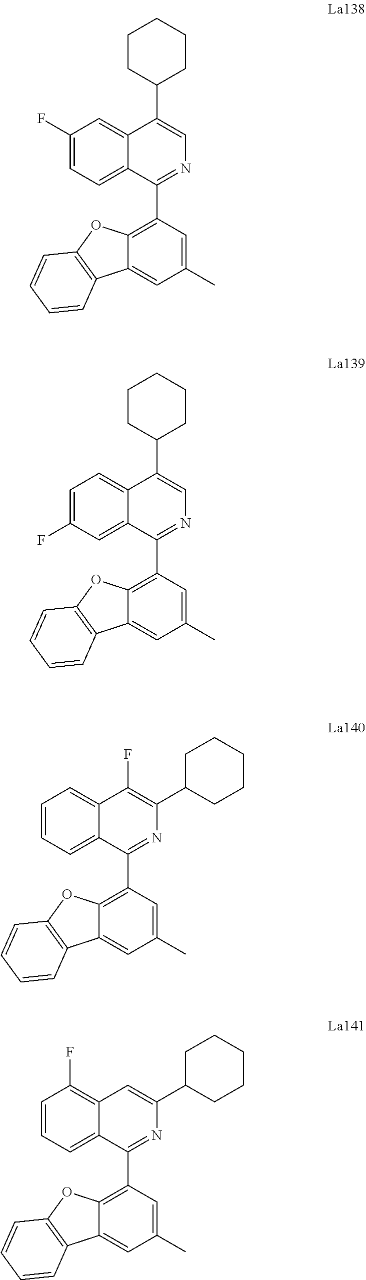 [SMILES: Cc1cc(-c2ncc(C3CCCCC3)c3cc(F)ccc23)c2oc3ccccc3c2c1 ; Cc1cc(-c2ncc(C3CCCCC3)c3ccc(F)cc23)c2oc3ccccc3c2c1 ; Cc1cc(-c2nc(C3CCCCC3)c(F)c3ccccc23)c2oc3ccccc3c2c1 ; Cc1cc(-c2nc(C3CCCCC3)cc3c(F)cccc23)c2oc3ccccc3c2c1]

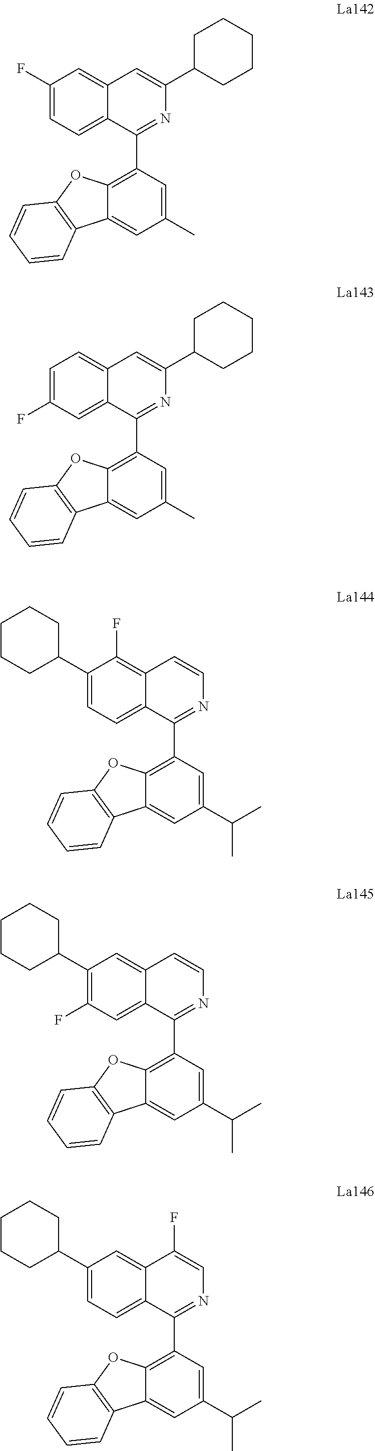 [SMILES: Cc1cc(-c2nc(C3CCCCC3)cc3cc(F)ccc23)c2oc3ccccc3c2c1 ; Cc1cc(-c2nc(C3CCCCC3)cc3ccc(F)cc23)c2oc3ccccc3c2c1 ; CC(C)c1cc(-c2nccc3c(F)c(C4CCCCC4)ccc23)c2oc3ccccc3c2c1 ; CC(C)c1cc(-c2nccc3cc(C4CCCCC4)c(F)cc23)c2oc3ccccc3c2c1 ; CC(C)c1cc(-c2ncc(F)c3cc(C4CCCCC4)ccc23)c2oc3ccccc3c2c1]

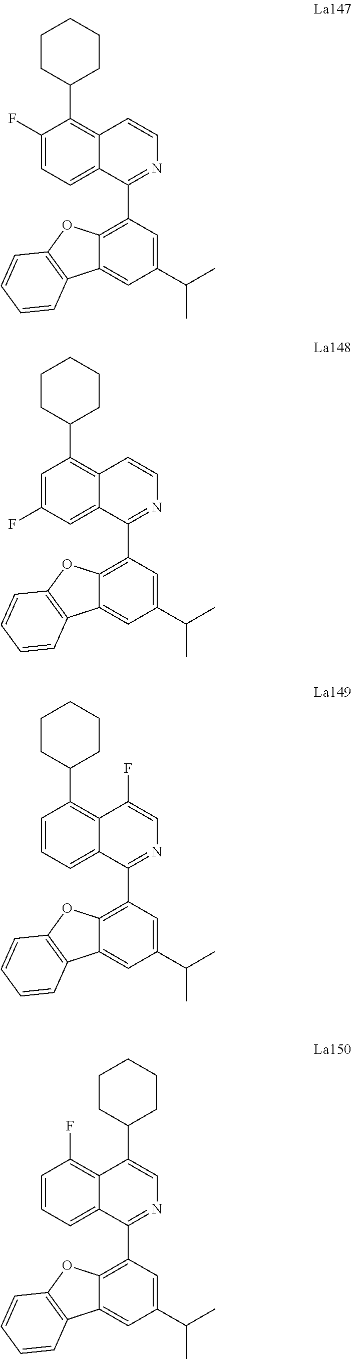 [SMILES: CC(C)c1cc(-c2nccc3c(C4CCCCC4)c(F)ccc23)c2oc3ccccc3c2c1 ; CC(C)c1cc(-c2nccc3c(C4CCCCC4)cc(F)cc23)c2oc3ccccc3c2c1 ; CC(C)c1cc(-c2ncc(F)c3c(C4CCCCC4)cccc23)c2oc3ccccc3c2c1 ; CC(C)c1cc(-c2ncc(C3CCCCC3)c3c(F)cccc23)c2oc3ccccc3c2c1]

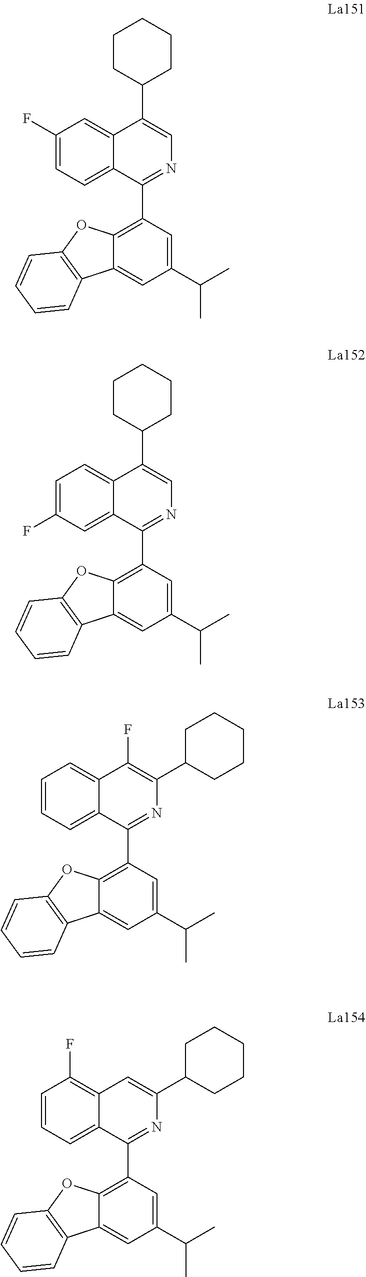 [SMILES: CC(C)c1cc(-c2ncc(C3CCCCC3)c3cc(F)ccc23)c2oc3ccccc3c2c1 ; CC(C)c1cc(-c2ncc(C3CCCCC3)c3ccc(F)cc23)c2oc3ccccc3c2c1 ; CC(C)c1cc(-c2nc(C3CCCCC3)c(F)c3ccccc23)c2oc3ccccc3c2c1 ; CC(C)c1cc(-c2nc(C3CCCCC3)cc3c(F)cccc23)c2oc3ccccc3c2c1]

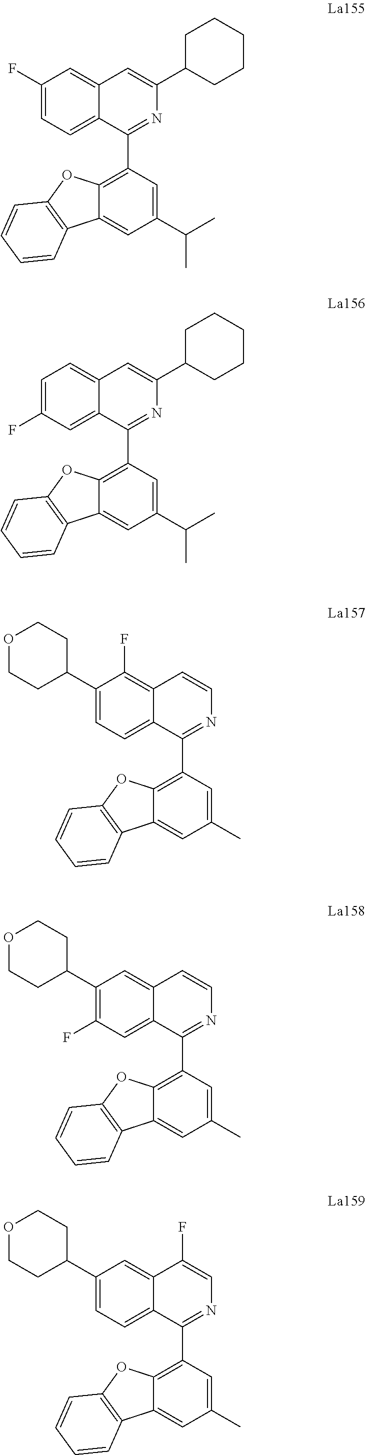 [SMILES: CC(C)c1cc(-c2nc(C3CCCCC3)cc3cc(F)ccc23)c2oc3ccccc3c2c1 ; CC(C)c1cc(-c2nc(C3CCCCC3)cc3ccc(F)cc23)c2oc3ccccc3c2c1 ; Cc1cc(-c2nccc3c(F)c(C4CCOCC4)ccc23)c2oc3ccccc3c2c1 ; Cc1cc(-c2nccc3cc(C4CCOCC4)c(F)cc23)c2oc3ccccc3c2c1 ; Cc1cc(-c2ncc(F)c3cc(C4CCOCC4)ccc23)c2oc3ccccc3c2c1]

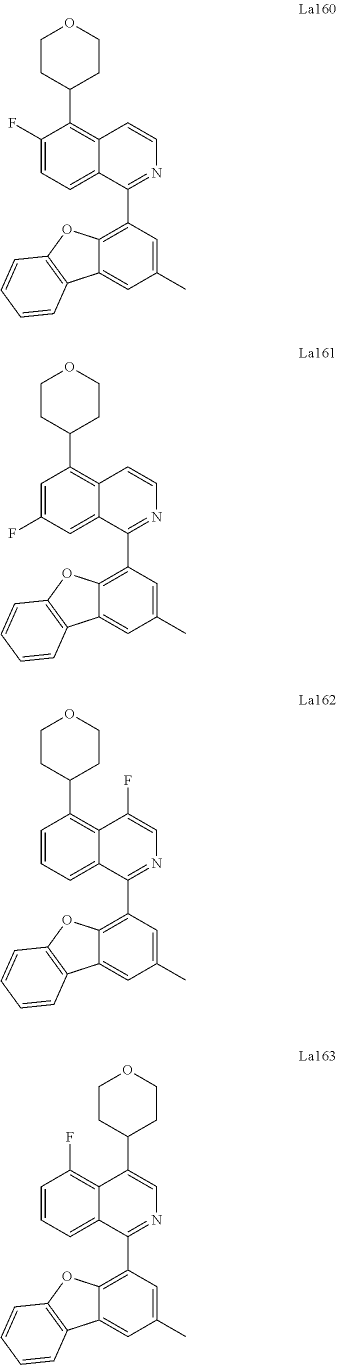 [SMILES: Cc1cc(-c2nccc3c(C4CCOCC4)c(F)ccc23)c2oc3ccccc3c2c1 ; Cc1cc(-c2nccc3c(C4CCOCC4)cc(F)cc23)c2oc3ccccc3c2c1 ; Cc1cc(-c2ncc(F)c3c(C4CCOCC4)cccc23)c2oc3ccccc3c2c1 ; Cc1cc(-c2ncc(C3CCOCC3)c3c(F)cccc23)c2oc3ccccc3c2c1]

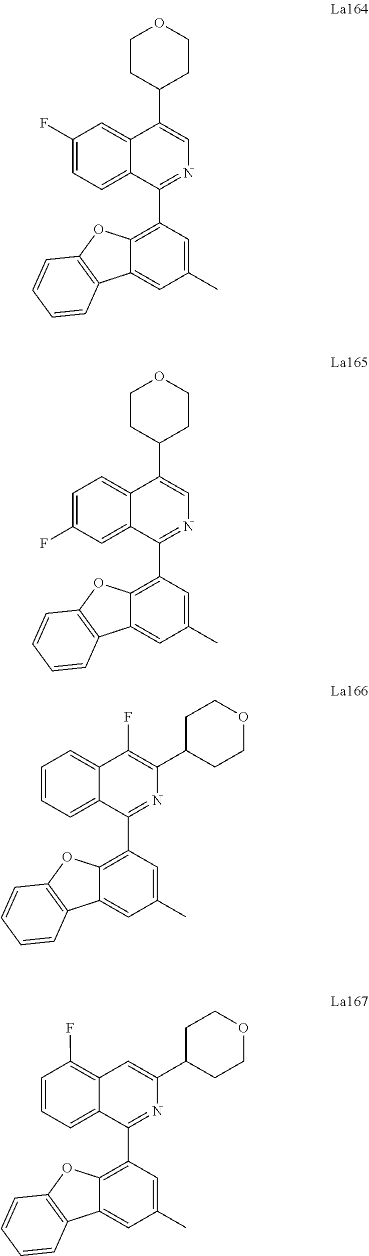 [SMILES: Cc1cc(-c2ncc(C3CCOCC3)c3cc(F)ccc23)c2oc3ccccc3c2c1 ; Cc1cc(-c2ncc(C3CCOCC3)c3ccc(F)cc23)c2oc3ccccc3c2c1 ; Cc1cc(-c2nc(C3CCOCC3)c(F)c3ccccc23)c2oc3ccccc3c2c1 ; Cc1cc(-c2nc(C3CCOCC3)cc3c(F)cccc23)c2oc3ccccc3c2c1]

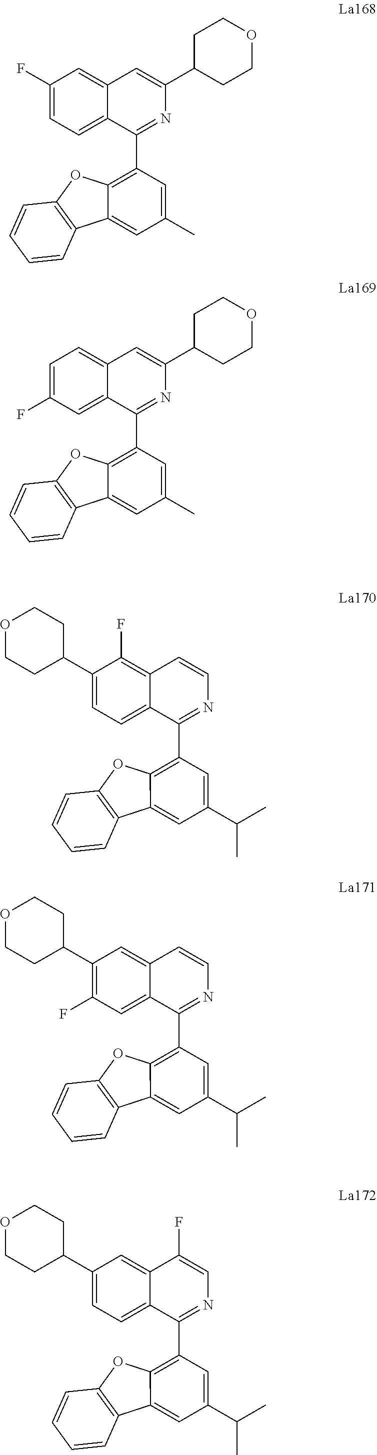 [SMILES: Cc1cc(-c2nc(C3CCOCC3)cc3cc(F)ccc23)c2oc3ccccc3c2c1 ; Cc1cc(-c2nc(C3CCOCC3)cc3ccc(F)cc23)c2oc3ccccc3c2c1 ; CC(C)c1cc(-c2nccc3c(F)c(C4CCOCC4)ccc23)c2oc3ccccc3c2c1 ; CC(C)c1cc(-c2nccc3cc(C4CCOCC4)c(F)cc23)c2oc3ccccc3c2c1 ; CC(C)c1cc(-c2ncc(F)c3cc(C4CCOCC4)ccc23)c2oc3ccccc3c2c1]

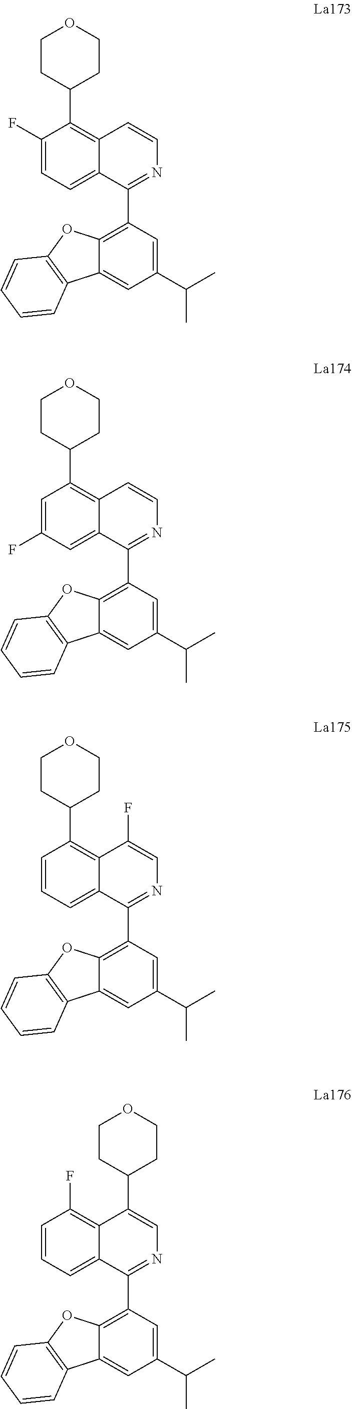 [SMILES: CC(C)c1cc(-c2nccc3c(C4CCOCC4)c(F)ccc23)c2oc3ccccc3c2c1 ; CC(C)c1cc(-c2nccc3c(C4CCOCC4)cc(F)cc23)c2oc3ccccc3c2c1 ; CC(C)c1cc(-c2ncc(F)c3c(C4CCOCC4)cccc23)c2oc3ccccc3c2c1 ; CC(C)c1cc(-c2ncc(C3CCOCC3)c3c(F)cccc23)c2oc3ccccc3c2c1]

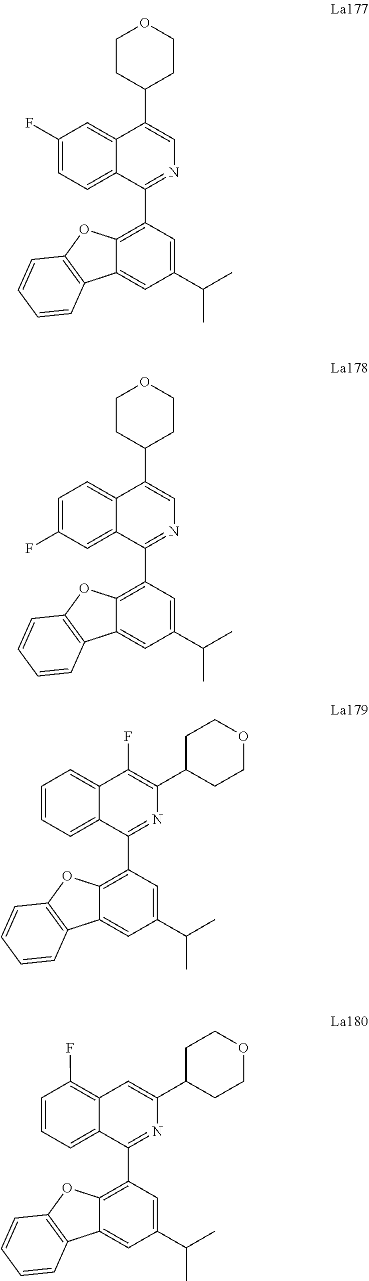

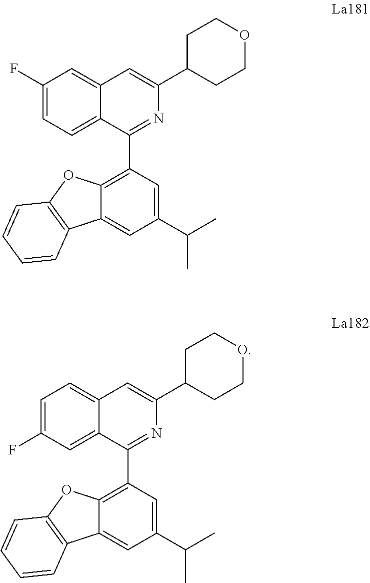 [SMILES: CC(C)c1cc(-c2nc(C3CCOCC3)cc3cc(F)ccc23)c2oc3ccccc3c2c1 ; CC(C)c1cc(-c2nc(C3CCOCC3)cc3ccc(F)cc23)c2oc3ccccc3c2c1]

13. The iridium complex according to claim 2, wherein the Lb is independently selected from one of the following structural formulas, or corresponding parts or complete deuterides or fluorides thereof:

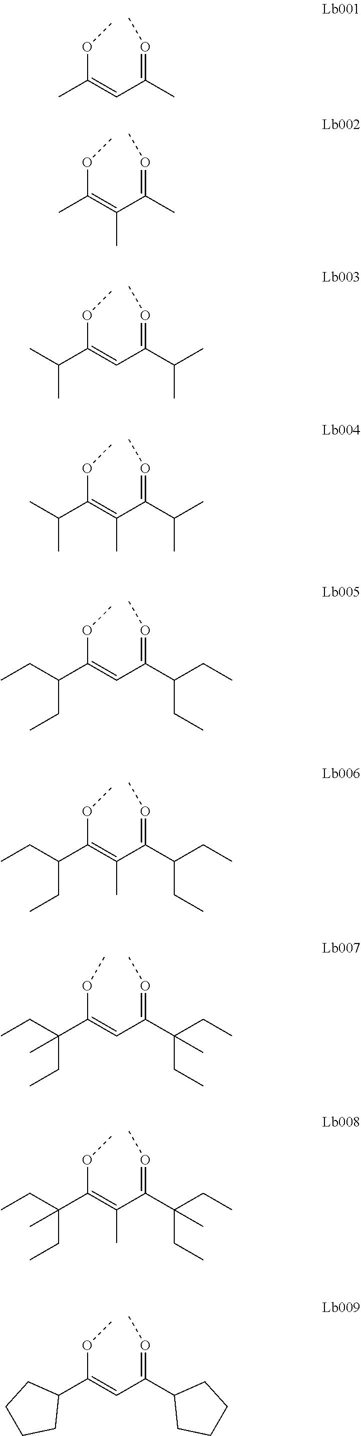

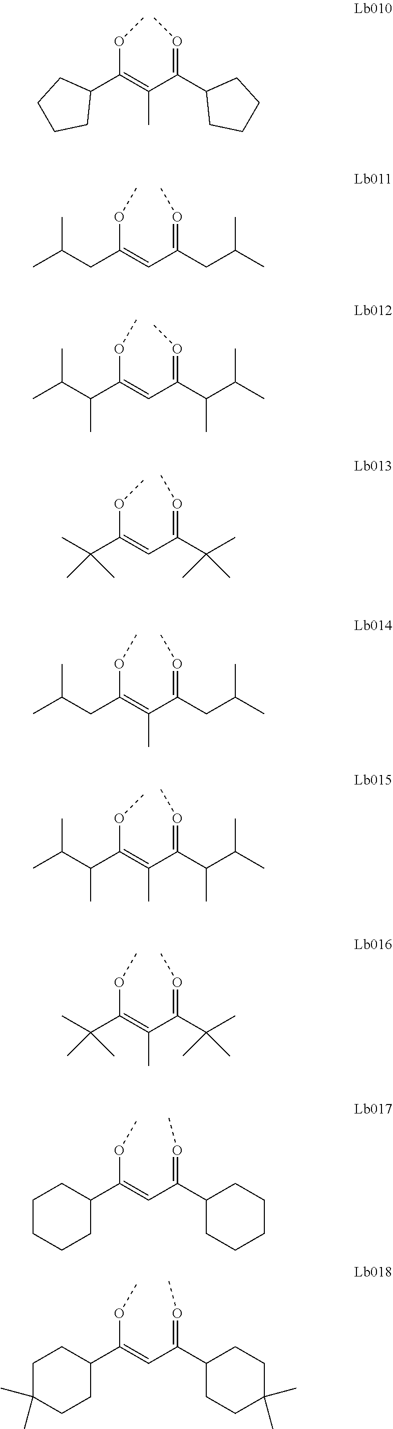

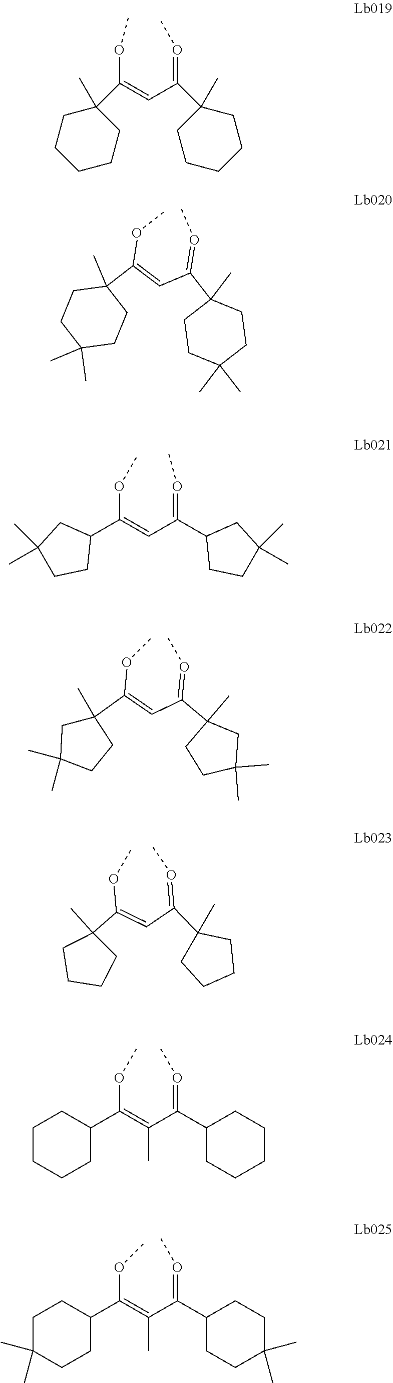

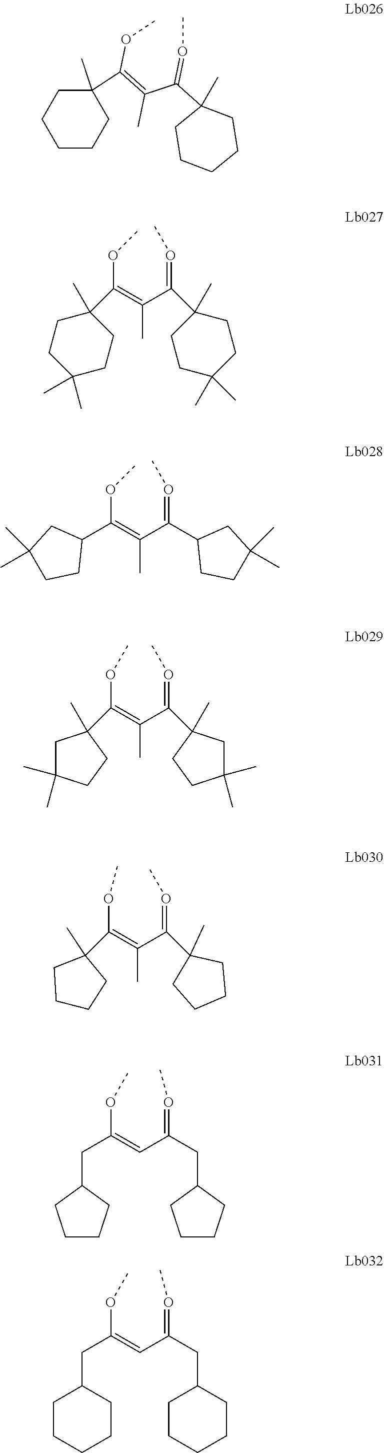

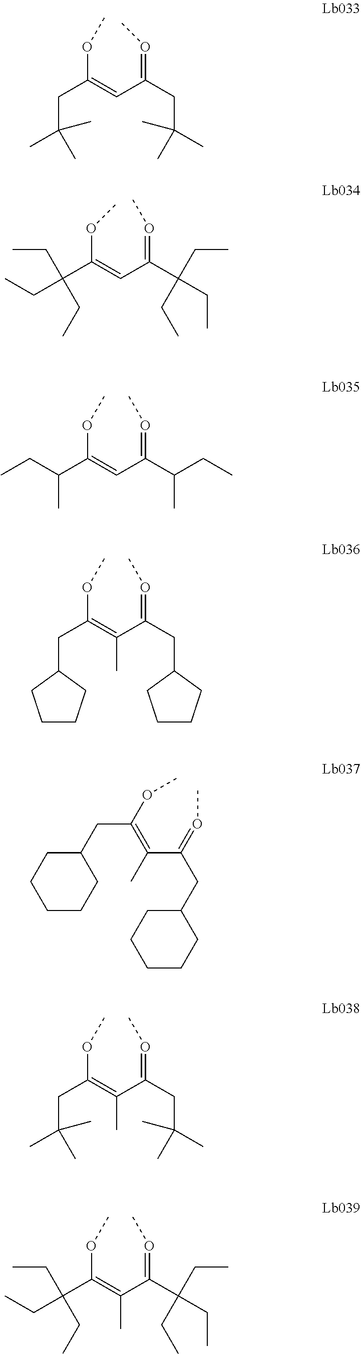

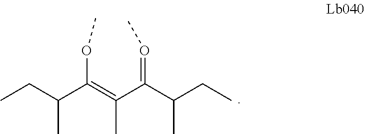

14. The iridium complex according to claim 5, wherein as a preferred iridium complex, the Lc is independently selected from the following structural formulas, or corresponding parts or complete deuterides or fluorides thereof:

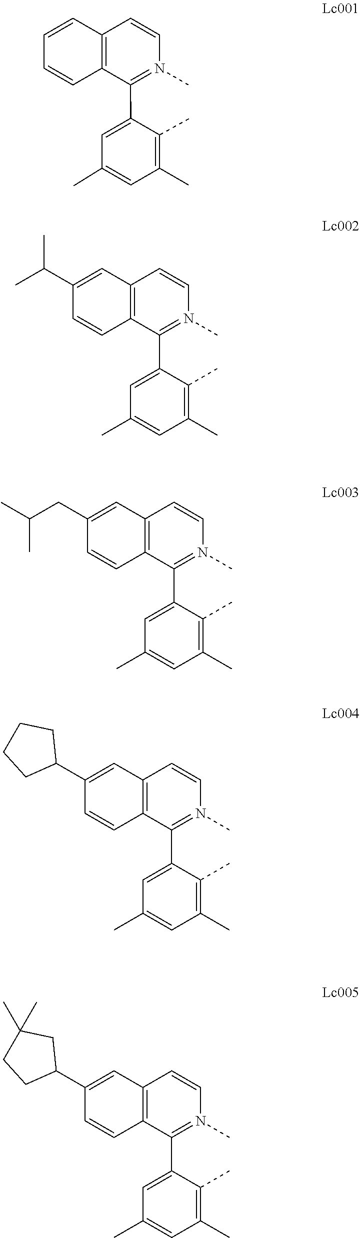

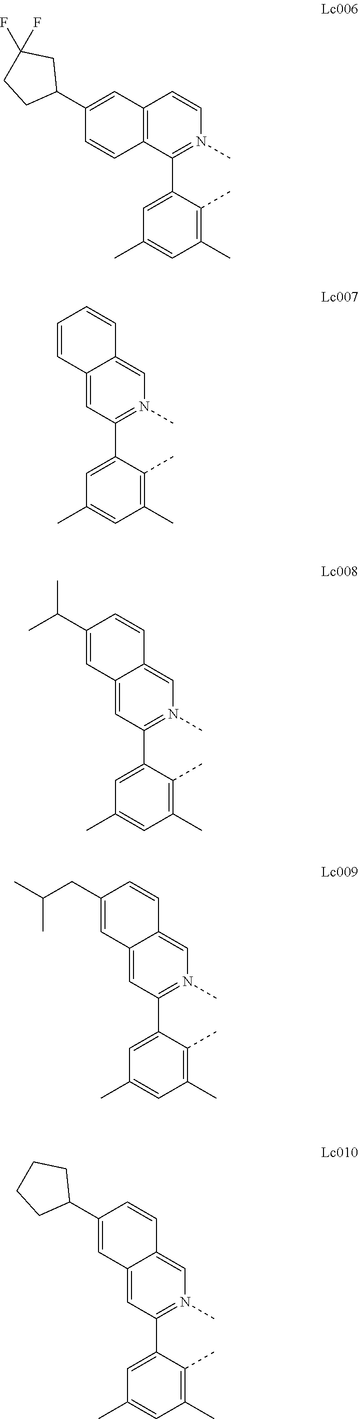

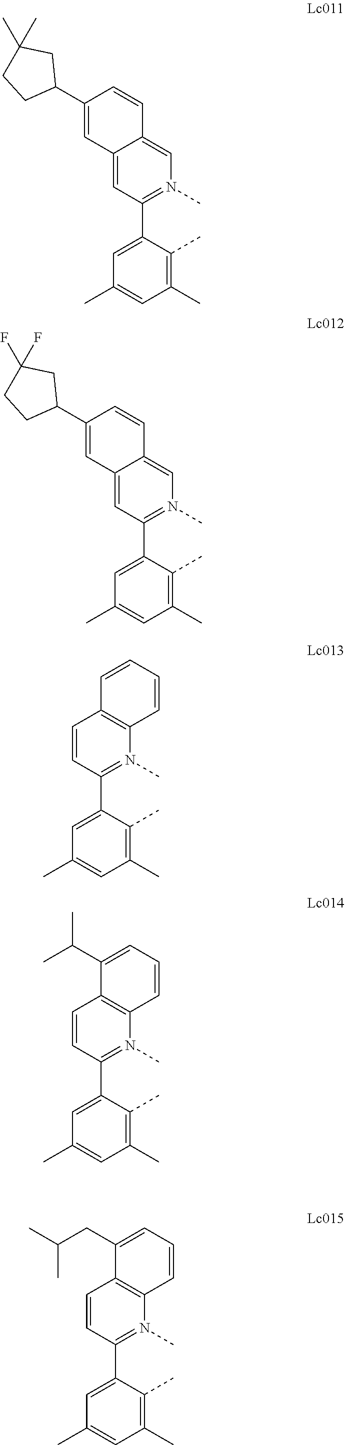

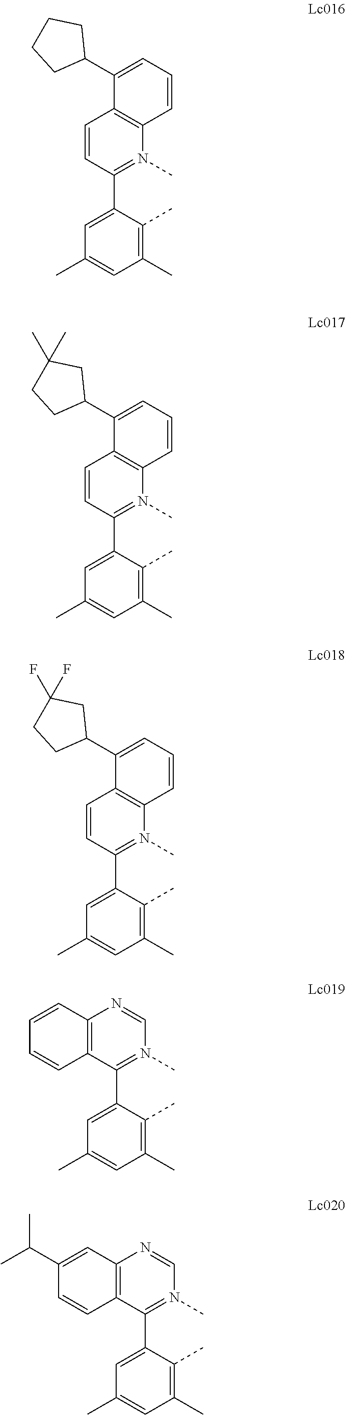

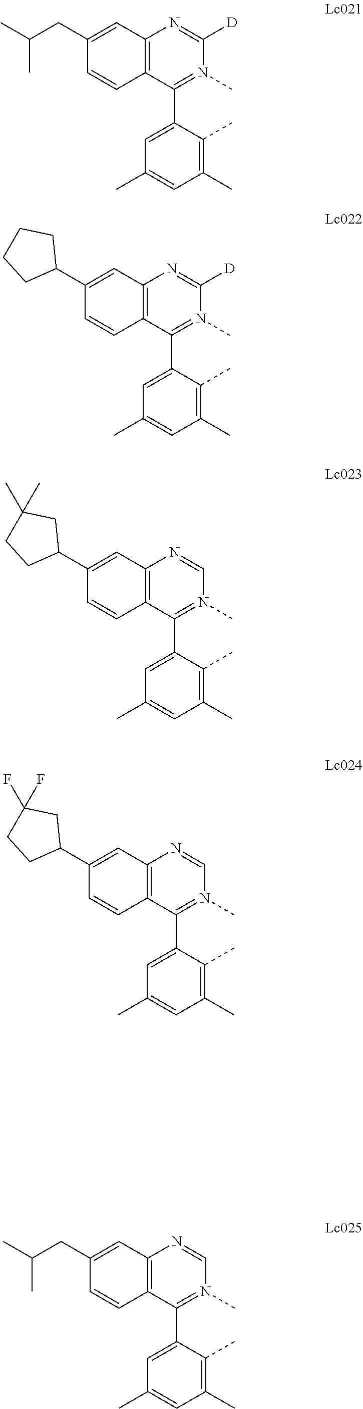

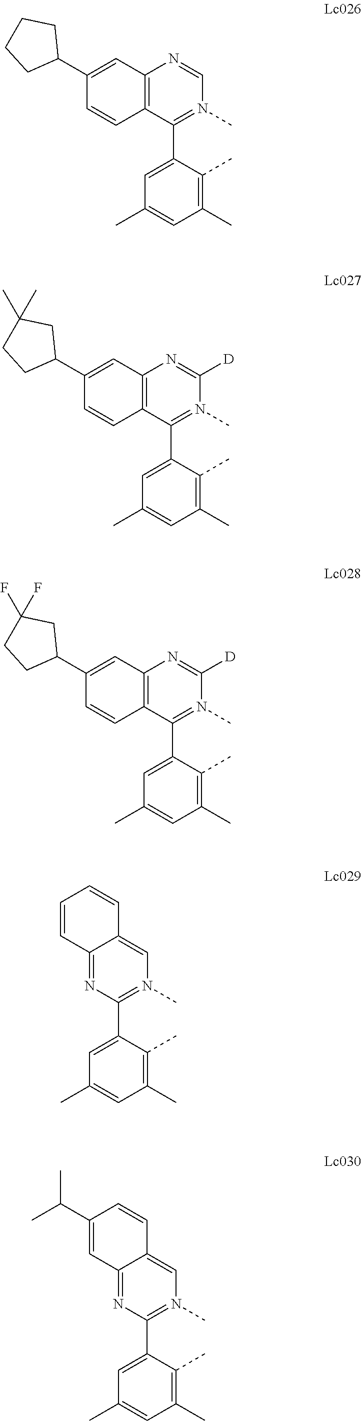

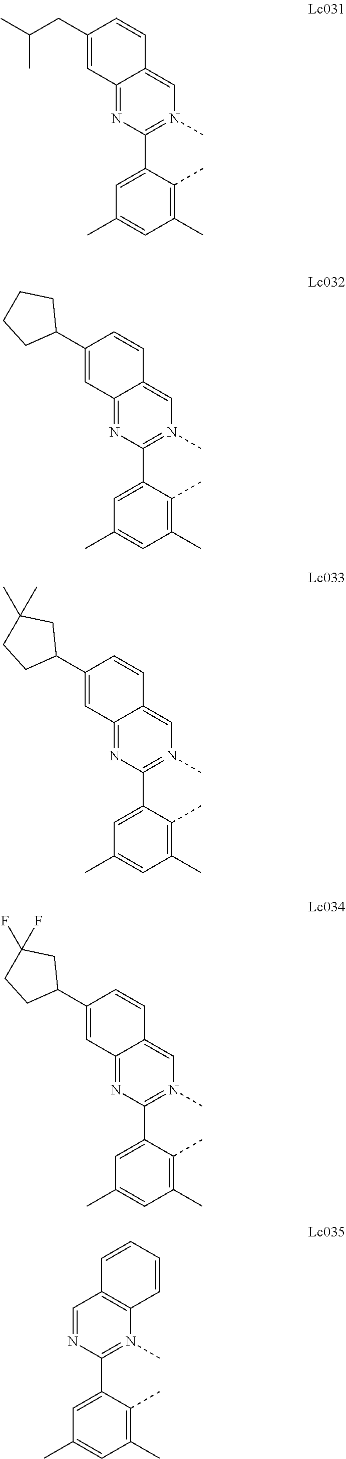

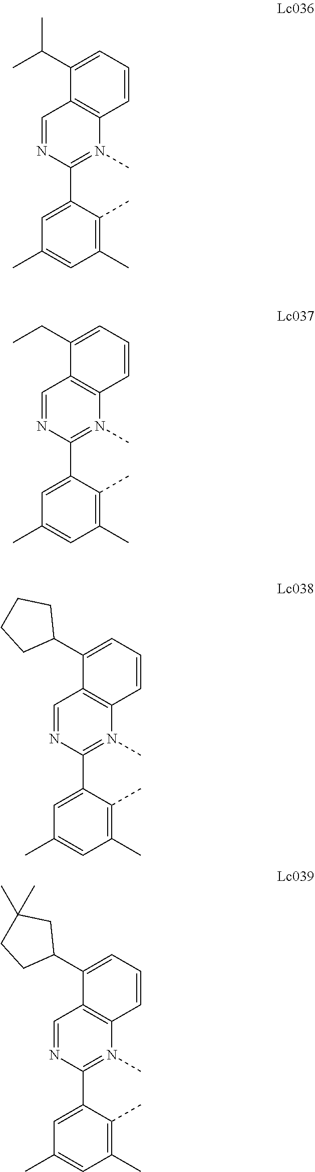

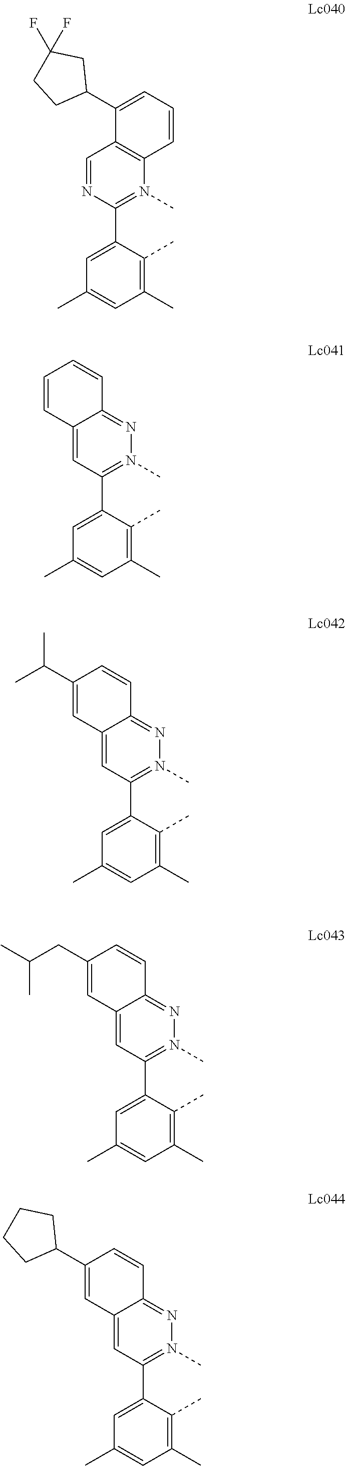

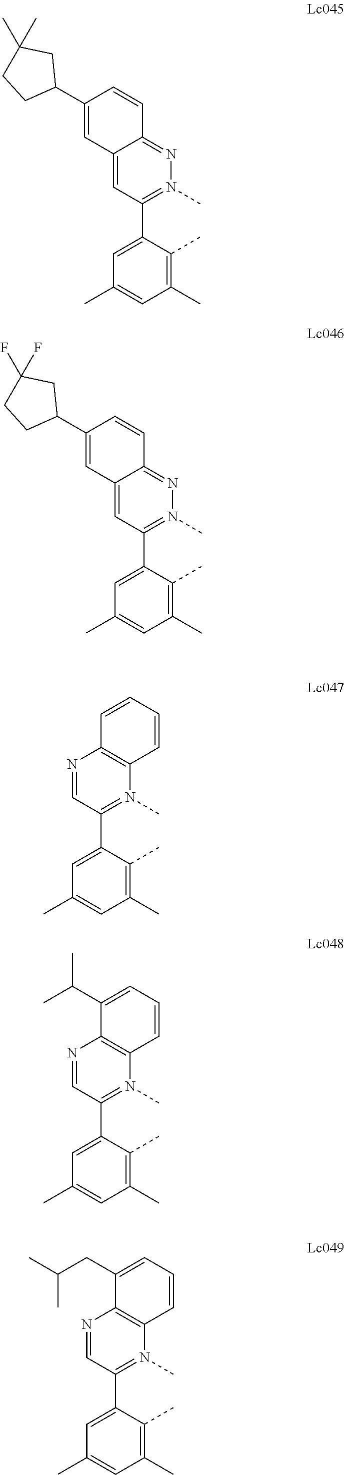

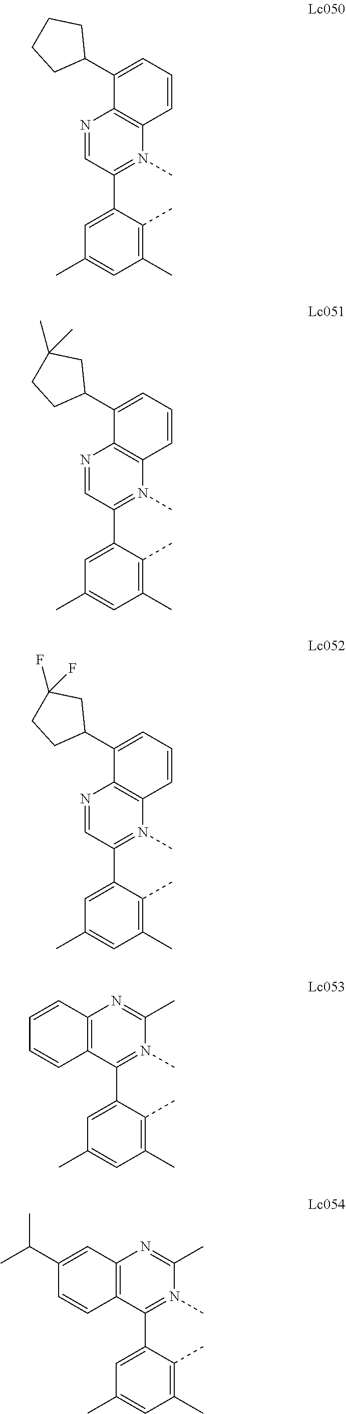

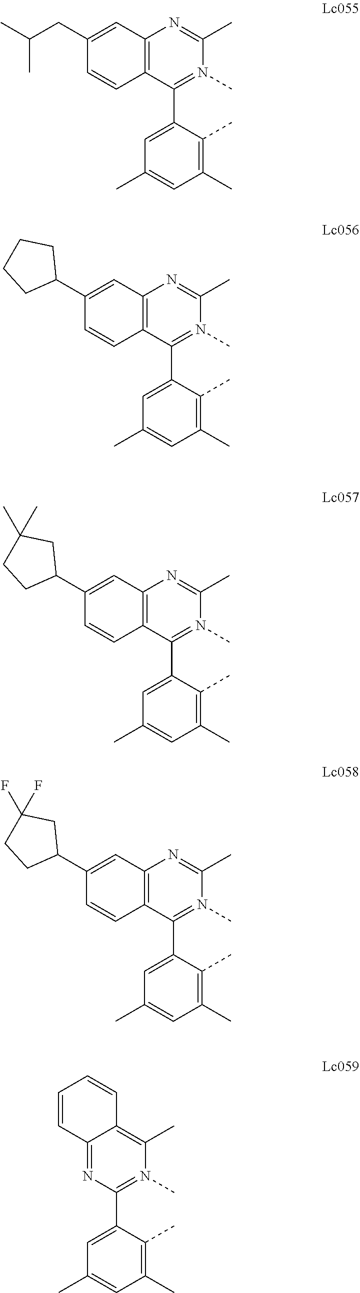

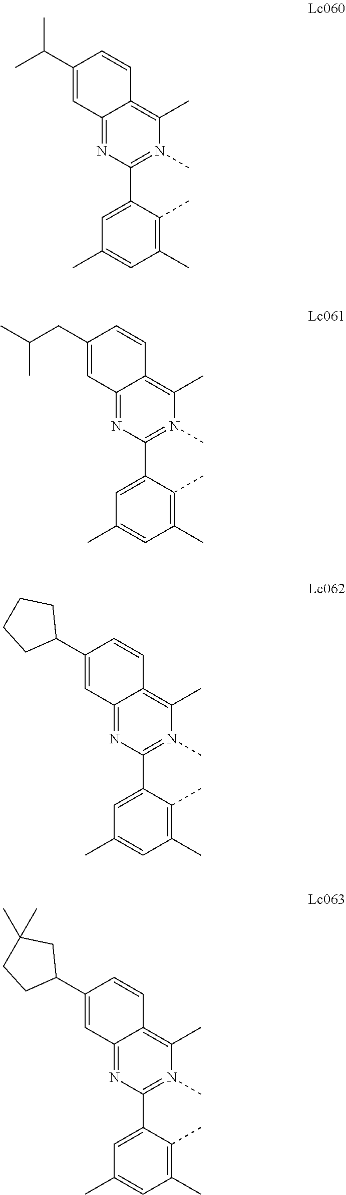

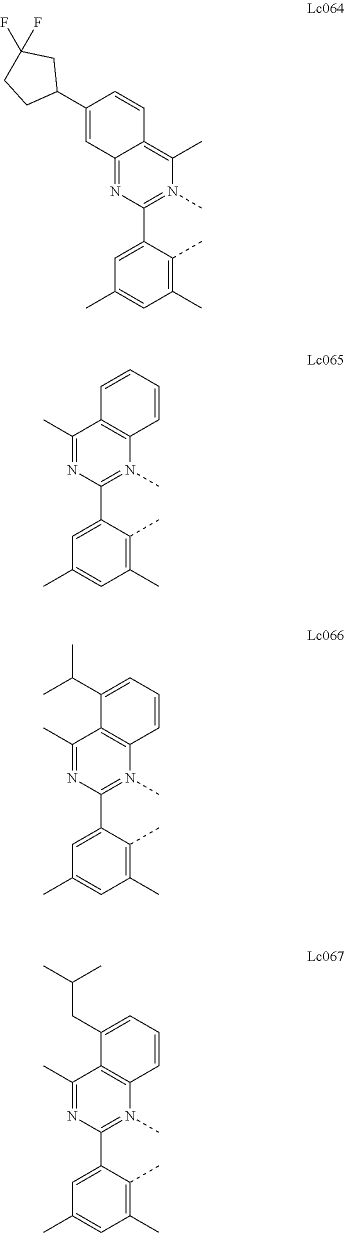

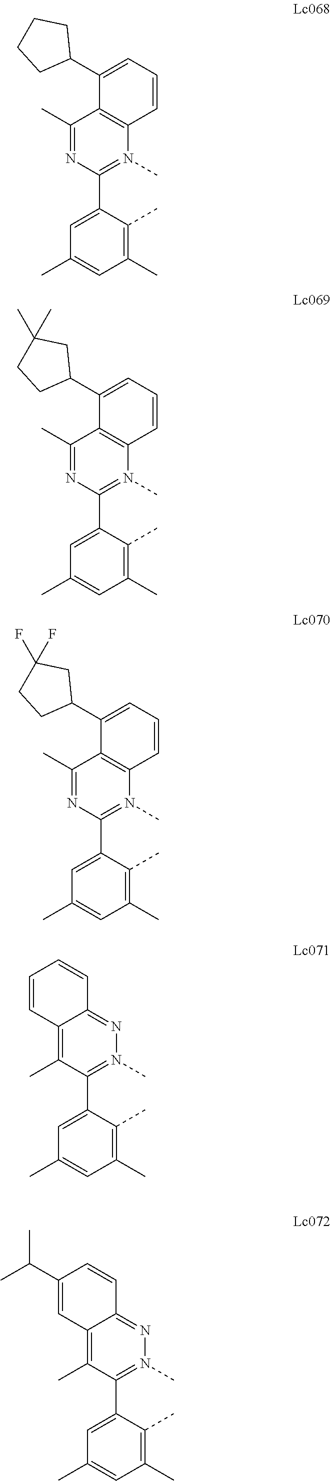

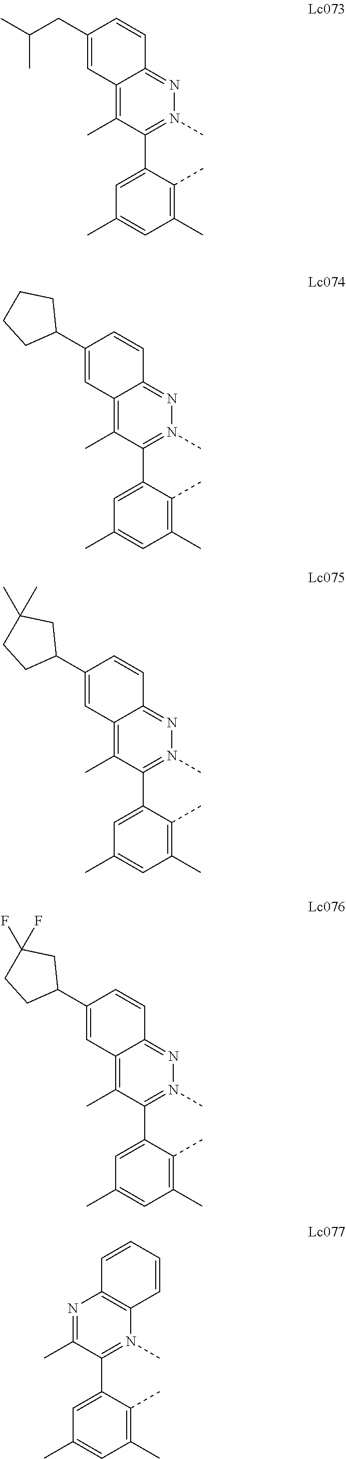

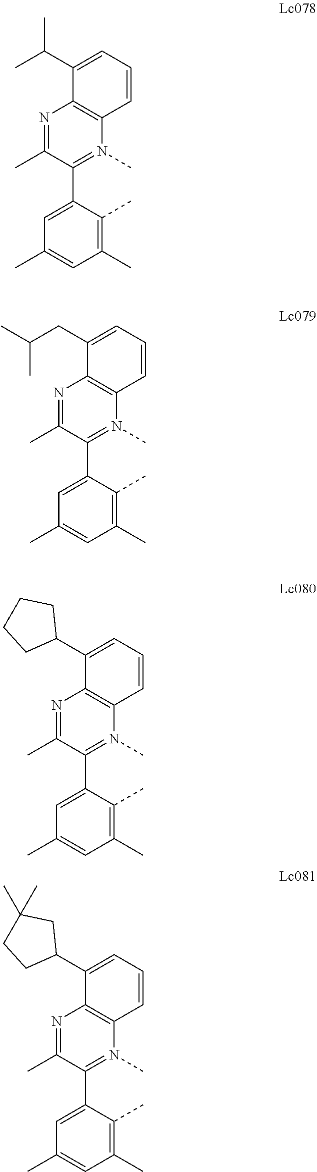

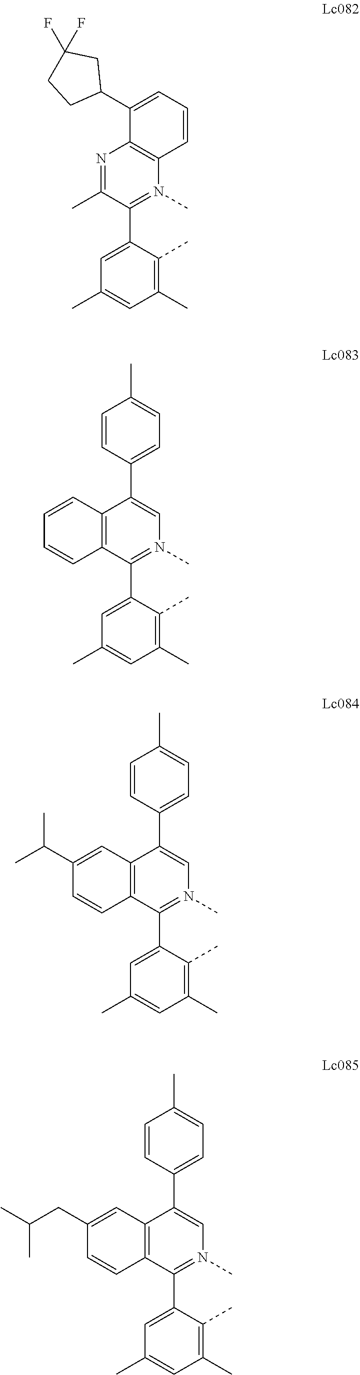

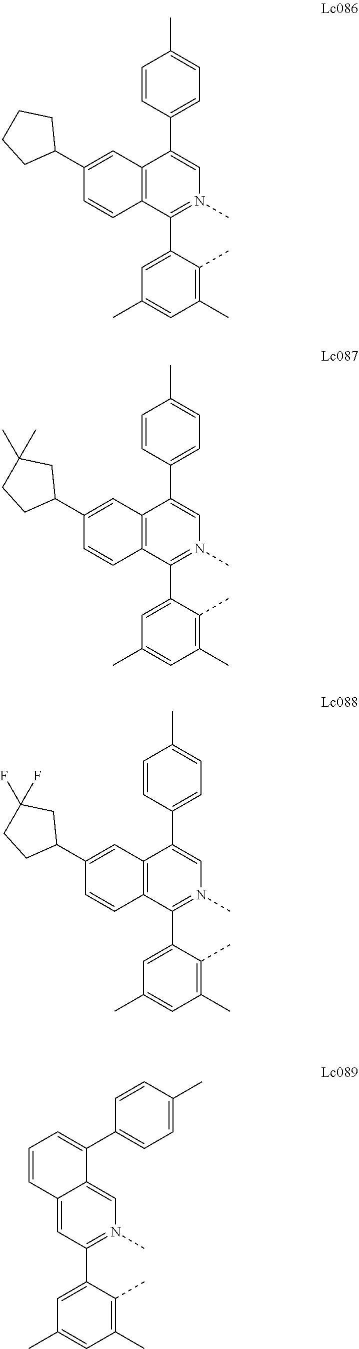

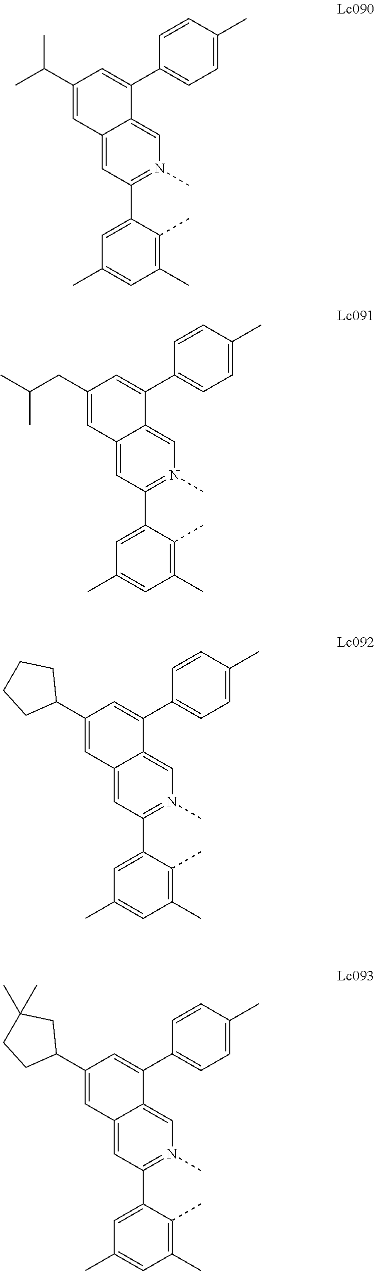

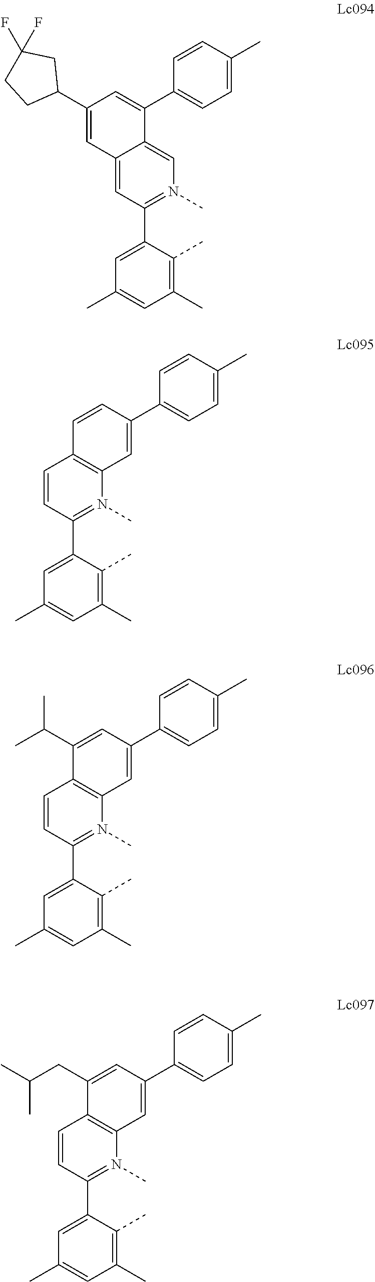

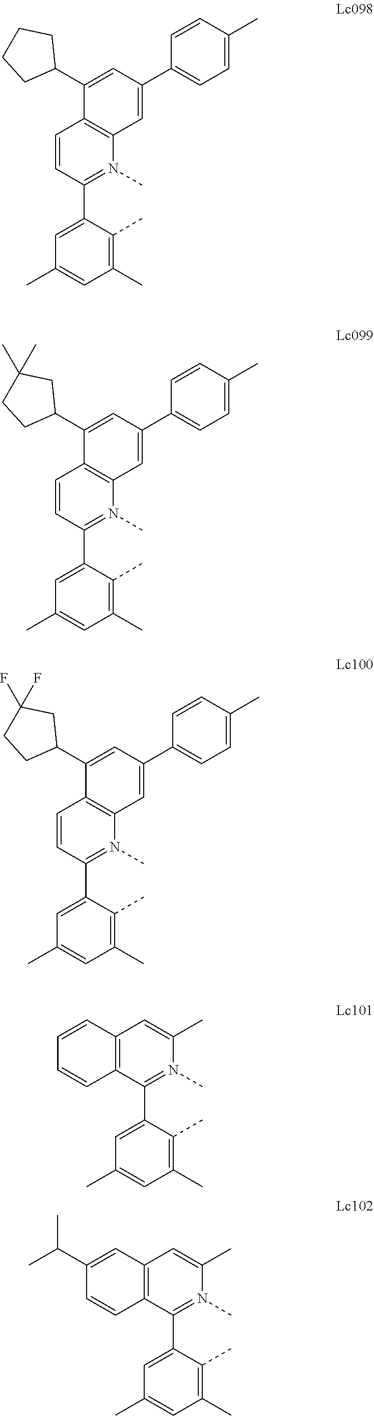

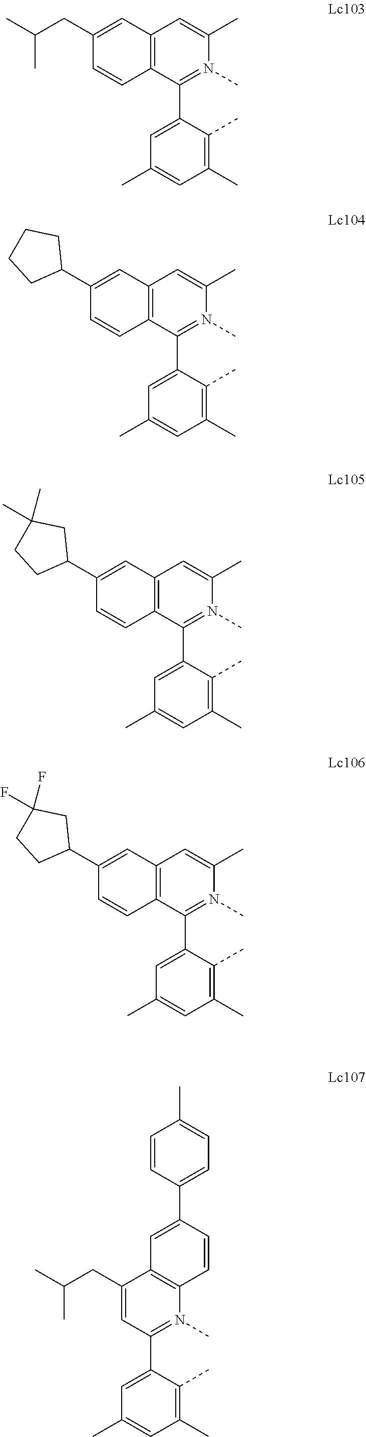

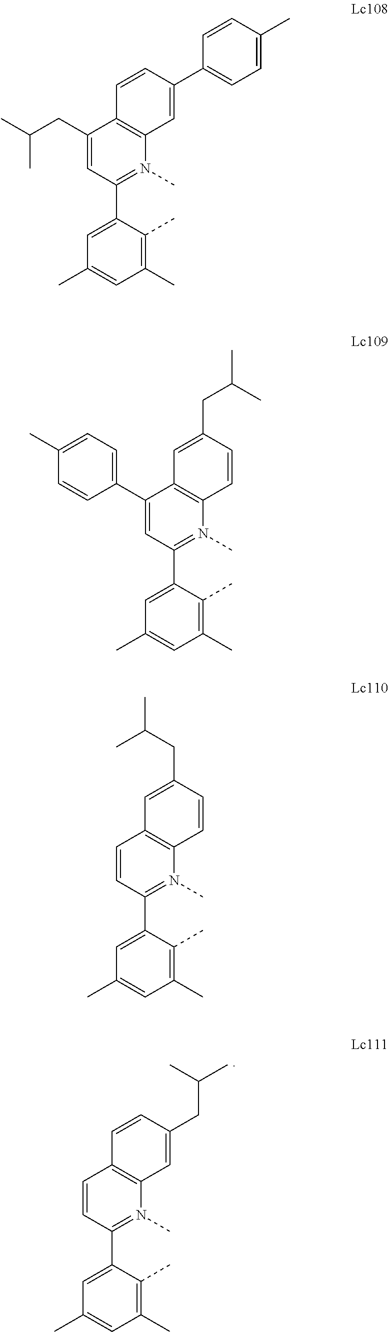

15. An electroluminescent device, comprising a cathode, an anode, and organic layers arranged between the cathode and the anode, wherein at least one of the organic layers comprises the iridium complex according to any one of claims 1-14.

16. The electroluminescent device according to claim 15, wherein the organic layers comprise a light-emitting layer, and the iridium complex according to any one of claims 1-14 is used a red light-emitting doping material for the light-emitting layer; or the organic layers comprise a hole injection layer, and the iridium complex according to any one of claims 1-14 is used as a hole injection material in the hole injection layer.
